(19) United States
(12) Patent Application Publication
(10) Pub. No.: US 2013/0240942 A1
(43) Pub. Date: Sep. 19, 2013

(54) SEMICONDUCTOR LIGHT EMITTING DEVICE

(71) Applicant: PANASONIC CORPORATION, Osaka (JP)

(72) Inventors: Akira INOUE, Osaka (JP); Masaki FUJIKANE, Osaka (JP); Toshiya YOKOGAWA, Nara (JP)

(73) Assignee: Panasonic Corporation, Osaka (JP)

(21) Appl. No.: 13/893,505

(22) Filed: May 14, 2013

Related U.S. Application Data
(63) Continuation of application No. PCT/JP2012/006063, filed on Sep. 24, 2012.

(30) Foreign Application Priority Data
Nov. 22, 2011 (JP) 2011-255045
Nov. 22, 2011 (JP) 2011-255051

(51) Int. Cl. H01L 33/58

(52) U.S. Cl. CPC H01L 33/58
USPC 257/98

(57) ABSTRACT

A semiconductor light emitting chip including a nitride semiconductor active layer having a nonpolar plane as a growth surface is configured such that when regions of a surface of a mounting substrate illuminated with light from the active layer and located laterally outward from the chip along a crystal axis that is parallel to the active layer and perpendicular to a polarization direction from the active layer are high polarization regions, and regions of the surface of the substrate illuminated with the light from the active layer except the high polarization regions are low polarization regions, metal is placed on a portion of the high polarization regions, and the proportion of mirror reflection from a portion of the low polarization regions is lower than that from the metal, and the proportion of mirror reflection from the high polarization regions is higher than that from the low polarization regions.

### CROSS-REFERENCE TO RELATED APPLICATIONS

This is a continuation of International Application No. PCT/JP2012/006063 filed on Sep. 24, 2012, which claims priority to Japanese Patent Applications Nos. 2011-255045 and 2011-255051 both filed on Nov. 22, 2011. The entire disclosures of these applications are incorporated by reference herein.

### BACKGROUND

The present disclosure relates to semiconductor light emitting devices including a semiconductor light emitting chip including a nitride semiconductor active layer having a nonpolar or semipolar plane as its growth surface.

Nitride semiconductors containing nitrogen (N) as a group V element have been expected as a material of a short wavelength light emitting element because of their band gap size. Gallium nitride-based compound semiconductors, in particular, have been actively researched, and blue light emitting diodes (LEDs), green LEDs, and blue semiconductor laser diodes that use a gallium nitride-based compound semiconductor have been also commercialized.

Gallium nitride-based compound semiconductors include a compound semiconductor obtained by substituting at least one of aluminum (Al) or indium (In) for part of gallium (Ga). Such a nitride semiconductor is represented by the general formula AlₓGa_{y}In_{z}N (where 0≦x, z<1, 0<y≦1, and x+y+z=1). The gallium nitride-based compound semiconductors are hereinafter referred to as GaN-based semiconductors.

When Al or In is substituted for Ga in a GaN-based semiconductor, this allows the band gap of the GaN-based semiconductor to be wider or narrower than that of GaN. Thus, not only short wavelength light, such as blue or green light, but also long wavelength light, such as orange or red light, can be emitted. From such a feature, nitride semiconductor light emitting elements have been expected to be used for, e.g., image display devices and lighting devices.

Nitride semiconductors have a wurtzite crystal structure. In FIGS. 1A, 1B, and 1C, the plane orientations of the wurtzite crystal structure are expressed in four-index notation (hexagonal indices). In four-index notation, crystal planes and the orientations of the planes are expressed using primitive vectors expressed as a₁, a₂, a₃, and c. The primitive vector c extends in a [0001] direction, and an axis in this direction is referred to as a “c-axis.” A plane perpendicular to the c-axis is referred to as a “c-plane” or a “(0001) plane.” FIG. 1A illustrates, not only the c-plane, but also an a-plane (=(11-20) plane) and an m-plane (=(1-100) plane). FIG. 1B illustrates an r-plane (=(1-102) plane), and FIG. 1C illustrates a (11-22) plane. Herein, the symbol “-” attached to the left of one of parenthesized numbers indicating the Miller indices expediently indicates inversion of the number, and corresponds to each of “bars” in some of the drawings.

FIG. 2A illustrates a crystal structure of a GaN-based semiconductor using a ball-and-stick model. FIG. 2B is a ball-and-stick model obtained by observing atomic arrangement in the vicinity of the m-plane surface from an a-axis direction. The m-plane is perpendicular to the plane of the paper of FIG. 2B. FIG. 2C is a ball-and-stick model obtained by observing atomic arrangement of a +c-plane surface from an m-axis direction.

The c-plane is perpendicular to the plane of the paper of FIG. 2C. As seen from FIGS. 2A and 2B, N atoms and Ga atoms are located on a plane parallel to the m-plane. On the other hand, as seen from FIGS. 2A and 2C, a layer in which only Ga atoms are located, and a layer in which only N atoms are located are formed on the c-plane. Conventionally, when a semiconductor element is to be fabricated using a GaN-based semiconductor, a c-plane substrate, i.e., a substrate having a (0001) plane as its principal surface, has been used as a substrate on which a nitride semiconductor crystal is grown. In this case, spontaneous electrical polarization is induced in the nitride semiconductor along the c-axis due to the arrangements of Ga and N atoms. Thus, the “c-plane” is referred to as a “polar plane.” As a result of the electrical polarization, a piezoelectric field is generated in a quantum well layer forming a portion of a light emitting layer of a nitride semiconductor light emitting element and made of InGaN along the c-axis. Due to the generated piezoelectric field, the distributed electrons and holes in the light emitting layer are displaced, and the internal quantum efficiency of the light emitting layer is decreased due to a quantum-confined Stark effect of carriers. In order to reduce the decrease in the internal quantum efficiency of the light emitting layer, the light emitting layer formed on the (0001) plane is designed to have a thickness equal to or less than 3 nm.

Furthermore, in recent years, consideration has been made to fabricate a light emitting element using a substrate having an m- or a-plane called a nonpolar plane, or a -r- or (11-22) plane called a semipolar plane as its principal surface. As illustrated in FIG. 1A, m-planes of the wurtzite crystal structure are parallel to the c-axis, and are six equivalent planes orthogonal to the c-plane. For example, in FIG. 1A, a (1-100) plane perpendicular to a [1-100] direction corresponds to one of the m-planes. The other m-planes equivalent to the (1-100) plane include a (−1010) plane, a (10-10) plane, a (−1100) plane, a (01-10) plane, and a (0-110) plane.

As illustrated in FIGS. 2A and 2B, Ga and N atoms on the m-planes are present on the same atomic plane, and thus, electrical polarization is not induced in directions perpendicular to the m-planes. Therefore, when a light emitting element is fabricated using a semiconductor layered structure having an m-plane as its growth surface, a piezoelectric field is not generated in a light emitting layer, and the problem where the internal quantum efficiency is decreased due to the quantum-confined Stark effect of carriers can be solved. This applies also to the a-plane that is a nonpolar plane except the m-planes, and furthermore, even when, instead of the m-plane, the -r- or (11-22) plane called the semipolar plane is used as the growth surface, similar advantages can be provided.

A nitride semiconductor light emitting element including an active layer having an m- or a-plane, or a -r- or (11-22) plane as a growth surface has polarization characteristics resulting from the structure of the valence band of the active layer.

For example, Japanese Patent Publication No. 2009-38293 describes a nitride semiconductor light emitting element which includes a mounting base having a mounting surface 30 serving also as a reflector 30R and recessed when viewed in cross section, and in which the mounting surface or the surface of the reflector forms a metal coating surface 35 to serve as a specular surface, in order to prevent diffusion of deflected light emitted from the light emitting element.

Japanese Patent Publication No. 2008-109098 describes a light emitting diode device including light emitting diode chips 10 each including a light emitting layer 12 having a principal plane 12a, and a package 20 having a chip-arrangement surface 21a on which the light emitting diode chips 10 are arranged, and configured such that light exiting from the principal plane 12a of the light emitting layer 12 has a plurality of different intensities depending on the in-plane azimuth angle of the principal plane 12a of the light emitting layer 12, and at least the light emitting diode chips 10 or the package 20 reduce variations in the intensity of light exiting from the package 20 due to the differences among the in-plane azimuth angles of the chip-arrangement surface 21a, in order to reduce the variations in the intensity of light exiting from the package due to the differences among the in-plane azimuth angles of the chip-arrangement surface.

### SUMMARY

The conventional nitride semiconductor light emitting device including an active layer having a nonpolar or semipolar plane as a growth surface has required more appropriate control over the polarization characteristics of outgoing light.

It is therefore an object of the present disclosure to more appropriately control polarization characteristics.

In order to solve the problem, an aspect of the present disclosure is directed to a semiconductor light emitting device including: a mounting substrate; metal formed on a surface of the mounting substrate; and a semiconductor light emitting chip held on the surface of the mounting substrate, and including a nitride semiconductor active layer having a nonpolar plane or a semipolar plane as a growth surface. The metal is placed on at least one portion of one of high polarization regions, a proportion of mirror reflection from at least one portion of one of low polarization regions is lower than a proportion of mirror reflection from the metal, and a proportion of mirror reflection from the high polarization regions is higher than a proportion of mirror reflection from the low polarization regions, where the high polarization regions represent regions of the surface of the mounting substrate illuminated with light from the nitride semiconductor active layer and located laterally outward from the semiconductor light emitting chip along a crystal axis that is parallel to the nitride semiconductor active layer and perpendicular to a polarization direction of the light from the nitride semiconductor active layer, and the low polarization regions represent regions of the surface of the mounting substrate illuminated with the light from the nitride semiconductor active layer except the high polarization regions.

Another aspect of the present disclosure is directed to a semiconductor light emitting device including: a mounting substrate; metal formed on a surface of the mounting substrate; and a semiconductor light emitting chip held on the surface of the mounting substrate, and including a nitride semiconductor active layer having a nonpolar plane or a semipolar plane as a growth surface. A diffuse reflectivity of surfaces of high polarization regions is higher than a mirror reflectivity of the surfaces of the high polarization regions, the metal is placed on at least one portion of one of low polarization regions, and a mirror reflectivity of a surface of the metal is higher than the mirror reflectivity of the surfaces of the high polarization regions, where the high polarization regions represent regions of the surface of the mounting substrate illuminated with light from the nitride semiconductor active layer and located laterally outward from the semiconductor light emitting chip along a crystal axis that is parallel to the nitride semiconductor active layer and perpendicular to a polarization direction of the light from the nitride semiconductor active layer, and the low polarization regions represent regions of the surface of the mounting substrate illuminated with the light from the nitride semiconductor active layer except the high polarization regions.

A semiconductor light emitting device according to the present disclosure can more appropriately control the polarization characteristics of light emitted from the semiconductor light emitting device.

### BRIEF DESCRIPTION OF THE DRAWINGS

FIG. 1A is a perspective view illustrating primitive vectors a₁, a₂, a₃, and c, and a-, c-, and m-planes of a wurtzite crystal structure. FIG. 1B is a perspective view illustrating an r-plane of the wurtzite crystal structure. FIG. 1C is a perspective view illustrating a (11-22) plane of the wurtzite crystal structure.

FIGS. 2A-2C are diagrams illustrating a crystal structure of a GaN-based semiconductor using a ball-and-stick model.

FIG. 3A is a schematic plan view illustrating a semiconductor light emitting device according to a first embodiment of the present disclosure. FIG. 3B is a cross-sectional view taken along the line IIIb-IIIb in FIG. 3A.

FIG. 4A is a schematic plan view illustrating a semiconductor light emitting device according to a first variation of the first embodiment. FIG. 4B is a cross-sectional view taken along the line IVb-IVb in FIG. 4A.

FIG. 5A is a schematic plan view illustrating a semiconductor light emitting device according to a second variation of the first embodiment. FIG. 5B is a cross-sectional view taken along the line Vb-Vb in FIG. 5A.

FIG. 6A is a graph illustrating the relationship between the major axis radius of a mounting surface effective portion and the length L of a side of a semiconductor light emitting chip according to the first embodiment of the present disclosure, and FIG. 6B is a graph illustrating the relationship between the minor axis radius of the mounting surface effective portion and the length L of the side of the semiconductor light emitting chip according to the first embodiment of the present disclosure.

FIG. 7 is a graph illustrating the relationship between the proportion of a second region of the mounting surface effective portion located laterally outward from a central region thereof along the major axis in the mounting surface effective portion and the length L of the side of the semiconductor light emitting chip according to the first embodiment of the present disclosure.

FIG. 8A is a schematic plan view illustrating a semiconductor light emitting device according to a second embodiment of the present disclosure. FIG. 8B is a cross-sectional view taken along the line VIIIb-VIIIb in FIG. 8A. FIGS. 8C and 8D each depict a plan view and a cross-sectional view illustrating a variation of raised/recessed portions of a light extraction surface.

FIG. 9A is a schematic plan view illustrating a semiconductor light emitting device according to a third embodiment of the present disclosure. FIG. 9B is a cross-sectional view taken along the line IXb-IXb in FIG. 9A.

FIG. 10A is a schematic plan view illustrating a semiconductor light emitting device according to a fourth embodiment of the present disclosure. FIG. 10B is a cross-sectional view taken along the line Xb-Xb in FIG. 10A.

FIG. 11 is a graph illustrating the relationship between the height from a mounting surface to an upper surface of each of semiconductor light emitting chips of the semiconductor light emitting device according to the fourth embodiment and the distance between the chips emitting light waves interfering with each other along the a-axis.

FIG. 12A is a schematic plan view illustrating a semiconductor light emitting device according to a fifth embodiment of the present disclosure. FIG. 12B is a cross-sectional view taken along the line XIIb-XIIb in FIG. 12A.

FIG. 13 is a graph illustrating the relationship between the height from a mounting surface to an upper surface of each of semiconductor light emitting chips of the semiconductor light emitting device according to the fifth embodiment and the distance between the chips emitting light waves interfering with each other along the c-axis.

FIG. 14A is a schematic plan view illustrating a semiconductor light emitting device according to a sixth embodiment of the present disclosure. FIG. 14B is a cross-sectional view taken along the line XIVb-XIVb in FIG. 14A.

FIG. 15A is a schematic plan view illustrating a semiconductor light emitting device according to a seventh embodiment of the present disclosure. FIG. 15B is a cross-sectional view taken along the line XVb-XVb in FIG. 15A.

FIG. 16A is a schematic plan view illustrating a semiconductor light emitting device according to a third variation of the first embodiment of the present disclosure. FIG. 16B is a cross-sectional view taken along the line XVIb-XVIb in FIG. 16A.

FIGS. 17A and 17B are schematic views illustrating a measurement system of luminous intensity distribution characteristics of semiconductor light emitting chips according to examples of the present disclosure.

FIG. 18 is a graph illustrating the relationships between the angles of radiation of light emitted from the semiconductor light emitting chip according to each of the examples of the present disclosure along the a- and c-axes and the wavelength of the emitted light.

FIG. 19A is a graph relating to reflection of light emitted from the semiconductor light emitting chip according to each of the examples of the present disclosure off the uppermost surface of a reflecting material made of silver (Ag), and illustrating the relationship between the roughness of the Ag uppermost surface and each of the mirror reflectivity of the Ag uppermost surface, the diffuse reflectivity thereof, and the proportion of mirror reflection therefrom. FIG. 19B is a graph illustrating the relationship between the surface roughness of a base material and the roughness of the Ag uppermost surface.

FIGS. 20A and 20B are diagrams illustrating an examination system for examining the influence of reflection properties on the degree of polarization, in which FIG. 20A is a cross-sectional view of the examination system, and FIG. 20B is a photomacrograph of a plan view thereof.

FIG. 21 is a schematic view illustrating a measurement system of the degree of polarization of light emitted from the semiconductor light emitting chip according to each of the examples of the present disclosure.

FIG. 22 is a graph illustrating the degree of polarization of light emitted from the semiconductor light emitting chip according to each of the examples of the present disclosure when a corresponding one of samples 1, 13, and 15 is used as a mounting substrate.

FIG. 23 is a graph illustrating the relationship between the angle between the direction of extension of stripes corresponding to raised/recessed portions formed on the light extraction surface of the semiconductor light emitting chip according to each of the examples of the present disclosure and an a-axis of a light emitting layer, and the degree of polarization of light.

FIG. 24 is a schematic plan view illustrating a semiconductor light emitting device according to a first example.

FIG. 25 is a schematic plan view illustrating a semiconductor light emitting device according to a second example.

FIG. 26 is a schematic plan view illustrating a semiconductor light emitting device according to a third example.

FIG. 27 is a schematic plan view illustrating a semiconductor light emitting device according to a fourth example.

FIG. 28 is a schematic plan view illustrating a semiconductor light emitting device according to a comparative example.

FIG. 29A is a schematic plan view illustrating a semiconductor light emitting device according to an eighth embodiment of the present disclosure. FIG. 29B is a cross-sectional view taken along the line XXIXb-XXIXb in FIG. 29A.

FIG. 30A is a schematic plan view illustrating a semiconductor light emitting device according to a first variation of the eighth embodiment. FIG. 30B is a cross-sectional view taken along the line XXXb-XXXb in FIG. 30A.

FIG. 31A is a schematic plan view illustrating a semiconductor light emitting device according to a second variation of the eighth embodiment. FIG. 31B is a cross-sectional view taken along the line XXXIb-XXXIb in FIG. 31A.

FIG. 32A is a graph illustrating the relationship between the major axis radius of a mounting surface effective portion and the length L of a side of a semiconductor light emitting chip according to the eighth embodiment of the present disclosure, and FIG. 32B is a graph illustrating the relationship between the minor axis radius of the mounting surface effective portion and the length L of the side of the semiconductor light emitting chip according to the eighth embodiment of the present disclosure.

FIG. 33 is a graph illustrating the relationship between the proportion of a second region of the mounting surface effective portion located laterally outward from a central region thereof along the major axis in the mounting surface effective portion and the length L of the side of the semiconductor light emitting chip according to the eighth embodiment of the present disclosure.

FIG. 34A is a schematic plan view illustrating a semiconductor light emitting device according to a ninth embodiment of the present disclosure. FIG. 34B is a cross-sectional view taken along the line XXXIVb-XXXIVb in FIG. 34A. FIGS. 34C-34F each depict a plan view and a cross-sectional view illustrating a variation of raised/recessed portions of a light extraction surface.

FIG. 35A is a schematic plan view illustrating a semiconductor light emitting device according to a tenth embodiment of the present disclosure. FIG. 35B is a cross-sectional view taken along the line XXXVb-XXXVb in FIG. 35A.

FIG. 36A is a schematic plan view illustrating a semiconductor light emitting device according to an eleventh embodiment of the present disclosure. FIG. 36B is a cross-sectional view taken along the line XXXVIb-XXXVIb in FIG. 36A.

FIG. 37 is a graph illustrating the relationship between the height from a mounting surface to an upper surface of each of semiconductor light emitting chips of the semiconductor light emitting device according to the eleventh embodiment and the distance between the chips emitting light waves interfering with each other along the a-axis.

FIG. 38A is a schematic plan view illustrating a semiconductor light emitting device according to a twelfth embodiment of the present disclosure. FIG. 38B is a cross-sectional view taken along the line XXXVIIIb-XXXVIIIb in FIG. 38A.

FIG. 39 is a graph illustrating the relationship between the height from a mounting surface to an upper surface of each of semiconductor light emitting chips of the semiconductor light emitting device according to the twelfth embodiment and the distance between the chips emitting light waves interfering with each other along the c-axis.

FIG. 40A is a schematic plan view illustrating a semiconductor light emitting device according to a thirteenth embodiment of the present disclosure. FIG. 40B is a cross-sectional view taken along the line XLb-XLb in FIG. 40A.

FIG. 41A is a schematic plan view illustrating a semiconductor light emitting device according to a fourteenth embodiment of the present disclosure. FIG. 41B is a cross-sectional view taken along the line XLIb-XLIb in FIG. 41A.

FIG. 42A is a schematic plan view illustrating a semiconductor light emitting device according to a third variation of the eighth embodiment of the present disclosure.

FIG. 42B is a cross-sectional view taken along the line XLIIb-XLIIb in FIG. 42A.

FIGS. 43A and 43B are schematic views illustrating a measurement system of luminous intensity distribution characteristics of semiconductor light emitting chips according to examples of the present disclosure.

FIG. 44 is a graph illustrating the relationships between the angles of radiation of light emitted from the semiconductor light emitting chip according to each of the examples of the present disclosure along the a- and c-axes and the wavelength of the emitted light.

FIG. 45A is a graph relating to reflection of light emitted from the semiconductor light emitting chip according to each of the examples of the present disclosure off the uppermost surface of a reflecting material made of silver (Ag), and illustrating the relationship between the roughness of the Ag uppermost surface and each of the mirror reflectivity of the Ag uppermost surface, the diffuse reflectivity thereof, and the proportion of mirror reflection therefrom. FIG. 45B is a graph illustrating the relationship between the surface roughness of a base material and the roughness of the Ag uppermost surface.

FIGS. 46A and 46B are diagrams illustrating an examination system for examining the influence of reflection properties on the degree of polarization, in which FIG. 46A is a cross-sectional view of the examination system, and FIG. 46B is a photomacrograph of a plan view thereof.

FIG. 47 is a schematic view illustrating a measurement system of the degree of polarization of light emitted from the semiconductor light emitting chip according to each of the examples of the present disclosure.

FIG. 48 is a graph illustrating the degree of polarization of light emitted from the semiconductor light emitting chip according to each of the examples of the present disclosure when a corresponding one of samples 1, 13, and 15 is used as a mounting substrate.

FIG. 49 is a scanning electron microscope (SEM) image illustrating raised/recessed portions formed on a light extraction surface of the semiconductor light emitting chip according to an example of the present disclosure.

FIG. 50 is a graph illustrating the relationship between the angle between the direction of extension of stripes corresponding to raised/recessed portions formed on the light extraction surface of the semiconductor light emitting chip according to each of the examples of the present disclosure and an a-axis of a light emitting layer, and the degree of polarization of light.

FIGS. 51A and 51B are schematic plan views illustrating a semiconductor light emitting device according to a fifth example.

FIG. 52 is a schematic plan view illustrating a semiconductor light emitting device according to a sixth example.

FIG. 53 is a schematic plan view illustrating a semiconductor light emitting device according to a seventh example.

FIGS. 54A and 54B are schematic plan views illustrating a semiconductor light emitting device according to a comparative example.

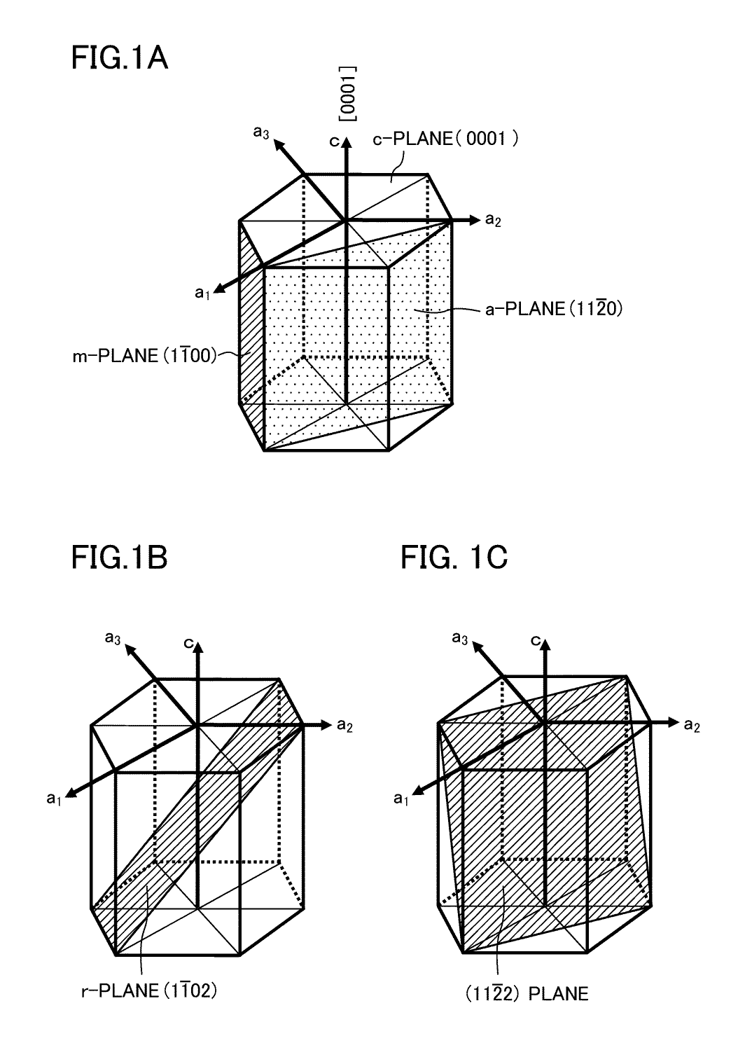

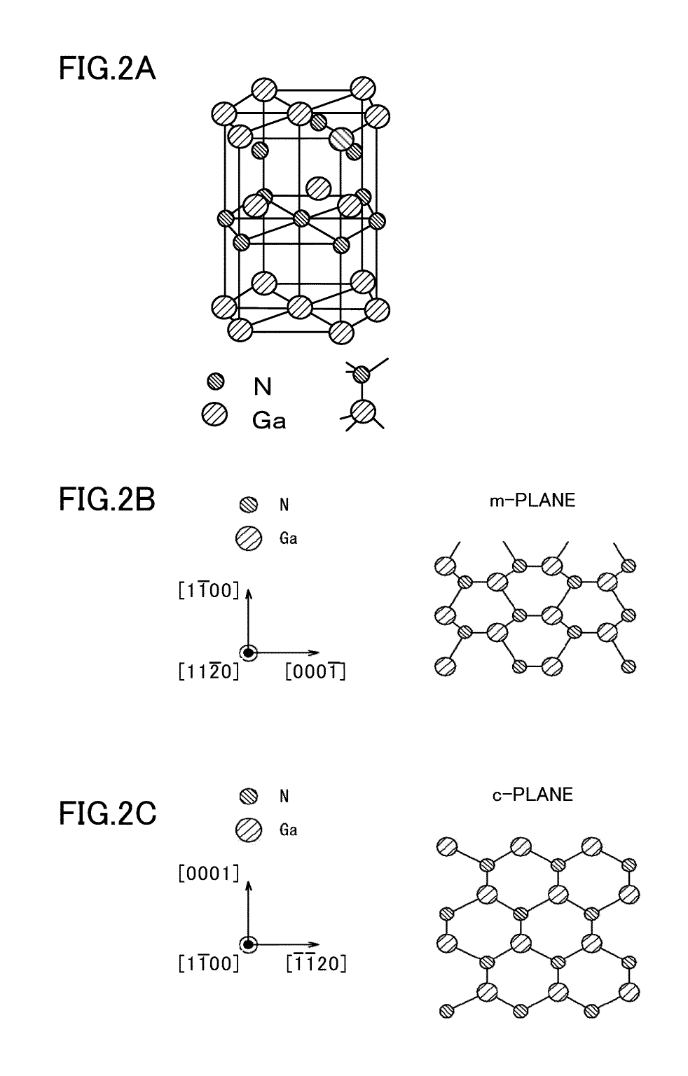

### DETAILED DESCRIPTION

A semiconductor light emitting device according to an embodiment is directed to a semiconductor light emitting device including: a mounting substrate; metal formed on a surface of the mounting substrate; and a semiconductor light emitting chip held on the surface of the mounting substrate, and including a nitride semiconductor active layer having a nonpolar plane or a semipolar plane as a growth surface. The metal is placed on at least one portion of one of high polarization regions, a proportion of mirror reflection from at least one portion of one of low polarization regions is lower than a proportion of mirror reflection from the metal, and a proportion of mirror reflection from the high polarization regions is higher than a proportion of mirror reflection from the low polarization regions, where the high polarization regions represent regions of the surface of the mounting substrate illuminated with light from the nitride semiconductor active layer and located laterally outward from the semiconductor light emitting chip along a crystal axis that is parallel to the nitride semiconductor active layer and perpendicular to a polarization direction of the light from the nitride semiconductor active layer, and the low polarization regions represent regions of the surface of the mounting substrate illuminated with the light from the nitride semiconductor active layer except the high polarization regions.

A semiconductor light emitting device according to another embodiment is directed to a semiconductor light emitting device including: a mounting substrate; an interconnect electrode formed on a surface of the mounting substrate; and a semiconductor light emitting chip held on the surface of the mounting substrate so as to be electrically connected to the interconnect electrode, and including a nitride semiconductor active layer having a nonpolar plane or a semipolar plane as a growth surface. The interconnect electrode is placed on at least one portion of one of high polarization regions, a proportion of mirror reflection from at least one portion of one of low polarization regions is lower than a proportion of mirror reflection from the interconnect electrode, and a proportion of mirror reflection from the high polarization regions is higher than a proportion of mirror reflection from the low polarization regions, where the high polarization regions represent regions of the surface of the mounting substrate illuminated with light from the nitride semiconductor active layer and located laterally outward from the semiconductor light emitting chip along a crystal axis that is parallel to the nitride semiconductor active layer and perpendicular to a polarization direction of the light from the nitride semiconductor active layer, and the low polarization regions represent regions of the surface of the mounting substrate illuminated with the light from the nitride semiconductor active layer except the high polarization regions.

A semiconductor light emitting device according to still another embodiment is directed to a semiconductor light emitting device including: a mounting substrate; an interconnect electrode formed on a surface of the mounting substrate; and a semiconductor light emitting chip held on the surface of the mounting substrate so as to be electrically connected to the interconnect electrode, and including a nitride semiconductor active layer having an m-plane as a growth surface. An elliptical shape is defined on the surface of the mounting substrate, the elliptical shape has a center identical with a center of the semiconductor light emitting chip when viewed in plan, a major axis parallel to a c-axis of the nitride semiconductor active layer, and a minor axis parallel to an a-axis of the nitride semiconductor active layer, the major axis and the minor axis respectively have a radius α and a radius β respectively represented by:

α=2√{(L²+2TL)/π} (1);

and

β=√{(L²+2TL)/π} (2)

where L is a length of a side of the semiconductor light emitting chip, and T is a thickness of the semiconductor light emitting chip, when viewed in plan, a region of the surface of the mounting substrate inside the elliptical shape is sectioned into nine sub-regions using two straight lines parallel to the c-axis of the nitride semiconductor active layer and two straight lines parallel to the a-axis of the nitride semiconductor active layer such that the semiconductor light emitting chip is surrounded by the straight lines, a first region represents one of the nine sub-regions that contains the semiconductor light emitting chip, a second region represents a group of two of the nine sub-regions adjacent to the first region along the c-axis, a third region represents a group of six of the nine sub-regions except the first and second regions, the two straight lines parallel to the c-axis and the two straight lines parallel to the a-axis are defined such that an area of the first region is minimum, the interconnect electrode is formed on at least one portion of the second region, a proportion of mirror reflection from at least one portion of the third region is lower than a proportion of mirror reflection from the interconnect electrode, and a proportion of mirror reflection from the second region is higher than a proportion of mirror reflection from the third region.

In an embodiment, a proportion of mirror reflection from a surface of the interconnect electrode may be higher than or equal to 15%.

In an embodiment, a relationship represented by T<L may be satisfied.

In an embodiment, a relationship represented by T<L/6 may be satisfied.

In an embodiment, a proportion of mirror reflection from a surface of the interconnect electrode may be higher than or equal to 50%.

In an embodiment, a surface roughness of the interconnect electrode may be equal to or less than 50 nm.

In an embodiment, an area of a portion of the third region from which a proportion of mirror reflection may be lower than the proportion of mirror reflection from the interconnect electrode when viewed in plan is equal to or less than (L²+4TL)/10.

In an embodiment, a plurality of stripe-shaped raised/recessed portions may be formed on a light extraction surface of the semiconductor light emitting chip, and a direction of extension of the raised/recessed portions may be inclined at an angle greater than or equal to 0° and less than 5° with respect to a direction of polarization of light from the nitride semiconductor active layer or an a-axis of the nitride semiconductor active layer.

In an embodiment, the semiconductor light emitting device may further include: a reflection member held on the surface of the mounting substrate, having a height H1 from the surface, and having its inner surface that is a reflection surface. In this case, the relationships represented by D1<2.75×H1 and D2<5.67×H1 may be satisfied where D1 is a distance from an end surface of the semiconductor light emitting chip corresponding to an a-plane of the chip to the reflection member along the a-axis, and D2 is a distance from an end surface of the chip corresponding to a c-plane of the chip to the reflection member along the c-axis, and a proportion of mirror reflection from a region of the reflection surface of the reflection member corresponding to the second region may be higher than or equal to 15%.

In an embodiment, the semiconductor light emitting chip may include a plurality of semiconductor light emitting chips held on the surface of the mounting substrate along the a-axis while being spaced, and the elliptical shape inside which the region of the surface of the mounting substrate is sectioned into the first region, the second region, and the third region may be defined on the surface of the mounting substrate to correspond to each of the semiconductor light emitting chips.

In an embodiment, a distance D3 between an adjacent pair of the semiconductor light emitting chips may be greater than a smaller one of a value given by (2.75×H2), where H2 is a height from the surface of the mounting substrate to an upper surface of each of the semiconductor light emitting chips, and a value given by [√{(L²+2TL)/π}−L/2].

In an embodiment, a distance D3 between an adjacent pair of the semiconductor light emitting chips may be greater than a greater one of a value given by (2.75×H2), where H2 is a height from the surface of the mounting substrate to an upper surface of each of the semiconductor light emitting chips, and a value given by [√{(L²+2TL)/π}−L/2].

In an embodiment, the semiconductor light emitting chip may include a plurality of semiconductor light emitting chips at least two of which are held on the surface of the mounting substrate along the a-axis while being spaced, and at least two of which are held on the surface of the mounting substrate along the c-axis while being spaced, the elliptical shape inside which the region of the surface of the mounting substrate is sectioned into the first region, the second region, and the third region may be defined on the surface of the mounting substrate to correspond to each of the semiconductor light emitting chips, and D3<D4 may be satisfied where D3 is a distance between an adjacent pair of the semiconductor light emitting chips along the a-axis, and D4 is a distance between an adjacent pair of the semiconductor light emitting chips along the c-axis.

In an embodiment, Nc<Na may be satisfied where Na is the number of the semiconductor light emitting chips arranged along the a-axis, and Nc is the number of the semiconductor light emitting chips arranged along the c-axis.

In an embodiment, the distance D3 may be greater than a smaller one of a value given by (2.75×H2), where H2 is a height from the surface of the mounting substrate to an upper surface of each of the semiconductor light emitting chips, and a value given by [√{(L²+2TL)/π}−L/2], and the distance D4 may be greater than a smaller one of a value given by (5.67×H2) and a value given by [2√{(L²+2TL)/π}−L/2].

In an embodiment, the distance D3 may be greater than a greater one of a value given by (2.75×H2), where H2 is a height from the surface of the mounting substrate to an upper surface of each of the semiconductor light emitting chips, and a value given by [√{(L²+2TL)/π}−L/2], and the distance D4 may be greater than a greater one of a value given by (5.67×H2) and a value given by [2√{(L²+2TL)/π}−L/2].

A semiconductor light emitting device according to yet another embodiment is directed to a semiconductor light emitting device including: a mounting substrate; metal formed on a surface of the mounting substrate; and a semiconductor light emitting chip held on the surface of the mounting substrate, and including a nitride semiconductor active layer having a nonpolar plane or a semipolar plane as a growth surface. A diffuse reflectivity of surfaces of high polarization regions is higher than a mirror reflectivity of the surfaces of the high polarization regions, the metal is placed on at least one portion of one of low polarization regions, and a mirror reflectivity of a surface of the metal is higher than the mirror reflectivity of the surfaces of the high polarization regions, where the high polarization regions represent regions of the surface of the mounting substrate illuminated with light from the nitride semiconductor active layer and located laterally outward from the semiconductor light emitting chip along a crystal axis that is parallel to the nitride semiconductor active layer and perpendicular to a polarization direction of the light from the nitride semiconductor active layer, and the low polarization regions represent regions of the surface of the mounting substrate illuminated with the light from the nitride semiconductor active layer except the high polarization regions.

A semiconductor light emitting device according to a further embodiment is directed to a semiconductor light emitting device including: a mounting substrate; an interconnect electrode formed on a surface of the mounting substrate; and a semiconductor light emitting chip held on the surface of the mounting substrate so as to be electrically connected to the interconnect electrode, and including a nitride semiconductor active layer having a nonpolar plane or a semipolar plane as a growth surface. A diffuse reflectivity of surfaces of high polarization regions is higher than a mirror reflectivity of the surfaces of the high polarization regions, the interconnect electrode is placed on at least one portion of one of low polarization regions, and a mirror reflectivity of a surface of the interconnect electrode is higher than the mirror reflectivity of the surfaces of the high polarization regions, where the high polarization regions represent regions of the surface of the mounting substrate illuminated with light from the nitride semiconductor active layer and located laterally outward from the semiconductor light emitting chip along a crystal axis that is parallel to the nitride semiconductor active layer and perpendicular to a polarization direction of the light from the nitride semiconductor active layer, and the low polarization regions represent regions of the surface of the mounting substrate illuminated with the light from the nitride semiconductor active layer except the high polarization regions.

A semiconductor light emitting device according to a further embodiment is directed to a semiconductor light emitting device including: a mounting substrate; an interconnect electrode formed on a surface of the mounting substrate; and a semiconductor light emitting chip held on the surface of the mounting substrate so as to be electrically connected to the interconnect electrode, and including a nitride semiconductor active layer having an m-plane as a growth surface. An elliptical shape is defined on the surface of the mounting substrate, the elliptical shape has a center identical with a center of the semiconductor light emitting chip when viewed in plan, a major axis parallel to a c-axis of the nitride semiconductor active layer, and a minor axis parallel to an a-axis of the nitride semiconductor active layer, the major axis and the minor axis respectively have a radius α and a radius β respectively represented by:

α=2√{(L²+2TL)/π} (3);

and

β=√{(L²+2TL)/π} (4)

where L is a length of a side of the semiconductor light emitting chip, and T is a thickness of the semiconductor light emitting chip, when viewed in plan, a region of the surface of the mounting substrate inside the elliptical shape is sectioned into nine sub-regions using two straight lines parallel to the c-axis of the nitride semiconductor active layer and two straight lines parallel to the a-axis of the nitride semiconductor active layer such that the semiconductor light emitting chip is surrounded by the straight lines, a first region represents one of the nine sub-regions that contains the semiconductor light emitting chip, a second region represents a group of two of the nine sub-regions adjacent to the first region along the c-axis, a third region represents a group of six of the nine sub-regions except the first and second regions, the two straight lines parallel to the c-axis and the two straight lines parallel to the a-axis are defined such that an area of the first region is minimum, the interconnect electrode is formed on at least one portion of the third region, a diffuse reflectivity of a surface of the second region is higher than a mirror reflectivity of the surface of the second region, and a mirror reflectivity of a surface of the interconnect electrode is higher than the mirror reflectivity of the surface of the second region.

In an embodiment, a relationship represented by T<L may be satisfied.

In an embodiment, a relationship represented by T<L/6 may be satisfied.

In an embodiment, the diffuse reflectivity of the surface of the second region may be higher than or equal to 90%.

In an embodiment, a surface roughness of the second region may be greater than or equal to 200 nm.

In an embodiment, a proportion of mirror reflection from the surface of the interconnect electrode may be higher than or equal to 12%, and a diffuse reflectivity of the surface of the interconnect electrode is less than 69%.

In an embodiment, an area of the interconnect electrode when viewed in plan may be equal to or less than (L²+4TL)/10.

In an embodiment, a plurality of raised/recessed portions may be formed on a light extraction surface of the semiconductor light emitting chip.

In an embodiment, the plurality of raised/recessed portions may be hemispherical.

In an embodiment, the plurality of raised/recessed portions may be stripe-shaped when viewed in plan, and a direction of extension of the raised/recessed portions may be inclined at an angle greater than or equal to 5° and equal to or less than 90° with respect to a direction of polarization of light from the nitride semiconductor active layer or an a-axis of the nitride semiconductor active layer.

In an embodiment, the semiconductor light emitting device may further include: a reflection member held on the surface of the mounting substrate, having a height H1 from the surface, and having its inner surface that is a reflection surface. In this case, the relationships represented by D1<2.75×H1 and D2<5.67×H1 may be satisfied where D1 is a distance from an end surface of the semiconductor light emitting chip corresponding to an a-plane of the chip to the reflection member along the a-axis, and D2 is a distance from an end surface of the chip corresponding to a c-plane of the chip to the reflection member along the c-axis, and a diffuse reflectivity of a region of the reflection surface of the reflection member corresponding to the second region may be higher than a mirror reflectivity of the region of the reflection surface.

In an embodiment, the semiconductor light emitting chip may include a plurality of semiconductor light emitting chips held on the surface of the mounting substrate along the a-axis while being spaced, and the elliptical shape inside which the region of the surface of the mounting substrate is sectioned into the first region, the second region, and the third region may be defined on the surface of the mounting substrate to correspond to each of the semiconductor light emitting chips.

In an embodiment, a distance D3 between an adjacent pair of the semiconductor light emitting chips may be greater than a smaller one of a value given by (2.75×H2), where H2 is a height from the surface of the mounting substrate to an upper surface of each of the semiconductor light emitting chips, and a value given by [√{(L²+2TL)/π}−L/2].

In an embodiment, a distance D3 between an adjacent pair of the semiconductor light emitting chips may be greater than a greater one of a value given by (2.75×H2), where H2 is a height from the surface of the mounting substrate to an upper surface of each of the semiconductor light emitting chips, and a value given by [√{(L²+2TL)/π}−L/2].

In an embodiment, the semiconductor light emitting chip may include a plurality of semiconductor light emitting chips at least two of which are held on the surface of the mounting substrate along the a-axis while being spaced, and at least two of which are held on the surface of the mounting substrate along the c-axis while being spaced, the elliptical shape inside which the region of the surface of the mounting substrate is sectioned into the first region, the second region, and the third region may be defined on the surface of the mounting substrate, and corresponds to each of the semiconductor light emitting chips, and D3<D4 may be satisfied where D3 is a distance between an adjacent pair of the semiconductor light emitting chips along the a-axis, and D4 is a distance between an adjacent pair of the semiconductor light emitting chips along the c-axis.

In an embodiment, Nc<Na may be satisfied where Na is the number of the semiconductor light emitting chips arranged along the a-axis, and Nc is the number of the semiconductor light emitting chips arranged along the c-axis.

In an embodiment, the distance D3 may be greater than a smaller one of a value given by (2.75×H2), where H2 is a height from the surface of the mounting substrate to an upper surface of each of the semiconductor light emitting chips, and a value given by [√{(L²+2TL)/π}−L/2], and the distance D4 may be greater than a smaller one of a value given by (5.67×H2) and a value given by [2√{(L²+2TL)/π}−L/2].

In an embodiment, the distance D3 may be greater than a greater one of a value given by (2.75×H2), where H2 is a height from the surface of the mounting substrate to an upper surface of each of the semiconductor light emitting chips, and a value given by [√{(L²+2TL)/π}−L/2], and the distance D4 may be greater than a greater one of a value given by (5.67×H2) and a value given by [2√{(L²+2TL)/π}−L/2].

In an embodiment, the semiconductor light emitting device may further include: a protection element held on one of the low polarization regions of the mounting substrate.

In an embodiment, the semiconductor light emitting device may further include: an alignment marker placed on one of the low polarization regions of the mounting substrate.

In an embodiment, the nitride semiconductor active layer may be a GaN-based semiconductor active layer.

Incidentally, the nitride semiconductor active layer having an m-plane as a growth surface emits light with electric field intensity varying principally along the a-axis. When light emitted from a light emitting element has polarization characteristics, it is theoretically predicted that the light emitted from the light emitting element will exhibit the luminous intensity distribution where the intensity of the emitted light increases in a direction perpendicular to the polarization direction of the light. In other words, the light emitted from the light emitting element exhibits an uneven radiation pattern (luminous intensity distribution). Furthermore, it is theoretically predicted that light with electric field intensity varying along a specific crystal direction of a nitride semiconductor will be emitted also from each of semipolar planes, such as -r-, (20-21), (20-2-1), (10-1-3), and (11-22) planes, and other nonpolar planes, such as a-planes, and the emitted light will exhibit the luminous intensity distribution where the intensity of the emitted light increases in a direction perpendicular to the polarization direction of the light.

The polarization direction of light from a nitride semiconductor active layer having an a-plane as a growth surface has been known to be along the m-axis. Therefore, it is predicted that the light will exhibit the luminous intensity distribution where the intensity of the emitted light increases in a direction perpendicular to the m-axis.

The polarization direction of light from a nitride semiconductor active layer having a (20-2-1) or (20-21) plane that is a semipolar plane as a growth surface has been known to correspond to the [-12-10] direction. Therefore, it is predicted that the light will exhibit the luminous intensity distribution where the intensity of the emitted light increases in a direction perpendicular to the [-12-10] direction.

When the In content of a nitride semiconductor active layer having a (10-1-3) plane that is a semipolar plane as a growth surface is high, the polarization direction of light from the nitride semiconductor active layer has been known to correspond to the [-12-10] direction, and when the In content of the nitride semiconductor active layer is low, the polarization direction of the light has been known to correspond to the [11-23] direction. Therefore, it is predicted that the light will exhibit the luminous intensity distribution where when the In content of the active layer is high, the intensity of the emitted light increases in a direction perpendicular to the [-12-10] direction, and when the In content of the active layer is low, the intensity of the emitted light increases in a direction perpendicular to the [11-23] direction.

When the In content of a nitride semiconductor active layer having a (11-22) plane that is a semipolar plane as a growth surface is high, the polarization direction of light from the nitride semiconductor active layer has been known to be along the m-axis, and when the In content of the nitride semiconductor active layer is low, the polarization direction of the light has been known to correspond to the [-1-123] direction. Therefore, it is predicted that the light will exhibit the intensity distribution where when the In content of the active layer is high, the intensity of the emitted light increases in a direction perpendicular to the m-axis, and when the In content of the active layer is low, the intensity of the emitted light increases in a direction perpendicular to the [-1-123] direction.

Light with electric field intensity varying along a specific direction is herein referred to as “polarized light.” For example, light with electric field intensity varying along an X-axis is referred to as “polarized light along the X-axis,” and in this case, a direction along the X-axis is referred to as a “polarization direction.” The “polarized light along the X-axis” does not mean only linearly polarized light along the X-axis, and may include linearly polarized light along other axes. More specifically, the “polarized light along the X-axis” means light including a light component that transmits through a “polarizer having a polarization transmission axis along the X-axis” and has higher intensity (electric field intensity) than a light component transmitting through a “polarizer having a polarization transmission axis along another axis.” Therefore, the “polarized light along the X-axis” includes incoherent light including not only linearly polarized light and elliptically polarized light along the X-axis, but also linearly polarized light and elliptically polarized light in various directions.

When the polarization transmission axis of a polarizer is rotated about the optical axis, the degree of polarization is defined by the following expression (A):

Degree of Polarization=|Imax−Imin|/|Imax+Imin| (A)

where Imax is the highest electric field intensity of light transmitting through the polarizer, and Imin is the lowest electric field intensity thereof.

When the polarization transmission axis of the polarizer is parallel to the X-axis, the electric field intensity of “light polarized along the X-axis” and transmitting through the polarizer is Imax, and when the polarization transmission axis of the polarizer is parallel to the Y-axis, the electric field intensity of the light is Imin. The electric field intensity Imin of completely linearly polarized light is equal to 0, and thus, the degree of polarization is equal to one. By contrast, the difference between the electric field intensity Imax of completely depolarized light and the electric field intensity Imin thereof is equal to zero, and thus, the degree of polarization is equal to zero.

A nitride semiconductor light emitting element including an active layer having an m-plane as a growth surface emits polarized light principally along the a-axis as described above. In this case, the nitride semiconductor light emitting element emits also polarized light along the c-axis and polarized light along the m-axis. However, the intensity of each of the polarized light along the c-axis and the polarized light along the m-axis is lower than that of the polarized light along the a-axis.

Herein, an active layer having an m-plane as a growth surface is used as an example, and attention is focused on polarized light along the a-axis. However, also when a semipolar plane, such as a -r-, (20-21), (20-2-1), (10-1-3), or (11-22) plane, or another nonpolar plane, such as an a-plane, is used as the growth surface, similar statements apply to polarized light in a specific crystal direction.

Herein, “m-planes” include not only planes completely parallel to the m-planes, but also planes inclined at an angle of about ±5° or less from the m-planes. Planes inclined slightly from the m-planes are much less affected by spontaneous electrical polarization. In addition, in some cases, in a crystal growth technique, a semiconductor layer is more easily epitaxially grown on a substrate having a crystal orientation inclined slightly from a desired orientation than on a substrate having a crystal orientation exactly coinciding with the desired orientation. Therefore, it may be useful to slightly incline a crystal plane in order to improve the crystal quality of the semiconductor layer to be epitaxially grown or increase the crystal growth rate of the semiconductor layer while reducing the influence of spontaneous electrical polarization to a sufficient level.

Similar statements apply to “a-planes,” “(20-21) planes,” “(20-2-1) planes,” “(10-1-3) planes,” “-r-planes,” and “(11-22) planes,” and thus, the “a-planes,” the “(20-21) planes,” the “(20-2-1) planes,” the “(10-1-3) planes,” the “-r-planes,” and the “(11-22) planes” herein each include not only planes completely parallel to corresponding ones of the “a-planes,” the “(20-21) planes,” the “(20-2-1) planes,” the “(10-1-3) planes,” the “-r-planes,” and the “(11-22) planes,” but also planes inclined at an angle of about ±5° or less from the corresponding ones of the “a-planes,” the “(20-21) planes,” the “(20-2-1) planes,” the “(10-1-3) planes,” the “-r-planes,” and the “(11-22) planes.”

When a light emitting element that emits light with polarization characteristics is used as a light source, the amount of reflection off the object surface varies depending on the direction of polarization of light from the light source, i.e., the direction in which the light emitting element is oriented. This causes the visibility of an object to vary. The reason for this is that the reflectivity of P-polarized light is different from that of S-polarized light. That is, the reflectivity of the S-polarized light from the object surface is higher than that of the P-polarized light therefrom. Here, the P-polarized light is light having an electric field component parallel to the plane of incidence. The S-polarized light is light having an electric field component perpendicular to the plane of incidence. In applications utilizing the polarization characteristics as they are, such as a backlight for a liquid crystal display, it is significant to increase the degree of polarization; however, in typical lighting applications, the polarization characteristics may impair the visibility of the object.

Generally, a nitride semiconductor light emitting device includes a semiconductor light emitting chip made of a nitride semiconductor, and a mounting substrate. The mounting substrate may be referred to as a package. A surface of the mounting substrate on which the semiconductor light emitting chip is held is referred to as a mounting surface. A plurality of interconnect electrodes electrically connected to the semiconductor light emitting chip, and insulators providing electrical isolation between the interconnect electrodes are generally placed on the mounting surface that is the surface of the mounting substrate. The interconnect electrodes may be referred to as interconnect patterns. Furthermore, a reflector configured to shape light emitted from the semiconductor light emitting chip, and a protection element configured to protect the semiconductor light emitting chip from a reverse voltage or a high voltage may be placed on the mounting surface.

As such, a plurality of components can be placed on the mounting surface of the mounting substrate. However, the relationship between the locations at which the components are placed and the degree of polarization has not been conventionally revealed. Japanese Patent Publication No. 2009-38293 described above does not specifically describe appropriate relationships among the locations of a semiconductor light emitting chip, specular and mounting surfaces of a mounting substrate, and the reflector surface.

It is an object of Japanese Patent Publication No. 2008-109098 described above to reduce variations in the intensity of light exiting from the package due to the differences among the in-plane azimuth angles of the light with respect to the chip-arrangement surface, and no consideration has been given to the degree of polarization of the light emitted from the package.

### First Embodiment

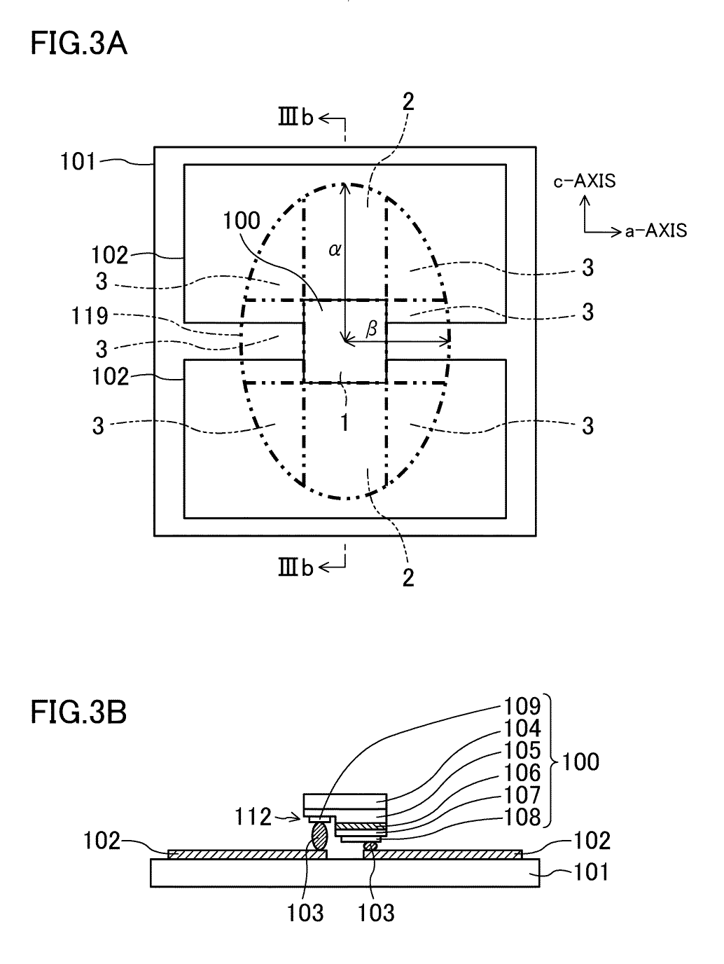

A semiconductor light emitting device according to a first embodiment of the present disclosure will be described hereinafter with reference to FIGS. 3A and 3B.

First, as illustrated in FIG. 3B, a semiconductor light emitting chip 100 made of a nitride semiconductor includes a substrate 104 including a GaN layer (hereinafter referred to as an m-plane GaN layer) that has an m-plane as its principal surface (and a growth surface) and is formed, for example, on at least a surface of the substrate 104, an n-type nitride semiconductor layer 105 formed on the principal surface of the substrate 104, an active layer 106 formed on the n-type nitride semiconductor layer 105 and made of a nitride semiconductor, a p-type nitride semiconductor layer 107 formed on the active layer 106, a p-side electrode 108 formed on and in contact with the p-type nitride semiconductor layer 107, and an n-side electrode 109 formed on and in contact with an exposed portion of the n-type nitride semiconductor layer 105. The growth surface of each of the n-type nitride semiconductor layer 105, the active layer 106, and the p-type nitride semiconductor layer 107 is substantially parallel to m-planes. In other words, the layers 105, 106, and 107 are stacked along the m-axis. Another layer may be formed between the n-type nitride semiconductor layer 105 and the active layer 106. Furthermore, another layer may be formed between the active layer 106 and the p-type nitride semiconductor layer 107. Here, a semiconductor (GaN-based semiconductor) made of a gallium nitride-based compound will be described as an example nitride semiconductor. The GaN-based semiconductor includes a semiconductor represented by the general expression AlₓIn_{y}Ga_{z}N (where 0≦x, y<1, 0<z≦1, and x+y+z=1).

As illustrated in FIGS. 3A and 3B, the semiconductor light emitting chip 100 is mounted on a mounting substrate 101 with the p-side and n-side electrodes 108 and 109 opposed to interconnect electrodes 102 that are placed on the surface of the mounting substrate 101. In other words, the semiconductor light emitting chip 100 is electrically connected to and held on the two interconnect electrodes 102 on the mounting substrate 101 with a bump 103 interposed between the semiconductor light emitting chip 100 and each of the interconnect electrodes 102. Such a structure is referred to as a flip-chip structure. One of the interconnect electrodes 102 is connected to the p-side electrode 108, and the other interconnect electrode 102 is connected to the n-side electrode 109.

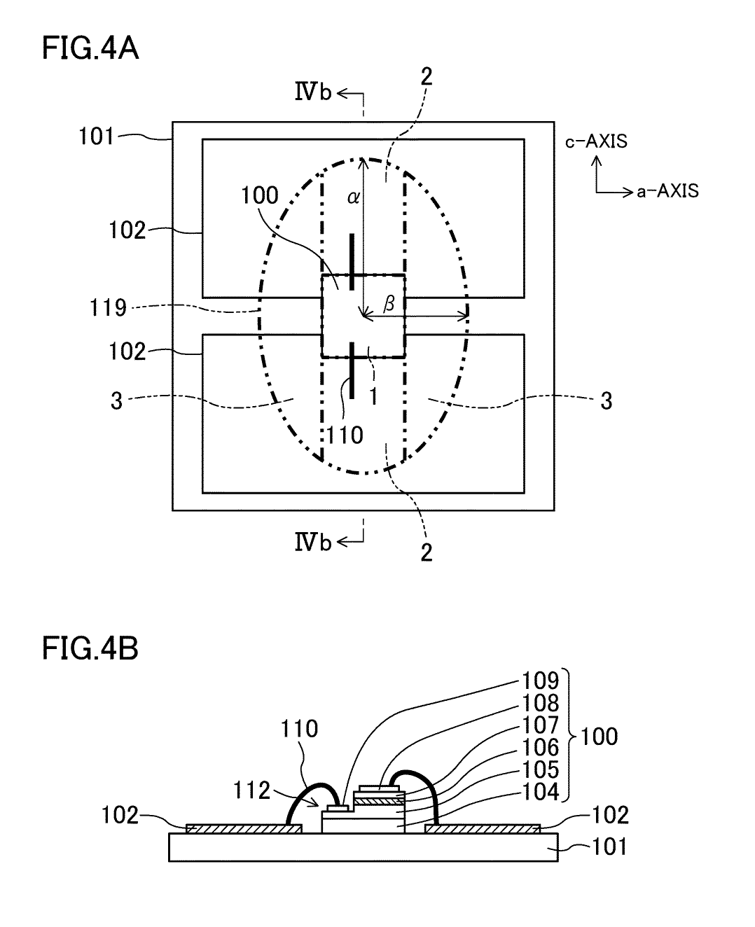

As illustrated in FIGS. 4A and 4B, instead of the flip-chip structure, a wire bonding structure can be employed in a first variation of this embodiment. In this case, a semiconductor light emitting chip 100 is held with the substrate 104 opposed to the surface of the mounting substrate 101. The p-side and n-side electrodes 108 and 109 are electrically connected through wires 110 made of gold (Au) to the interconnect electrodes 102 on the mounting substrate 101.

As such, the flip-chip structure and the wire bonding structure are different in terms of their processes used to connect the p-side and n-side electrodes 108 and 109 to the interconnect electrodes 102 on the mounting substrate 101. However, the other configuration in the first variation is substantially similar to that in the first embodiment, and when the embodiment of the present disclosure is used, operational advantages in the first variation are also similar to those in the first embodiment. Therefore, the flip-chip structure will be described hereinafter.

The substrate 104 may be a hexagonal m-plane GaN substrate, a hexagonal m-plane SiC substrate having a surface on which an m-plane GaN layer is formed, or an r-plane sapphire substrate, an m-plane sapphire substrate, or an a-plane sapphire substrate having a surface on which an m-plane GaN layer is formed. Furthermore, the substrate 104 may be removed.

The n-type nitride semiconductor layer 105 is made of, e.g., n-type AlᵤGaᵥIn_{w}N (where 0≦u, v, w≦1 and u+v+w=1). For example, silicon (Si) can be used as an n-type dopant.

The active layer 106 includes a plurality of barrier layers made of In_{y}Ga_{1-Y}N (where 0≦Y<1), and at least one well layer vertically interposed between an adjacent pair of the barrier layers and made of InₓGa₁₋ₓN (where 0<X≦1). The well layer included in the active layer 106 may be a single layer. Alternatively, the active layer 106 may have a multiple quantum well (MQW) structure in which well layers and barrier layers are alternately stacked. The wavelength of light emitted from the semiconductor light emitting chip 100 depends on the In content ratio x of an InₓGa₁₋ₓN semiconductor that is a semiconductor composition of the well layer.

The p-type nitride semiconductor layer 107 is made of, e.g., a p-type AlₛGaₜN (where 0≦s, t≦1 and s+t=1) semiconductor. For example, magnesium (Mg) can be used as a p-type dopant. As the p-type dopant, instead of Mg, zinc (Zn) or beryllium (Be), for example, may be used. The Al content ratio s of the p-type nitride semiconductor layer 107 may be uniform along the thickness thereof, or may vary along the thickness thereof in a continuous or stepwise manner. Specifically, the thickness of the p-type nitride semiconductor layer 107 is, e.g., about 0.05-2 μm. The Al content ratio s of a portion of the p-type nitride semiconductor layer 107 near an upper surface thereof, i.e., a portion thereof near the interface between the p-type nitride semiconductor layer 107 and the p-side electrode 108, may be zero. In other words, the portion of the p-type nitride semiconductor layer 107 near the upper surface thereof may be made of GaN. In this case, GaN may contain a high concentration of p-type impurities, and may function as a contact layer with the p-side electrode 108.

The p-side electrode 108 may cover substantially the entire surface of the p-type nitride semiconductor layer 107. The p-side electrode 108 is made of, e.g., a layered structure (Pd/Pt) in which a palladium (Pd) layer and a platinum (Pt) layer are stacked. In order to increase the reflectivity of emitted light, a layered structure (Ag/Pt) in which a silver (Ag) layer and a platinum (Pt) layer are stacked, or a layered structure (Pd/Ag/Pt) in which a Pd layer, an Ag layer, and a Pt layer are sequentially stacked may be used as the p-side electrode 108.

The n-side electrode 109 is made of, e.g., a layered structure (Ti/Pt) in which a titanium (Ti) layer and a platinum (Pt) layer are stacked. In order to increase the reflectivity of emitted light, a layered structure (Ti/Al/Pt) in which a Ti layer, an Al layer, and a Pt layer are sequentially stacked may be used.

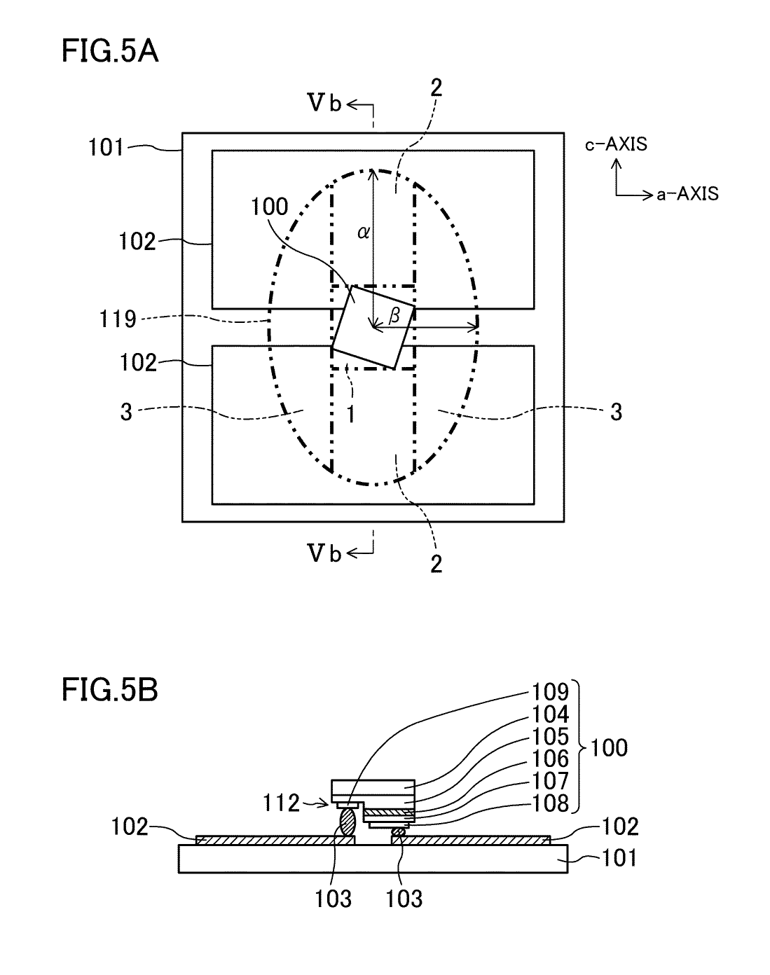

The semiconductor light emitting chip 100 illustrated in FIGS. 3A and 3B is one of square or rectangular pieces into which a wafer including stacked semiconductor layers is singulated along the a- and c-axes. In this case, a c-plane of a nitride semiconductor is easily cleaved, and thus, a singulation process step can be simplified. Alternatively, as illustrated in a second variation in FIGS. 5A and 5B, the semiconductor light emitting chip 100 may be one of pieces into which the wafer is singulated along directions inclined from the a- and c-axes. In this case, planes that are difficult to be cleaved are exposed at the side surfaces of the semiconductor light emitting chip 100. This exposure tends to cause the side surfaces of the semiconductor light emitting chip 100 to be uneven. The uneven surfaces enhance the light extraction efficiency at which emitted light is extracted from the side surfaces.

Features of the first embodiment are the reflection properties of the surface of the mounting substrate 101 (hereinafter referred to as the mounting surface), and the layout of components placed on the mounting surface. The reflection properties of the mounting surface of the mounting substrate 101, and the layout of components placed on the mounting surface will be described hereinafter in detail.

As described above, light emitted from the semiconductor light emitting chip 100 including the active layer 106 having the m-plane as its principal surface (and the growth surface) and made of a nitride semiconductor has polarization characteristics. As a result, when the emitted light is viewed from the m-axis, a contour line along which the light intensities are equal forms a shape close to an elliptical shape having a radius along the c-axis perpendicular to the polarization direction of the light as a major axis radius α, and a radius along the a-axis corresponding to the polarization direction of the light as a minor axis radius β. Since, as described below, the radiation angle of light emitted along the c-axis perpendicular to the polarization direction of the light is about 160°, and the radiation angle of light emitted along the a-axis corresponding to the polarization direction of the light is about 140°, the emitted light forms a shape close to an elliptical shape, and the ratio of the major axis of the elliptical shape to the minor axis thereof is 2 to 1. In other words, the major axis radius α is substantially twice as large as the minor axis radius β (α=2α). Furthermore, reflected light off the mounting surface also forms a shape close to an elliptical shape. In this case, the center of the elliptical shape substantially coincides with the center of gravity of the planar shape of the semiconductor light emitting chip 100. In FIG. 3A, the outline of an elliptical shape 119 shows the perimeter of a region illuminated principally with light emitted from the semiconductor light emitting chip 100 to the outside. The mounting surface strongly affects light reflected off a region in the elliptical shape 119. The mounting surface does not actually include such an elliptical shape. Here, suppose that the semiconductor light emitting chip 100 forms the shape of a square with sides having a length L when viewed in plan, and has a thickness T. A portion of the mounting surface having substantially the same area as the surface area of the semiconductor light emitting chip 100 significantly contributes to reflection, and thus, the following expression (1) holds.

παβ−L²=L²+4TL (1)

Here, the left-hand side of expression (1) corresponds to a value obtained by subtracting the area L² of the semiconductor light emitting chip 100 when viewed in plan from the area παβ of the elliptical shape 119, and can be considered as the area of a portion of the mounting surface that is located inside the elliptical shape 119 and can effectively contribute to reflection. The portion of the mounting surface is referred to as the mounting surface effective portion. The right-hand side of expression (1) corresponds to the area of a surface of the semiconductor light emitting chip 100 contributing to light extraction. Since the major axis radius α is twice as large as the minor axis radius β, the major axis radius α and the minor axis radius β of the elliptical shape 119 are represented by expressions (2) and (3), respectively, based on expression (1).

α=2√{(L²+2TL)/π} (2)

β=√{(L²+2TL)/π} (3)

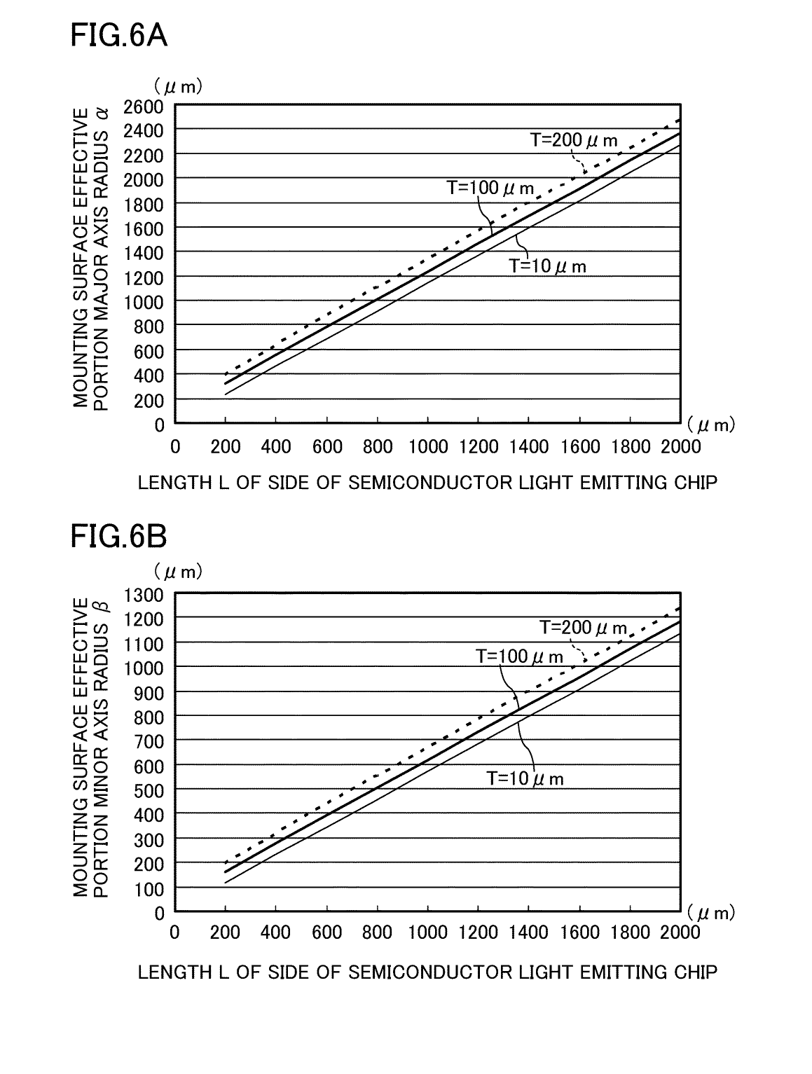

FIG. 6A illustrates the major axis radius α of the mounting surface effective portion as a function of the length L of each of the sides of the semiconductor light emitting chip 100, and FIG. 6B illustrates the minor axis radius β of the mounting surface effective portion thereas. In FIGS. 6A and 6B, the thickness T of the semiconductor light emitting chip 100 is varied among 10 μm, 100 μm, and 200 μm. As seen from FIGS. 6A and 6B, the major axis radius α and the minor axis radius β are substantially linear with respect to the length L of the side of the chip, and with increasing length L of the side, the major axis radius α and the minor axis radius β increase. Furthermore, with increasing chip thickness T, the major axis radius α and the minor axis radius β increase.

Similar statements apply to nonpolar planes other than the m-planes, and semipolar planes. As described above, light emitted from an active layer having a nonpolar plane, such as an m- or a-plane, or a semipolar plane, such as a (20-21), (20-2-1), (10-1-3), (11-22), -r-, or (11-22) plane, as a growth surface and made of a nitride semiconductor also has polarization characteristics. As a result, when the emitted light is viewed from the active layer, a contour line along which the light intensities are equal forms a shape close to an elliptical shape having a radius in a direction perpendicular to the polarization direction of the light as a major axis radius α, and a radius in the polarization direction of the light as a minor axis radius β. Furthermore, reflected light off the mounting surface also forms a shape close to an elliptical shape.

Next, the mounting surface of the mounting substrate 101 is sectioned into three regions.

As illustrated in FIG. 3A, when viewed in plan, a region of the mounting surface inside the elliptical shape 119 is sectioned into nine sub-regions using two straight lines parallel to the c-axis of the active layer 106 and two straight lines parallel to the a-axis thereof such that the semiconductor light emitting chip 100 is surrounded by the straight lines. One of the nine sub-regions containing the semiconductor light emitting chip 100 is a first region 1. Furthermore, a group of two of the nine sub-regions located outside the first region 1 and being adjacent to the first region 1 along the c-axis is a second region 2, and a group of six of the nine sub-regions except the first and second regions 1 and 2 is a third region 3.

The first region 1 is defined by the two straight lines parallel to the c-axis and the two straight lines parallel to the a-axis such that its area is minimum. A portion of the inner region of the elliptical shape 119 except the first region 1 corresponds to the mounting surface effective portion. In each of the semiconductor light emitting devices illustrated in FIGS. 3A-4B, the outline of the semiconductor light emitting chip 100 when viewed in plan coincides with the outline of the first region 1. On the other hand, in the semiconductor light emitting device illustrated in FIGS. 5A and 5B, the area of the first region 1 is larger than that of the semiconductor light emitting chip 100 when viewed in plan.

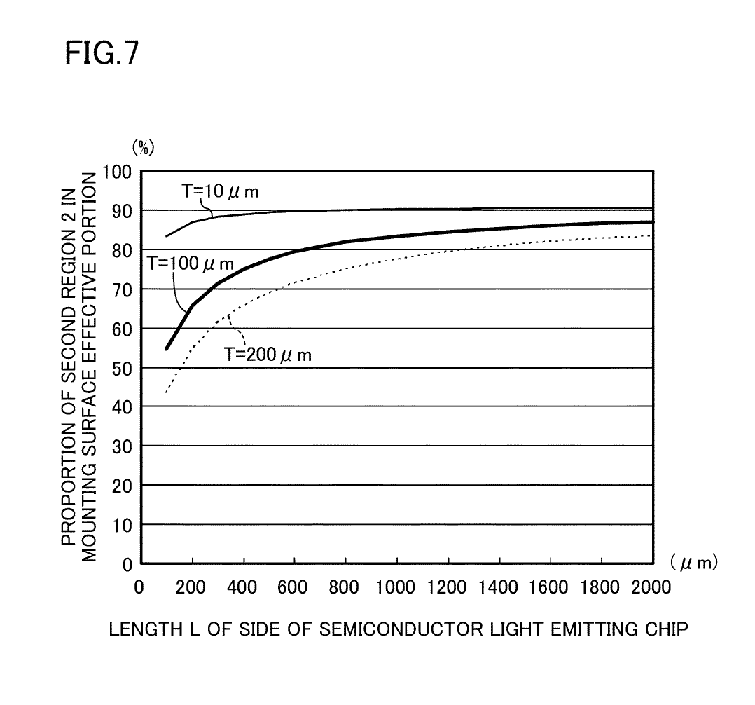

FIG. 7 illustrates the relationship between the proportion of the second region 2 in the mounting surface effective portion and the length L of a side of the semiconductor light emitting chip 100. The thickness T of the semiconductor light emitting chip 100 is varied among 10 μm, 100 μm, and 200 μm. With increasing length L of the side of the chip, the proportion of the second region 2 increases. Furthermore, with decreasing chip thickness T, the proportion of the second region 2 increases.

When the thickness T and the length L of the side are equal to each other (T=L), the proportion of the second region 2 is substantially 50%, and when the thickness T is less than the length L (T<L), the proportion of the second region 2 is higher than 50%. Therefore, when the thickness T is less than the length L (T<L), the second region 2 predominantly occupies the mounting surface effective portion.

When the thickness T is equal to the length L divided by six (T=L/6), the proportion of the second region 2 is substantially 80%, and when the thickness T is less than the length L divided by six (T<L/6), the proportion of the second region 2 is higher than 80%. Therefore, when the thickness T is less than the length L divided by six (T<L/6), the second region 2 very predominantly occupies the mounting surface effective portion.

The general size L of the semiconductor light emitting chip 100 is 200-1000 μm, and the chip thickness T is equal to or less than 150 μm. Thus, in these ranges, the proportion of the second region 2 is higher than 50%. In particular, when the chip size is increased to provide higher output power, the second region 2 grows in influence. In other words, in the semiconductor light emitting device including the semiconductor light emitting chip 100 including the active layer 106 having the m-plane as the growth surface, regions of the mounting surface of the mounting substrate 101 significantly contributing to reflection as a reflection surface correspond to the second region 2 illustrated in FIG. 3A. The present inventors found such findings.

Regions of the mounting substrate 101 illuminated with light from the active layer 106 and located laterally outward from the semiconductor light emitting chip 100 along the c-axis perpendicular to the polarization direction of the light are referred to as high polarization regions. Light reflected off the high polarization regions includes a large amount of light with electric field intensity varying along the a-axis corresponding to the polarization direction of the light from the semiconductor light emitting chip 100. The high polarization regions include, for example, the second region 2. In this embodiment, the surface of the second region 2 is covered with the plurality of interconnect electrodes 102. The proportion of mirror reflection from the surface of a portion of each of the interconnect electrodes 102 on at least the second region 2 is higher than or equal to 15%. The proportion of mirror reflection from the surface of a portion of each of the interconnect electrodes 102 located on a region of the mounting surface except the second region 2 may be less than 15%. The proportion of mirror reflection denotes the proportion of mirror reflectivity to the sum of the mirror reflectivity and diffuse reflectivity. The proportion of mirror reflection from the surface of the portion of each of the interconnect electrodes 102 on at least the second region 2 may be higher than or equal to 50%. A constituent material of the interconnect electrode 102 may be different from that (principal material) of the mounting substrate 101. In other words, a material from which the proportion of mirror reflection is high is placed on the second region 2 predominantly occupying the mounting surface effective portion to maintain the degree of polarization of light from the semiconductor light emitting device, thereby reducing a decrease in the degree of polarization.

Furthermore, regions of the mounting substrate 101 illuminated with light from the active layer 106 except the high polarization regions are referred to as low polarization regions. Light reflected off the low polarization regions includes a large amount of light with electric field intensity varying in directions other than the direction along the a-axis. The low polarization regions include, for example, the third region 3. In this embodiment, at least one portion of the surface of the third region 3 has lower mirror reflectivity than the second region 2. The interconnect electrodes 102 are not formed, for example, on portions of the third region 3 located laterally outward from the first region 1, and portions of the surface of the mounting substrate 101 or another insulating layer on the portions of the third region 3 are exposed. The proportion of mirror reflection from at least one portion of the third region 3 may be lower than that from the second region 2, and a material different from the principal material of the mounting substrate 101 may be exposed.

When, as such, a material having low mirror reflectivity is placed on the third region 3 that does not predominantly contribute to reflection as a reflection surface off which emitted light is reflected, this can also reduce a decrease in the degree of polarization of the emitted light.

Here, the interconnect electrodes 102 may each have a surface roughness equal to or less than 50 nm. This allows the mirror reflectivity of the surface of each of the interconnect electrodes 102 to be higher than or equal to 50%. When the mirror reflectivity of the surface of the interconnect electrode 102 is higher than or equal to 50%, this can reduce a decrease in the degree of polarization of light reflected off the second region 2.

Furthermore, the area of at least one portion of the surface of the third region 3 having lower mirror reflectivity than the second region 2 may be 10% or less of the area of the mounting surface effective portion. Specifically, the set area of the portion of the surface of the third region 3 having lower mirror reflectivity than the second region 2 may be set to the value satisfying the following expression (4):

Set Area<(L²+4TL)/10 (4)

where L is the length of a side of the semiconductor light emitting chip 100, and T is the thickness of the chip 100.

An insulative material, such as alumina (aluminum oxide) or aluminum nitride (AlN), a metal material, such as aluminum (Al), copper (Cu), or tungsten (W), a semiconductor material, such as silicon (Si) or germanium (Ge), or a composite of the materials can be used as the principal material forming the mounting substrate 101.

When the principal material of the mounting substrate 101 is an insulative material, such as alumina or AlN, metal, such as aluminum (Al), silver (Ag), gold (Au), or copper (Cu), may be used as a material of the interconnect electrodes 102 formed on at least the second region 2.

When the principal material of the mounting substrate 101 is a metal material, such as Al, Cu, or W, or a semiconductor material, such as Si or Ge, the surface of the mounting substrate 101 may be covered with an insulating film, and then, metal films made of, e.g., Al, Ag, Au, or Cu may be selectively formed, as the interconnect electrodes 102, on at least the second region 2. In this case, for example, a silicone resin containing fine particles made of, e.g., titanium dioxide (TiO₂), zinc oxide (ZnO), or silicon dioxide (SiO₂) can be used for the insulating film.

A composite obtained by placing ceramic, such as alumina, on the surface of a metal film can be used as the mounting substrate 101. When the principal material of the mounting substrate 101 is a metal, such as Al, Cu, or W, a portion of the principal material itself corresponding to the second region 2 may be exposed.

By contrast, a material having, e.g., Al or Ag as the main ingredient can be used as a constituent material of each of the interconnect electrodes 102. The proportion of mirror reflection from each of the interconnect electrodes 102 is higher than or equal to 15%. As described above, the interconnect electrode 102 may have a surface roughness equal to or less than 100 nm. When the interconnect electrode 102 has a surface roughness equal to or less than 100 nm, this allows the proportion of mirror reflection from the interconnect electrode 102 to be higher than or equal to 50%.

In this embodiment, a region of the mounting surface of the mounting substrate 101 outside the elliptical shape 119 does not significantly affect operating characteristics of the semiconductor light emitting device. Therefore, an optional material or component (electronic component) may be placed on the region outside the elliptical shape 119.

As described above, according to the first embodiment, while a decrease in the degree of polarization of light reflected off the mounting surface of the mounting substrate 101 on which the semiconductor light emitting chip 100 is held is reduced, a material or component decreasing the degree of polarization of the reflected light can be appropriately placed on the mounting surface.

(Fabrication Method)

A method for fabricating a semiconductor light emitting device according to the first embodiment will be described hereinafter with reference to FIGS. 3A and 3B.

First, an n-type nitride semiconductor layer 105 is epitaxially grown on the principal surface of a substrate 104 having an m-plane as its principal surface and made of n-type GaN by metal organic chemical vapor deposition (MOCVD) or any other method. Specifically, for example, silicon (Si) is used as an n-type dopant, trimethylgallium (TMG (Ga(CH₃)₃)) being a gallium source, and ammonia (NH₃) being a nitrogen source are supplied to the substrate 104, and the about 1-3-μm-thick n-type nitride semiconductor layer 105 made of GaN is formed at growth temperatures approximately higher than or equal to 900° C. and equal to or less than 1100° C. In this stage, the substrate 104 is a substrate at the wafer level, and a plurality of light emitting structures forming semiconductor light emitting devices can be fabricated at once.

Next, an active layer 106 made of a nitride semiconductor is grown on the n-type nitride semiconductor layer 105. The active layer 106 has an InGaN/GaN multiple quantum well (MQW) structure in which, for example, 15-nm-thick well layers made of In₁₋ₓGaₓN and 10-nm-thick barrier layers made of GaN are alternately stacked. When the well layers made of In₁₋ₓGaₓN are formed, the growth temperatures may be decreased to about 700-800° C. to ensure incorporation of In into the well layers being grown. The wavelength of emitted light is selected based on the intended use of the semiconductor light emitting device, and the In content ratio x is determined based on the wavelength. For example, when the wavelength is 450 nm (blue light wavelength), the In content ratio x is determined to be 0.25-0.27. When the wavelength is 520 nm (green light wavelength), the In content ratio x is determined to be 0.40-0.42. When the wavelength is 630 nm (red light wavelength), the In content ratio x is determined to be 0.56-0.58.

Next, a p-type nitride semiconductor layer 107 is epitaxially grown on the active layer 106. Specifically, for example, Cp2Mg (bis(cyclopentadienyl) magnesium) is used as p-type impurities, TMG and NH₃ are supplied, as materials, to the substrate 104, and the about 50-500-nm-thick p-type nitride semiconductor layer 107 made of p-type GaN is formed on the active layer 106 at growth temperatures approximately higher than or equal to 900° C. and equal to or less than 1100° C. The p-type nitride semiconductor layer 107 may contain an about 15-30-nm-thick p-type AlGaN layer. The formation of the p-type AlGaN layer can reduce the overflow of electrons that are carriers. An undoped GaN layer may be formed between the active layer 106 and the p-type nitride semiconductor layer 107.

Next, in order to activate Mg with which the p-type nitride semiconductor layer 107 is doped, the p-type nitride semiconductor layer 107 is thermally treated at temperatures of about 800-900° C. for about 20 minutes.

Next, a semiconductor layered structure including the substrate 104, the n-type nitride semiconductor layer 105, the active layer 106, and the p-type nitride semiconductor layer 107 is selectively etched by lithography and dry etching using a chlorine (Cl₂) gas. Thus, a recess 112 is formed by removing a portion of the p-type nitride semiconductor layer 107, a portion of the active layer 106, and a portion of the n-type nitride semiconductor layer 105 to expose a region of the n-type nitride semiconductor layer 105.

Next, an n-side electrode 109 is selectively formed on and in contact with the exposed region of the n-type nitride semiconductor layer 105. Here, for example, a multilayer film (Ti/Pt layer) of titanium (Ti) and platinum (Pt) is formed as the n-side electrode 109.

Next, a p-side electrode 108 is selectively formed on and in contact with the p-type nitride semiconductor layer 107. For example, a multilayer film (Pd/Pt layer) of palladium (Pd) and platinum (Pt) is formed as the p-side electrode 108. Thereafter, heat treatment is performed to alloy a region between the Ti/Pt layer and the n-type nitride semiconductor layer 105 and a region between the Pd/Pt layer and the p-type nitride semiconductor layer 107. The order in which the n-side electrode 109 and the p-side electrode 108 are formed is not particularly limited.

Next, a (back) surface of the substrate 104 opposite to the n-type nitride semiconductor layer 105 is polished to reduce the thickness of the substrate 104 by a predetermined amount.

The wafer-level substrate 104 is singulated into individual semiconductor light emitting chips 100 corresponding to a plurality of semiconductor light emitting devices fabricated as above. Examples of this singulation process include some processes, such as laser dicing and cleavage. The individual semiconductor light emitting chips 100 into which the substrate 104 has been singulated are mounted on a mounting surface of a mounting substrate 101. Here, a flip-chip structure will be described.

First, the mounting substrate 101 is prepared. As described above, an insulative material, such as alumina or AlN, a metal material, such as Al or Cu, a semiconductor material, such as Si or Ge, or a composite of the materials can be used as the principal material of the mounting substrate 101. A metal material having, e.g., Al or Ag as the main ingredient can be used as interconnect electrodes 102.

A metal film for forming interconnect electrodes is formed on the surface of the mounting substrate 101 through a film formation process, such as sputtering or plating. Thereafter, a desired resist pattern is formed on the formed metal film by, e.g., lithography. In this case, the resist pattern is designed such that interconnect electrodes 102 obtained by patterning the metal film are formed on at least a second region 2. The resist pattern is designed, for example, such that at least the second region 2 is covered with the interconnect electrodes 102, and the surface of the third region 3 of the mounting substrate 101 and the surface of a region thereof located outward from the third region 3, or portions of an insulating film located on the third region 3 and outward from the third region 3 are partially exposed. Thereafter, the resist pattern is transferred to the metal film by dry etching or wet etching to form interconnect electrodes 102 each having a desired electrode pattern. Next, a plurality of bumps 103 are formed on predetermined portions of the interconnect electrodes 102. Gold (Au) is preferably used as a constituent material of the bumps 103. The bumps 103 each having a diameter of about 40-80 μm can be formed with a bump bonder. The bumps 103 can be formed by Au plating instead of with a bump bonder. The surfaces of the electrodes of the semiconductor light emitting chip 100 are connected onto the interconnect electrodes 102 on which the plurality of bumps 103 are formed as above by, e.g., ultrasonic welding.

As such, the semiconductor light emitting device according to the first embodiment can be obtained.

### Second Embodiment

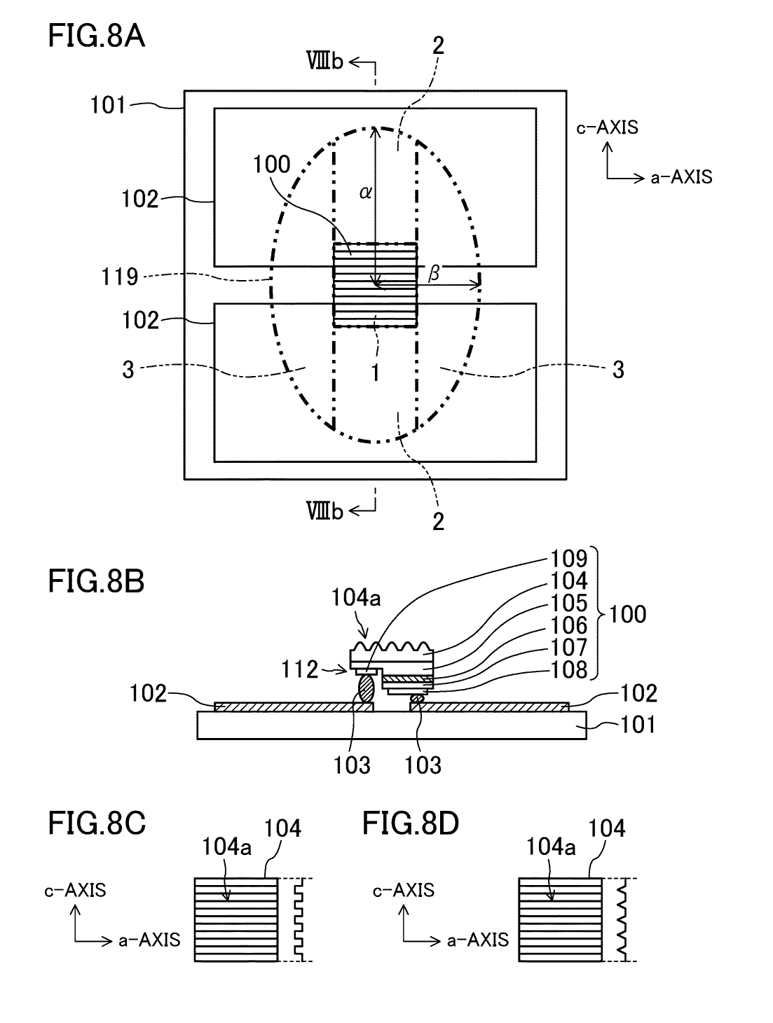

A semiconductor light emitting device according to a second embodiment of the present disclosure will be described hereinafter with reference to FIGS. 8A-8D. In FIG. 8A-8D, the same characters as those in FIGS. 3A and 3B are used to represent equivalent components, and thus, description thereof is omitted. The same applies to the following embodiments. Here, the difference between the first and second embodiments will be described.

As illustrated in FIGS. 8A and 8B, the second embodiment is different from the first embodiment in that a surface of a semiconductor light emitting chip 100, specifically, a light extraction surface of a substrate 104 opposite to a mounting substrate 101, has stripe-shaped raised/recessed portions 104a when viewed in plan. Here, the raised/recessed portions 104a have a generally semicircular shape when viewed in cross section taken along a direction perpendicular to the direction of extension of stripes.

In the second embodiment, the stripe-shaped raised/recessed portions 104a formed on the back surface of the substrate 104 corresponding to a surface thereof from which emitted light is extracted can improve the light extraction efficiency. The direction of extension of the stripes is inclined at an angle θ with respect to the a-axis of an active layer 106. When the angle θ from the a-axis is greater than or equal to 0° and less than 5°, a decrease in the degree of polarization of emitted light is reduced. Furthermore, the angle θ from the a-axis may be substantially 0°.

The raised/recessed portions 104a can be formed on the back surface of the substrate 104 by reducing the thickness of the substrate 104, then forming a resist pattern by lithography, and processing the back surface of the substrate 104 into stripes by dry etching using a gas containing chlorine.

FIGS. 8C and 8D illustrate variations of the raised/recessed portions 104a. FIG. 8C illustrates example raised/recessed portions 104a having a rectangular shape when viewed in cross section taken along the direction perpendicular to the direction of extension of stripes. FIG. 8D illustrates example raised/recessed portions 104a having a triangular shape when viewed in cross section taken along the direction perpendicular to the direction of extension of stripes.

A mounting surface effective portion of the second embodiment also has a configuration similar to that of the first embodiment. Specifically, at least the surface of a second region 2 defined inside an elliptical shape 119 is covered with interconnect electrodes 102 from each of which the proportion of mirror reflection is higher than or equal to 15%. Furthermore, the proportion of mirror reflection from the surface of each of the interconnect electrodes 102 may be higher than or equal to 50%.

Although, also in this embodiment, a portion of the surface of the third region 3 has lower mirror reflectivity than the second region 2, a decrease in the degree of polarization is less affected by the third region 3. Thus, while a decrease in the degree of polarization of emitted light reflected off the mounting surface of the mounting substrate 101 is reduced, a material or component decreasing the degree of polarization can be appropriately placed on the mounting surface.

Moreover, in this embodiment, stripe-shaped raised/recessed portions 104a are formed on the back surface of the substrate 104 corresponding to the light extraction surface, thereby increasing light output.

Although, in this embodiment, only a flip-chip structure was described, a wire bonding structure can also provide similar advantages.

### Third Embodiment

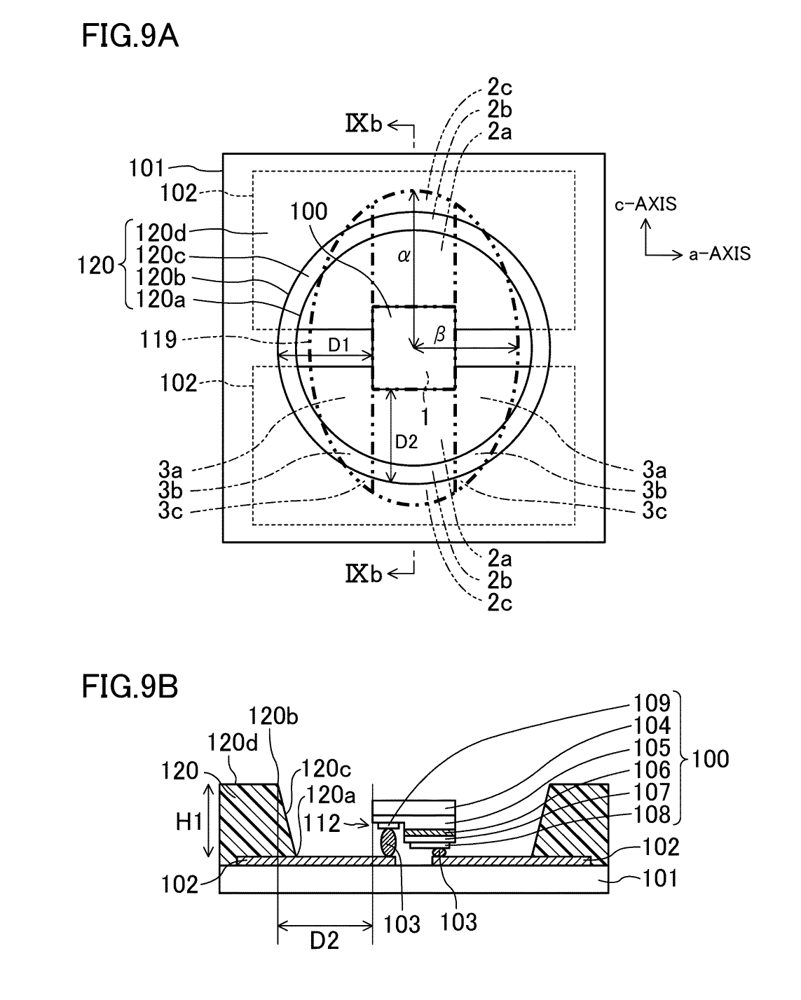

A semiconductor light emitting device according to a third embodiment of the present disclosure will be described hereinafter with reference to FIGS. 9A and 9B. Here, the difference between the first and third embodiments will be described.

As illustrated in FIGS. 9A and 9B, the third embodiment is different from the first embodiment in that a reflection member 120 is placed on a mounting surface of a mounting substrate 101. The reflection member 120 has a cavity. In some cases, the reflection member 120 controls the directivity and radiation pattern of emitted light from a semiconductor light emitting chip 100. When the top surface of the semiconductor light emitting chip 100 is encapsulated with a transparent member, such as a silicone resin, the reflection member 120 functions as a cup (container) for the transparent member injected onto the top surface thereof. If the reflection member 120 serves to control the directivity and radiation pattern of emitted light from a semiconductor light emitting chip 100, the reflection member 120 is referred to also as a reflector.

The reflection member 120 has an opening 120a in its lower end surface being in contact with the mounting surface, an opening 120b in its upper end surface, a reflection surface 120c opposed to the side surfaces of the semiconductor light emitting chip 100, and an upper surface 120d. A material having a high light reflectivity is preferably used for the reflection surface 120c of the reflection member 120. For example, aluminum (Al) can be used.

Although, in the third embodiment, each of the openings of the reflection member 120 is circular when viewed in plan, this shape is merely an example. For example, the opening of the reflection member 120 may be in the shape of an ellipse, an oval, or a polygon with three or more sides when viewed in plan.

Assume that H1 is the height of the reflection member 120, D1 is the distance from a side surface of the semiconductor light emitting chip 100 to the perimeter of the opening 120b in the upper end surface of the reflection member 120 along the a-axis, and D2 is the distance from a side surface of the semiconductor light emitting chip 100 to the perimeter of the opening 120b in the upper end surface of the reflection member 120 along the c-axis. Conditions where emitted light from the semiconductor light emitting chip 100 is effectively reflected off the reflection surface 120c of the reflection member 120 are that the radiation angle of light emitted along the c-axis is 160° and the radiation angle of light emitted along the a-axis is 140°, and thus, the distance D1 along the a-axis and the distance D2 along the c-axis are respectively given by the following expressions (5) and (6).

D1=H1·tan(140°/2)=2.75×H1 (5)

D2=H1·tan(160°/2)=5.67×H1 (6)

When the distances D1 and D2 are less than the values obtained from the expressions (5) and (6), respectively, the reflection surface 120c of the reflection member 120 strongly affects emitted light from the semiconductor light emitting chip 100. Therefore, when the reflection member 120 is provided in order to control the directivity and radiation pattern of light, the distances D1 and D2 are set less than the values obtained from the expressions (5) and (6), respectively.

The second region 2 is further sectioned into three portions: a portion 2a corresponding to an exposed portion of the surface of the mounting substrate 101; a portion 2b corresponding to the reflection surface 120c of the reflection member 120; and a portion 2c corresponding to the upper surface 120d of the reflection member 120. The portion 2b is a portion of the second region 2 on which the reflection surface 120c is located when viewed in plan from above the mounting substrate 101. In other words, the portion 2b corresponds to a region of the reflection surface 120c corresponding to the second region 2. The portion 2c is a portion of the second region 2 on which the upper surface 120d is located when viewed in plan from above the mounting substrate 101. In other words, the portion 2c corresponds to a portion of the upper surface 120d corresponding to the second region 2.

Similarly, the third region 3 is sectioned into three portions: a portion 3a corresponding to an exposed portion of the surface of the mounting substrate 101; a portion 3b corresponding to the reflection surface 120c of the reflection member 120; and a portion 3c corresponding to the upper surface 120d of the reflection member 120. The portion 3b is a portion of the third region 3 on which the reflection surface 120c is located when viewed in plan from above the mounting substrate 101. In other words, the portion 3b corresponds to a portion of the reflection surface 120c corresponding to the third region 3. The portion 3c is a portion of the third region 3 on which the upper surface 120d is located when viewed in plan from above the mounting substrate 101. In other words, the portion 3c corresponds to a portion of the upper surface 120d corresponding to the third region 3. Here, while the portions 2c and 3c are regions inside the elliptical shape 119, emitted light is not incident upon the portions 2c and 3c, and thus, the portions 2c and 3c do not function as a reflection surface off which light is reflected.

Specifically, in the third embodiment, the distance D2 in the second region 2 is less than 5.67×H1 represented by expression (6). Furthermore, the surfaces of the portions 2a and 2b of the second region 2 are covered with a material from which the proportion of mirror reflection is higher than or equal to 15%. Alternatively, the surfaces of the portions 2a and 2b may be covered with a material from which the proportion of mirror reflection is higher than or equal to 50%.

Also in this embodiment, a portion of the surface of the third region 3 has lower mirror reflectivity than the second region 2. However, a decrease in the degree of polarization is less affected by the third region 3, and thus, while a decrease in the degree of polarization of emitted light reflected off the mounting surface of the mounting substrate 101 is reduced, a material or component decreasing the degree of polarization can be appropriately placed on the mounting surface.

Furthermore, the reflection member 120 placed on the mounting surface of the mounting substrate 101 can control the directivity and radiation pattern of emitted light. While, in this embodiment, only the flip-chip structure was described, a wire bonding structure can also provide similar advantages.

### Fourth Embodiment

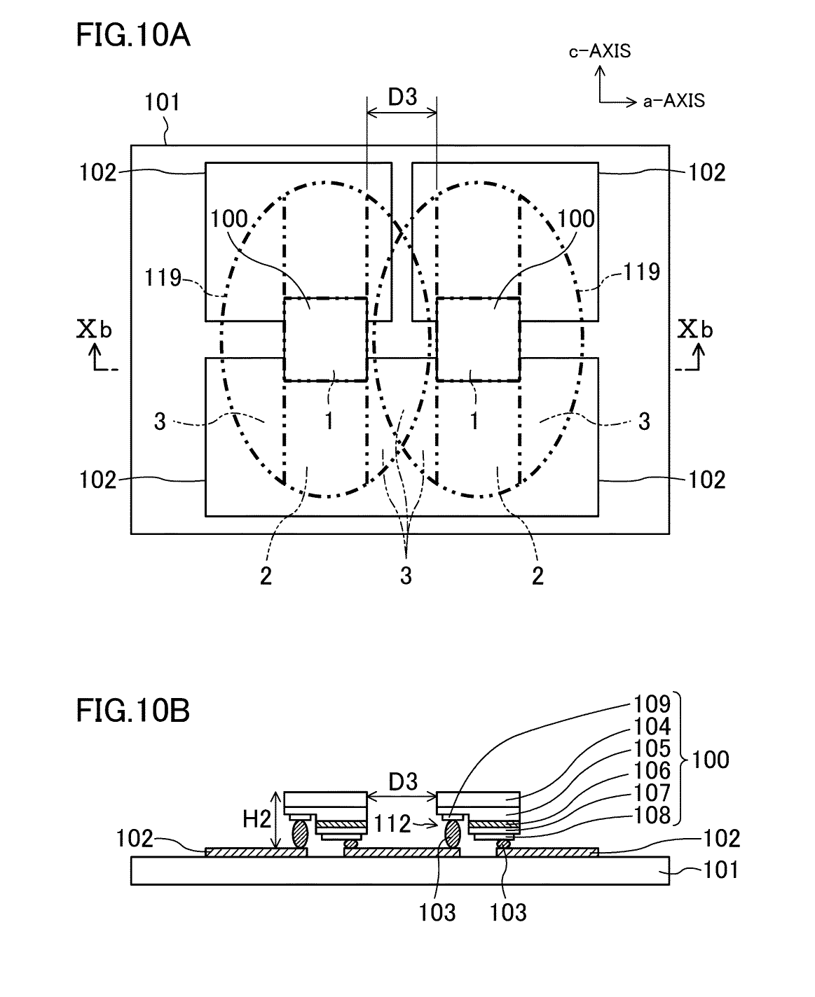

A semiconductor light emitting device according to a fourth embodiment of the present disclosure will be described hereinafter with reference to FIGS. 10A and 10B. Here, the difference between the first and fourth embodiments will be described.

As illustrated in FIGS. 10A and 10B, the fourth embodiment is different from the first embodiment in that a plurality of semiconductor light emitting chips 100 are mounted on a mounting substrate 101. Here, two semiconductor light emitting chips 100 are substantially aligned along the a-axis. The number of the semiconductor light emitting chips 100 is not limited to two, and three or more semiconductor light emitting chips 100 may be substantially aligned along the a-axis.

As described above, the radiation angle of light emitted along the a-axis is less than that of light emitted along the c-axis, and thus, when the semiconductor light emitting chips 100 are aligned along the a-axis, emitted light waves from the adjacent semiconductor light emitting chips 100 are less likely to interfere with each other. When emitted light from one of the semiconductor light emitting chips 100 enters the other semiconductor light emitting chip 100, this causes problems, such as a decrease in light output due to light absorption, and variations in directivity and radiation pattern due to light reflection. However, when the semiconductor light emitting chips 100 are aligned along the a-axis, the distance between the semiconductor light emitting chips 100 emitting light waves that interfere with each other is equal to or less than half of that when the semiconductor light emitting chips 100 are aligned along the c-axis. This enables a dense arrangement of a plurality of semiconductor light emitting chips 100.

When D3 is the distance between the semiconductor light emitting chips 100 adjacent to each other along the a-axis, the distance D3′ between the semiconductor light emitting chips 100 emitting light waves that interfere with each other is given by the following expression (7), based on the fact that the radiation angle of light emitted along the a-axis is 140°.

D3′=H2·tan(140°/2)=2.75×H2 (7)

where H2 is the height from the mounting surface of the mounting substrate 101 to an upper surface of each of the semiconductor light emitting chips 100.

Therefore, when the distance D3′ is equal to or less than 2.75×H2, light emitted from a side surface of one of the adjacent semiconductor light emitting chips 100 and directed upward from the semiconductor light emitting device interferes with light emitted from the other semiconductor light emitting chip 100.

Also when a mounting surface effective portion inside an elliptical shape 119 formed by one of the semiconductor light emitting chips 100 overlaps an elliptical shape 119 formed by the other semiconductor light emitting chip 100, light waves emitted from the semiconductor light emitting chips 100 interfere with each other.

The largest a-axis width of a group of three of sub-regions of a third region 3 that are adjacent along the c-axis, i.e., the distance D3″, is given by (minor axis radius β)−L/2, where L is the length of a side of each of the semiconductor light emitting chips 100, and thus, is given by the following expression (8) based on expression (3).

D3″=√{(L²+2TL)/π}−L/2 (8)

where T is the thickness of the semiconductor light emitting chip 100.

Specifically, a greater one of the distances D3′ and D3″ corresponds to a boundary value up to which light waves emitted from the semiconductor light emitting chips 100 interfere with each other.

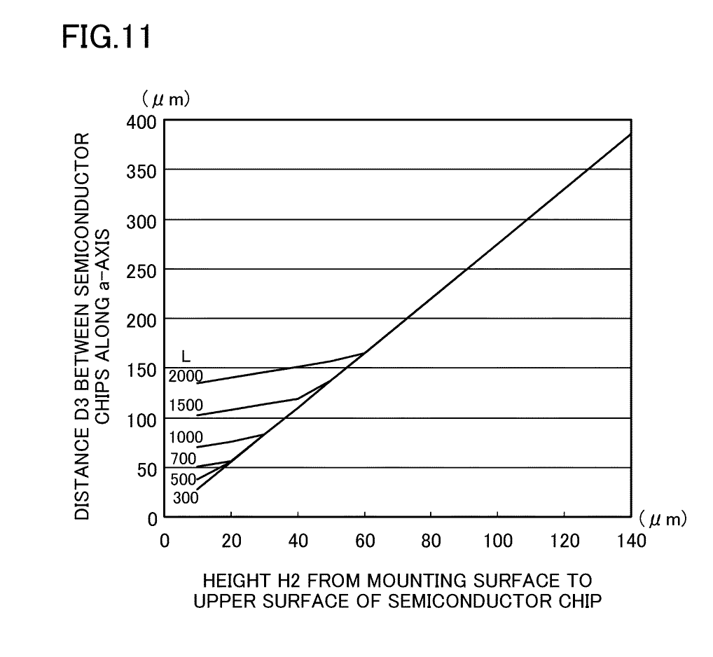

FIG. 11 illustrates the relationship between the height H2 from the mounting surface of the mounting substrate 101 to the upper surface of each of the semiconductor light emitting chips 100 and the distance D3 between the semiconductor light emitting chips 100 emitting light waves that interfere with each other along the a-axis. When the distance D3 is less than the corresponding value on a corresponding one of line graphs illustrated in FIG. 11, light waves emitted from the semiconductor light emitting chips 100 interfere with each other. The length L of a side of each of the semiconductor light emitting chips 100 is varied among 300 μm, 500 μm, 700 μm, 1000 μm, 1500 μm, and 2000 μm.

As seen from FIG. 11, with increasing height H2 of each of the semiconductor light emitting chips 100, light emitted from one of the adjacent semiconductor light emitting chips 100 and directed upward from the semiconductor light emitting device tends to interfere with light emitted from the other semiconductor light emitting chip 100. With increasing length L of a side of each of the semiconductor light emitting chips 100, light waves emitted from the semiconductor light emitting chips 100 tends to interfere with each other, because mounting surface effective portions overlap each other.

Therefore, when the distance D3 is greater than a smaller one of the distances D3′ and D3″ based on expressions (7) and (8), this can reduce the light interference occurring either with increasing height H2 or with increasing length L.

Furthermore, when the distance D3 is greater than a greater one of the distances D3′ and D3″, this can reduce the light interference occurring both with increasing height H2 and with increasing length L.

In the fourth embodiment, the plurality of semiconductor light emitting chips 100 are preferably connected in series. When the semiconductor light emitting chips 100 are connected in parallel, the operating voltages of the plurality of semiconductor light emitting chips 100 need to be set substantially equal to one another; however, when the semiconductor light emitting chips 100 are connected in series, and the chips 100 have different operating voltages, this also allows the chips 100 to emit light.

According to this embodiment, the semiconductor light emitting device including the plurality of semiconductor light emitting chips 100 reduces the interference between light waves emitted from the adjacent semiconductor light emitting chips 100 while reducing a decrease in the degree of polarization of emitted light reflected off the mounting surface of the mounting substrate 101, thereby enabling dense integration.

While, in this embodiment, only the flip-chip structure was described, a wire bonding structure can also provide similar advantages.

### Fifth Embodiment

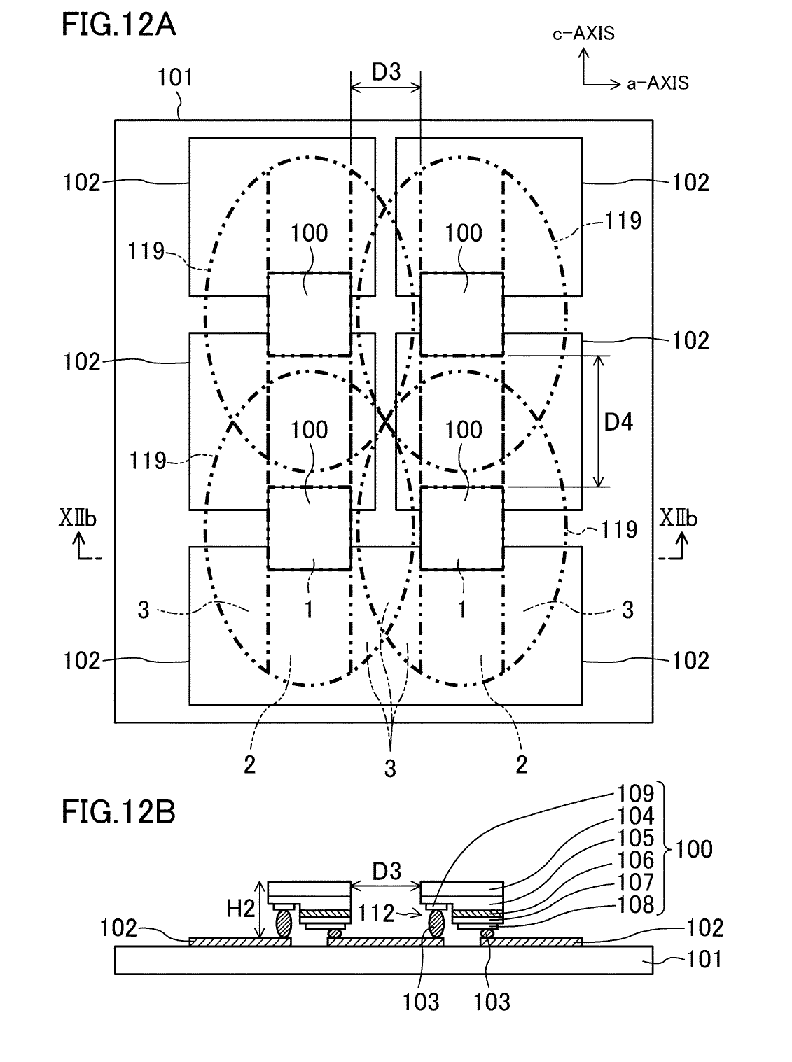

A semiconductor light emitting device according to a fifth embodiment of the present disclosure will be described hereinafter with reference to FIGS. 12A and 12B. Here, the difference between the fourth and fifth embodiments will be described.

As illustrated in FIGS. 12A and 12B, the fifth embodiment is different from the fourth embodiment in that a plurality of semiconductor light emitting chips 100 are arranged on a mounting substrate 101 in an array. Here, four semiconductor light emitting chips 100 are arranged in two rows and two columns along the a- and c-axes. The number of the semiconductor light emitting chips 100 is not limited to four, and five or more semiconductor light emitting chips 100 may be arranged in an array with two or more rows and two or more columns.

When D4 is the distance between two of the semiconductor light emitting chips 100 that are adjacent to each other along the c-axis, the distance D4′ between the adjacent semiconductor light emitting chips 100 emitting light waves that interfere with each other is given by the following expression (9), based on the fact that the radiation angle of light emitted along the c-axis is 160°.

D4′=H2·tan(160°/2)=5.67×H2 (9)

where H2 is the height from the mounting surface of the mounting substrate 101 to an upper surface of each of the semiconductor light emitting chips 100.

Therefore, when the distance D4′ is equal to or less than 5.67×H2, light emitted from a side surface of one of the semiconductor light emitting chips 100 and directed upward from the semiconductor light emitting device interferes with light emitted from another one of the semiconductor light emitting chips 100 adjacent to the one of the semiconductor light emitting chips 100 along the c-axis.

Also when a mounting surface effective portion inside an elliptical shape 119 formed by one of the semiconductor light emitting chips 100 overlaps an elliptical shape 119 formed by another one of the semiconductor light emitting chips 100 aligned with the one of the semiconductor light emitting chips 100 along the c-axis, light waves emitted from the semiconductor light emitting chips 100 interfere with each other.

The largest c-axis width of each of sub-regions of the second region 2, i.e., the distance D4″, is given by (major axis radius α)−L/2, where L is the length of a side of each of the semiconductor light emitting chips 100, and thus, is given by the following expression (10) based on expression (2).

D4″=√{(L²+2TL)/π}−L/2 (10)

where T is the thickness of the semiconductor light emitting chip 100.

Specifically, a greater one of the distances D4′ and D4″ corresponds to a boundary value up to which light waves emitted from the semiconductor light emitting chips 100 interfere with each other.

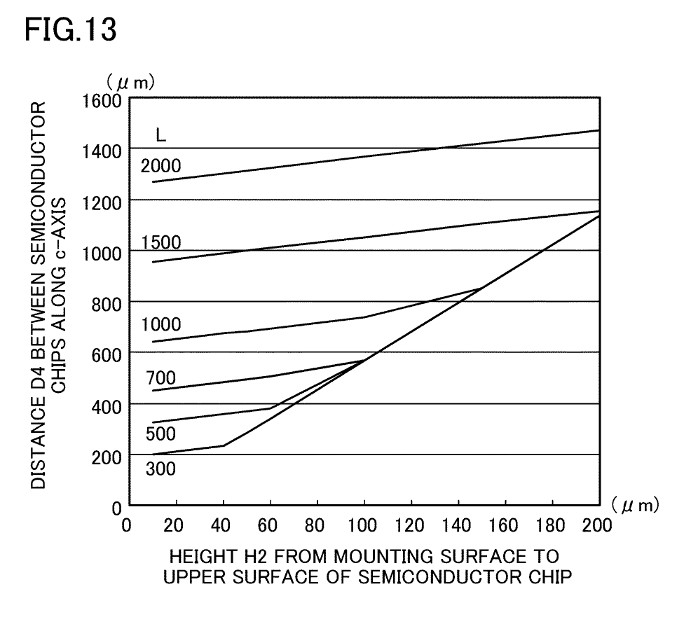

FIG. 13 illustrates the relationship between the height H2 from the mounting surface of the mounting substrate 101 to the upper surface of each of the semiconductor light emitting chips 100 and the distance D4 between two of the semiconductor light emitting chips 100 emitting light waves that interfere with each other along the c-axis. When the distance D4 is less than the corresponding value on a corresponding one of line graphs illustrated in FIG. 13, light waves emitted from the semiconductor light emitting chips 100 interfere with each other. The length L of a side of each of the semiconductor light emitting chips 100 is varied among 300 μm, 500 μm, 700 μm, 1000 μm, 1500 μm, and 2000 μm.

As seen from FIG. 13, with increasing height H2 of each of the semiconductor light emitting chips 100, light emitted from one of the semiconductor light emitting chips 100 and directed upward from the semiconductor light emitting device tends to interfere with light emitted from another one of the semiconductor light emitting chips 100 adjacent to the one of the semiconductor light emitting chips 100 along the c-axis. With increasing length L of a side of each of the semiconductor light emitting chips 100, light waves emitted from the semiconductor light emitting chips 100 tend to interfere with each other, because mounting surface effective portions overlap each other.

Comparison between FIG. 11 according to the fourth embodiment and FIG. 13 according to the fifth embodiment shows that light waves emitted from semiconductor light emitting chips 100 adjacent to each other along the c-axis more easily interfere with each other than those emitted from semiconductor light emitting chips 100 adjacent to each other along the a-axis.

In view of the above, when D3 is the distance between two of the semiconductor light emitting chips 100 that are adjacent to each other along the a-axis, and D4 is the distance between two of the semiconductor light emitting chips 100 that are adjacent to each other along the c-axis, the distance D3 along the a-axis may be smaller than the distance D4 along the c-axis (D3<D4). This can reduce the interference between light waves emitted from adjacent ones of the semiconductor light emitting chips 100.

Therefore, when the distance D3 along the a-axis is greater than a smaller one of the distances D3′ and D3″, this can reduce the light interference occurring either with increasing height H2 or with increasing length L.

Furthermore, when the distance D3 along the a-axis is greater than a greater one of the distances D3′ and D3″, this can reduce the light interference occurring both with increasing height H2 and with increasing length L.

When the distance D4 along the c-axis is greater than a smaller one of the distances D4′ and D4″, this can reduce the light interference occurring either with increasing height H2 or with increasing length L.

Furthermore, when the distance D4 along the c-axis is greater than a greater one of the distances D4′ and D4″, this can reduce the light interference occurring both with increasing height H2 and with increasing length L.

When the number of semiconductor light emitting chips 100 arranged along the a-axis is Na, and the number of semiconductor light emitting chips 100 arranged along the c-axis is Nc, the number Na of semiconductor light emitting chips 100 arranged along the a-axis may be greater than the number Nc of semiconductor light emitting chips 100 arranged along the c-axis (Na>Nc). Thus, even when semiconductor light emitting devices include the same total number of chips, some of the semiconductor light emitting devices in which the number Na is greater than the number Nc can provide denser integration of semiconductor light emitting chips 100 than other semiconductor light emitting devices in which the number Na is less than the number Nc.

According to the fifth embodiment, the semiconductor light emitting device including the plurality of semiconductor light emitting chips 100 reduces a decrease in the degree of polarization of emitted light reflected off the mounting surface of the mounting substrate 101, and furthermore, the semiconductor light emitting chips 100 are sparsely arranged along the c-axis along which the radiation angle of emitted light is large while being densely arranged along the a-axis along which the radiation angle of emitted light is smaller than that of emitted light along the c-axis. This reduces the interference between light waves emitted from adjacent ones of the semiconductor light emitting chips 100, thereby enabling dense integration.

While, in this embodiment, only the flip-chip structure was described, a wire bonding structure can also provide similar advantages.

### Sixth Embodiment

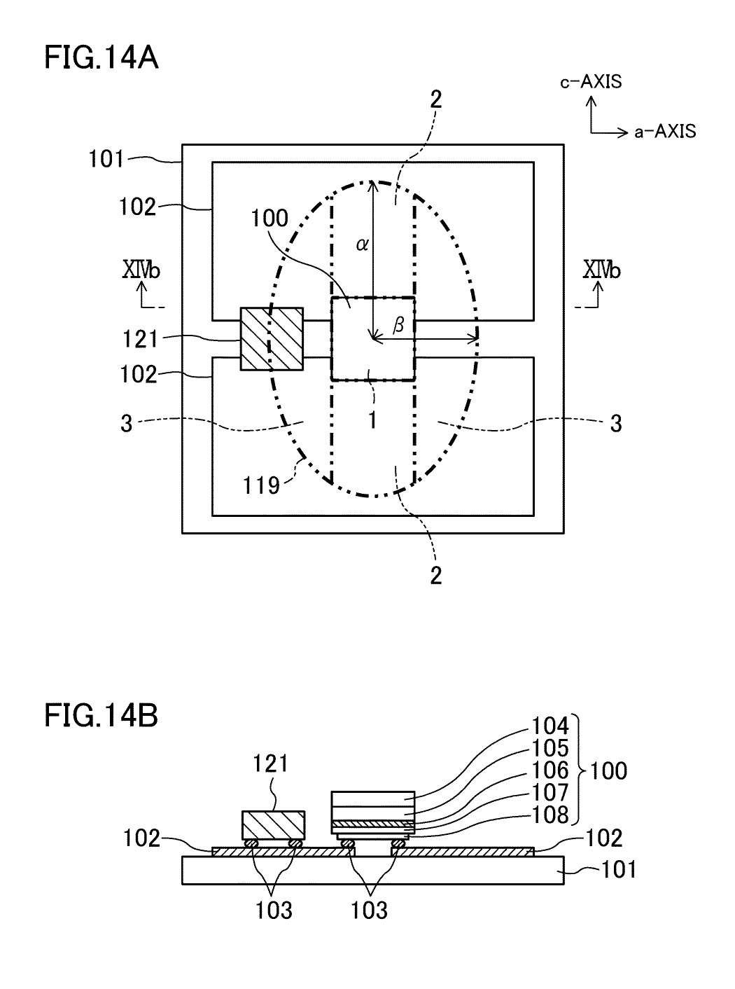

A semiconductor light emitting device according to a sixth embodiment of the present disclosure will be described hereinafter with reference to FIGS. 14A and 14B. Here, the difference between the first and sixth embodiments will be described.

As illustrated in FIGS. 14A and 14B, the sixth embodiment is different from the first embodiment in that a protection element 121 is placed on a mounting surface of a mounting substrate 101. The protection element 121 is connected in parallel to a semiconductor light emitting chip 100, for example, to protect the semiconductor light emitting chip 100 from high voltage, such as a surge. For example, a varistor or a Zener diode is used as the protection element 121. For example, ceramic to which zinc oxide (ZnO) is added as an additive can be used as the varistor. A Zener diode made of silicon (Si) can be used as the Zener diode.

A feature of the sixth embodiment is that the protection element 121 is placed on a region of the mounting surface except a second region 2. Here, the protection element 121 is exemplarily placed astride a third region 3 and a region of the mounting surface located outward from the third region 3.

When the protection element 121 is placed on a region of the mounting surface except the second region 2, this can reduce the influence of the protection element 121, i.e., the phenomenon where emitted light is scattered by the protection element 121 to decrease the degree of polarization of the emitted light, and the phenomenon where emitted light is absorbed by the placed protection element 121 to decrease the light output.

Furthermore, the protection element 121 may be placed on a region of the mounting surface outside an elliptical shape 119. This can reduce the influence of the protection element 121, i.e., the phenomenon where emitted light is scattered by the protection element 121 to decrease the degree of polarization of the emitted light, and the phenomenon where emitted light is absorbed by the placed protection element 121 to decrease the light output, to a sufficient level.

According to the sixth embodiment, a semiconductor light emitting device configured to reduce the influence of light absorption of the protection element 121 while reducing a decrease in the degree of polarization of emitted light reflected off the mounting surface can be achieved.

The protection element 121 is an example electronic component, and an electronic component placed on the mounting surface of the mounting substrate 101 is not limited to a protection element. The number of placed electronic components is not limited to one, and may be two or more.

While, in this embodiment, only the flip-chip structure was described, a wire bonding structure can also provide similar advantages.

### Seventh Embodiment

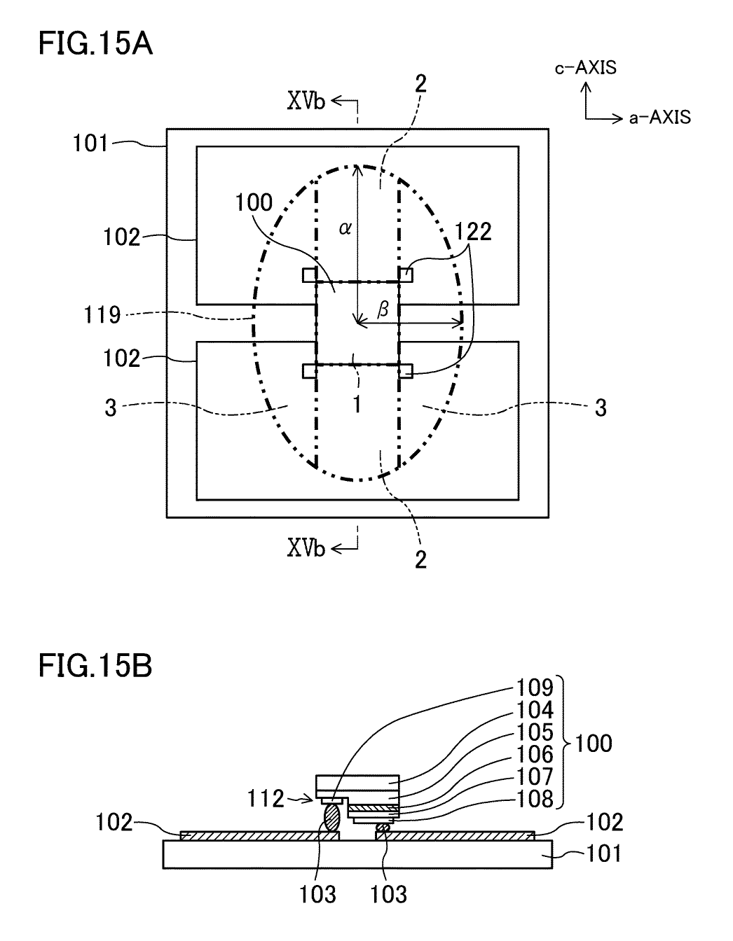

A semiconductor light emitting device according to a seventh embodiment of the present disclosure will be described hereinafter with reference to FIGS. 15A and 15B. Here, the difference between the first and seventh embodiments will be described.

As illustrated in FIGS. 15A and 15B, the seventh embodiment is different from the first embodiment in that alignment markers 122 are placed on a third region 3 of a mounting surface of a mounting substrate 101.

The alignment markers 122 according to this embodiment are marks used to place a semiconductor light emitting chip 100 on the mounting surface of the mounting substrate 101, specifically, on predetermined portions of interconnect electrodes 102. As illustrated in FIG. 15A, for example, the square alignment markers 122 are placed outward from four corners of the semiconductor light emitting chip 100. However, the planar shape of each of the alignment markers 122 is not limited to a square. As long as the planar shape of the alignment marker 122 can be visually checked or can be identified by a mounting facility, it may be any shape. As long as the number of the alignment markers 122 can be visually checked or can be identified by a mounting facility, it is also not limited to four. What is significant is that the alignment markers 122 are placed on the third region 3 of the mounting surface.

The alignment markers 122 are placed on the third region 3 of the mounting surface of the mounting substrate 101, thereby reducing the influence of the alignment markers 122 on the polarization characteristics of emitted light. The alignment markers 122 may be placed at locations different from on the interconnect electrodes 102. The same material as that of the interconnect electrodes 102 can be used as a material of the alignment markers 122. For example, after the formation of the interconnect electrodes 102, portions of the interconnect electrodes 102 corresponding to the alignment markers 122 may be removed to expose corresponding portions of the surface of the mounting substrate 101. When the alignment markers 122 and the interconnect electrodes 102 are formed at the same time, this can reduce the fabrication cost.

According to the seventh embodiment, a nitride semiconductor light emitting device configured to reduce the influence of the alignment markers 122 on the polarization characteristics while reducing a decrease in the degree of polarization of emitted light reflected off the mounting surface of the mounting substrate 101 can be achieved.

While, in this embodiment, only the flip-chip structure was described, a wire bonding structure can also provide similar advantages.

As described above, according to the first through seventh embodiments, a decrease in the degree of polarization of light emitted from a nitride semiconductor light emitting device including an active layer having a nonpolar plane, such as an m- or a-plane, or a semipolar plane, such as a (20-21), (20-2-1), (10-1-3), (11-22), -r-, or (11-22) plane, as a growth surface can be reduced. Furthermore, while a decrease in the degree of polarization of light emitted from the nitride semiconductor light emitting chips is reduced, a plurality of semiconductor light emitting chips can be densely arranged on the mounting surface.

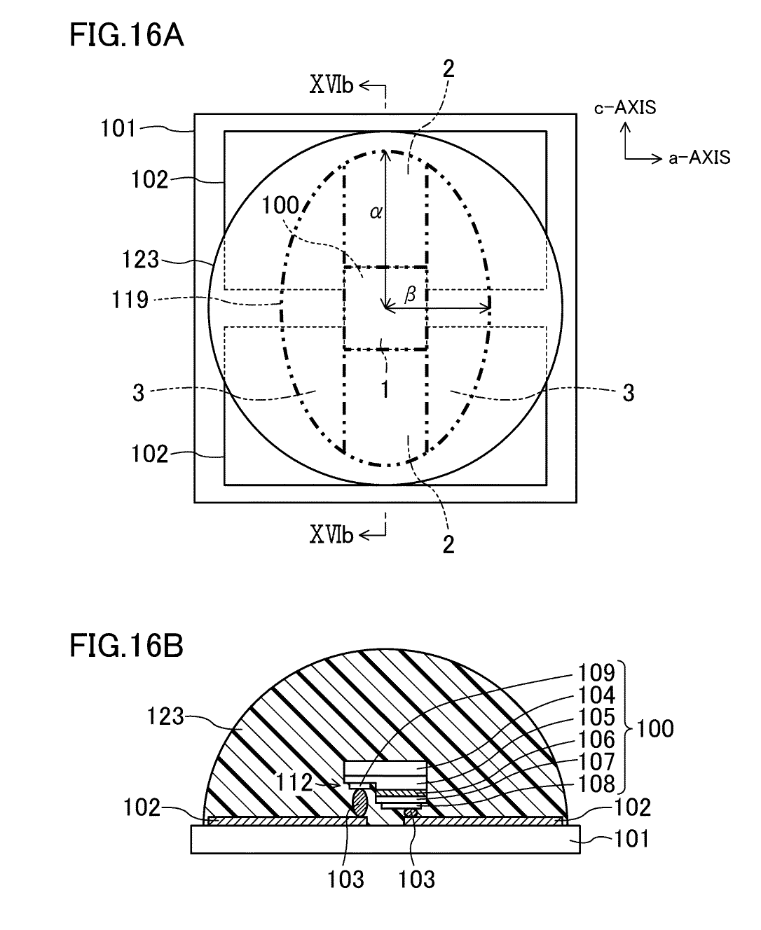

Also in each of all the embodiments and their variations, the semiconductor light emitting chip 100 may be covered with a transparent member. If the semiconductor light emitting chip 100 is covered with a transparent member, this increases the amount of light extracted from the semiconductor light emitting chip 100. Furthermore, the semiconductor light emitting chip 100 can be protected from water or contaminants in the outside air. FIGS. 16A and 16B illustrate an example in which the semiconductor light emitting chip 100 of the first embodiment illustrated in FIGS. 3A and 3B is covered with a transparent member 123. For example, a resin material, such as a silicone resin or an acrylic resin, or a low-temperature glass material can be used as the transparent member 123. Although, in FIGS. 16A and 16B, the example transparent member 123 has a hemispherical shape, the hemispherical transparent member 123 may be distorted in shape, or the transparent member 123 may have an optional shape, such as a cubic shape or a rectangular parallelepiped shape.

The configuration of the semiconductor light emitting device including the reflection member 120 described in the third embodiment can be used also in the embodiments other than the third embodiment and their variations.

### EXAMPLES

The luminous intensity distribution characteristics of emitted light, the reflection properties of a reflecting material, and the influence of raised/recessed portions of a light extraction surface on polarization characteristics were described in each of the first through seventh embodiments, and prior to examples, (1) examination of luminous intensity distribution characteristics of emitted light, (2) examination of reflection properties of a reflecting material, and (3) examination of the influence of raised/recessed portions of a light extraction surface on polarization characteristics will be quantitatively described hereinafter.

(1) Examination of Luminous Intensity Distribution Characteristics of Emitted Light From m-Plane Nitride Semiconductor Light Emitting Chip

First, an active layer having a three-period quantum well structure including a 2-μm-thick n-type nitride semiconductor layer made of n-type GaN, a quantum well layer made of InGaN, and a barrier layer made of GaN, and a 0.5-μm-thick p-type nitride semiconductor layer made of p-type GaN were formed on a wafer-level n-type GaN substrate having an m-plane as its principal surface. In order to fabricate semiconductor light emitting chips emitting light having different wavelengths, a plurality of chips including quantum well layers made of InGaN and having different In contents were fabricated by appropriately changing the amount of In supplied and the crystal growth temperature.

A Ti/Pt layer was formed as an n-side electrode, and a Pd/Pt layer was formed as a p-side electrode. The thickness of the n-type GaN substrate having an m-plane as its principal surface was reduced to a thickness of 150 μm by back grinding. Grooves having a depth of about several μm from the surface of the wafer were formed in the wafer along the c-axis, i.e., the [0001] direction, and the a-axis, i.e., the [11-20] direction, using a diamond pen. Thereafter, the wafer was broken into semiconductor light emitting chips 100 with sides each having a length of 350 μm.

One of the fabricated semiconductor light emitting chips 100 was mounted on a mounting substrate 101 made of alumina and having an upper surface on which interconnects were formed by flip-chip mounting, thereby fabricating a semiconductor light emitting device illustrated in FIGS. 3A and 3B. In order to focus attention on the luminous intensity distribution characteristics of emitted light from the semiconductor light emitting device, a sealing member is not formed on the surface of the semiconductor light emitting device.

An OL700-30 LED Goniometer made by Optronic Laboratories, Inc. was used to measure the semiconductor light emitting device fabricated as above. The luminous intensity distribution characteristics of light emitted along the a-axis and light emitted along the c-axis were measured under the condition A (where the distance from the front end of an LED to a measuring device 118 is 316 mm) specified in CIE127 published by International Commission on Illumination (CIE).

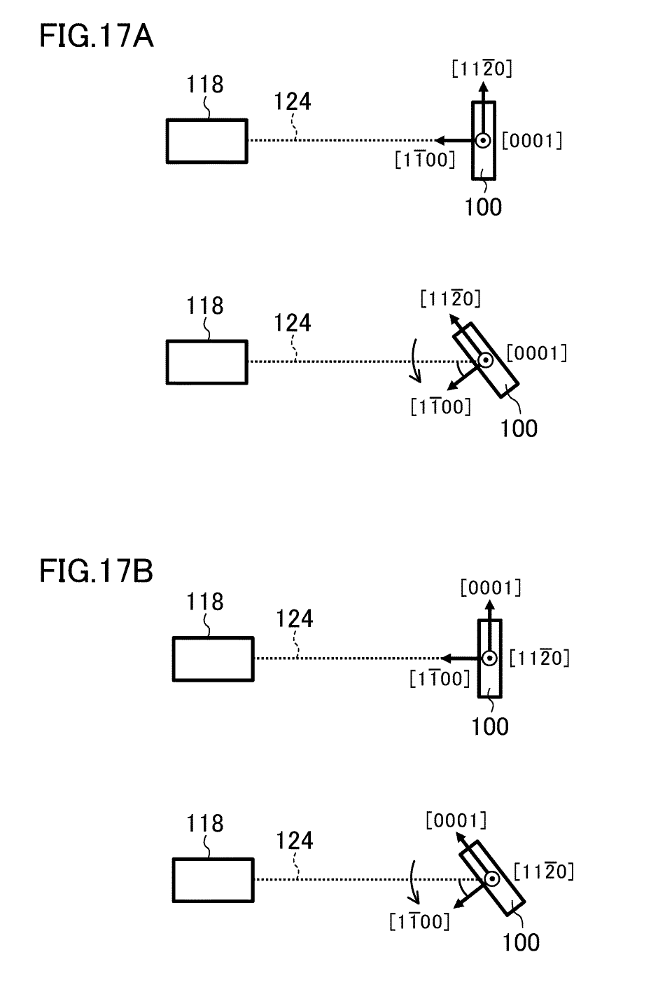

FIGS. 17A and 17B schematically illustrate a measurement system for the luminous intensity distribution characteristics.

The luminous intensity distribution characteristics of light emitted along the a-axis correspond to light intensities measured in the following manner: as illustrated in FIG. 17A, while the semiconductor light emitting chip 100 was rotated about its c-axis, the light intensities were measured using, as a measurement angle, an angle formed between the m-axis, i.e., the [1-100] direction, normal to an m-plane of an active layer of the semiconductor light emitting chip 100 and a measurement line 124 connecting the semiconductor light emitting chip 100 and the measuring device 118 together.

The luminous intensity distribution characteristics of light emitted along the c-axis correspond to light intensities measured in the following manner: as illustrated in FIG. 17B, while the semiconductor light emitting chip 100 was rotated about its a-axis, the light intensities were measured using, as a measurement angle, an angle formed between the m-axis, i.e., the [1-100] direction, normal to the m-plane of the active layer of the semiconductor light emitting chip 100 and the measurement line 124 connecting the semiconductor light emitting chip 100 and the measuring device 118 together. Here, the range of angles in which when the intensity of light emitted along the m-axis, i.e., the [1-100] direction, is one, the light intensity is 0.5 or greater is referred to as a radiation angle.

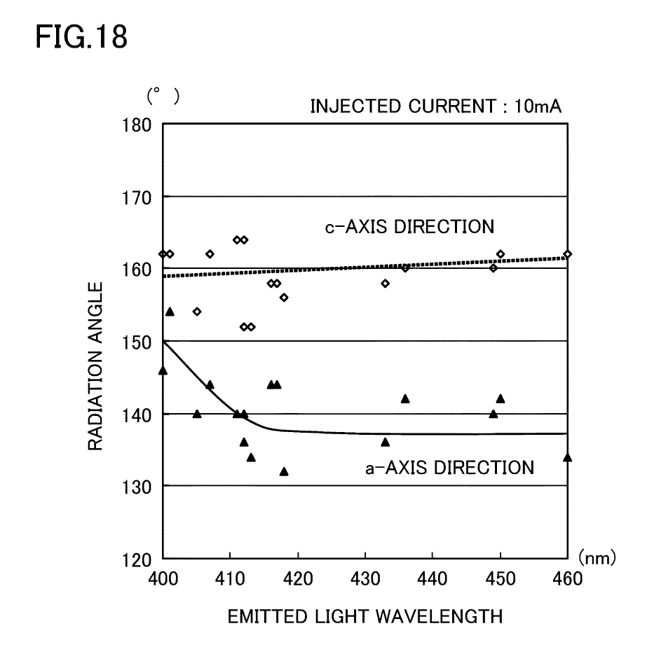

FIG. 18 illustrates the relationship between each of the radiation angles of light emitted from the semiconductor light emitting chip 100 along the a- and c-axes and the wavelength of the corresponding emitted light. The current injected into the semiconductor light emitting chip 100 is 10 mA. As seen from FIG. 18, the radiation angle of the light emitted along the c-axis is substantially fixed, and is about 160°. The radiation angle of the light emitted along the a-axis and having a wavelength greater than or equal to 420 nm is substantially fixed, and is about 140°. In other words, the semiconductor light emitting chip 100 using an m-plane as a growth surface of the active layer has luminous intensity distribution spread along the c-axis. A contour line along which the light intensity is 0.5 forms a shape close to an elliptical shape having a major axis along the c-axis, and a minor axis along the a-axis. When the radiation angle of light emitted along the c-axis is 160°, and the radiation angle of light emitted along the a-axis is 140°, the ratio of the length of the major axis (along the c-axis) to the length of the minor axis (along the a-axis) is 2 to 1.

(2) Examination of Reflection Properties of Reflecting Material

As a base material forming a mounting substrate 101 or a constituent material of interconnect electrodes 102, 15 types of samples were prepared, and their reflectivities were measured. In the measurement of the reflectivities, the mirror reflectivity and diffuse reflectivity of each of the samples were measured using a spectrophotometer (UV-VIS) made by JASCO Corporation. When the absolute reflectivity was measured using the UV-VIS spectrophotometer, the reflectivity of light reflected at an angle of reflection equal to the angle of incidence of the light was measured. Therefore, the measured absolute reflectivity means the mirror reflectivity or the specular reflectivity. When the relative reflectivity was measured using the UV-VIS spectrophotometer, the reflectivity of a specimen from which light is diffusely reflected was measured, where the reflectivity of a standard reflector (Spectralon made by US Labsphere, Inc.) is 100%. Therefore, the measured relative reflectivity means the diffuse reflectivity.

Table 1 shows the material and roughness Ra of the uppermost surface of each of the 15 types of samples, the material and surface roughness Ra of the base material of the sample, the mirror reflectivity, diffuse reflectivity, and total reflectivity of the uppermost surface of the sample, and the proportion of mirror reflection from the uppermost surface of the sample. The reflectivities are values at a wavelength of 450 nm.

TABLE 1

| | | | | ROUGHNESS | | | | |
|---|---|---|---|---|---|---|---|---|
| | | ROUGHNESS | | Ra OF | | | | |
| | | Ra of | | BASE | | DIFFUSE | TOTAL | PROPORTION |
| | | UPPERMOST | | MATERIAL | MIRROR | REFLEC- | REFLEC- | OF MIRROR |
| | UPPERMOST | SURFACE | | SURFACE | REFLECTIVITY | TIVITY | TIVITY | REFLECTION |
| | SURFACE | [nm] | BASE MATERIAL | [nm] | [%] | [%] | [%] | [%] |
| SAMPLE 1 | HIGH- | 1289 | HIGH- | 1289 | 1.1 | 94.4 | 95.5 | 1.2 |
| | TEMPERATURE | | TEMPERATURE | | | | | |
| | FIRED | | FIRED | | | | | |
| | ALUMINA | | ALUMINA | | | | | |
| | CERAMIC | | CERAMIC | | | | | |
| SAMPLE 2 | Ag | 569 | HIGH- | 1289 | 12.9 | 69.1 | 82.0 | 15.7 |
| | | | TEMPERATURE | | | | | |
| | | | FIRED | | | | | |
| | | | ALUMINA | | | | | |
| | | | CERAMIC | | | | | |
| SAMPLE 3 | Au | 1715 | HIGH- | 1289 | 4.1 | 29.1 | 33.2 | 12.3 |
| | | | TEMPERATURE | | | | | |
| | | | FIRED | | | | | |
| | | | ALUMINA | | | | | |
| | | | CERAMIC | | | | | |
| SAMPLE 4 | DIAMOND- | 368 | HIGH- | 1289 | 0.6 | 4.2 | 4.8 | 12.5 |
| | LIKE | | TEMPERATURE | | | | | |
| | CARBON | | FIRED | | | | | |
| | (DLC) | | ALUMINA | | | | | |
| | | | CERAMIC | | | | | |
| SAMPLE 5 | Ag | 206 | DLC/HIGH- | 368 | 17.3 | 63.9 | 81.2 | 21.3 |
| | | | TEMPERATURE | | | | | |
| | | | FIRED | | | | | |
| | | | ALUMINA | | | | | |
| | | | CERAMIC | | | | | |
| | | | (SAMPLE 4) | | | | | |
| SAMPLE 6 | LOW | 367 | LO [symbol] - | 367 | 0.7 | 57.63 | 58.3 | 1.2 |
| | TEMPERATURE | | TEMPERATURE | | | | | |
| | FIRED | | FIRED | | | | | |
| | ALUMINA | | ALUMINA | | | | | |
| | CERAMIC | | CERAMIC | | | | | |
| SAMPLE 7 | Ag | 162 | LO [symbol] - | 367 | 20.2 | 57.8 | 78.0 | 25.9 |
| | | | TEMPERATURE | | | | | |
| | | | FIRED | | | | | |
| | | | ALUMINA | | | | | |
| | | | CERAMIC | | | | | |
| SAMPLE 8 | AlN | 33 | AlN | 33 | 8.7 | 24.7 | 33.4 | 25.9 |
| SAMPLE 9 | Ag | 59 | AlN | 33 | 54.0 | 26.5 | 80.5 | 67.1 |
| SAMPLE | Au | 45 | AlN | 33 | 25.4 | 4.5 | 29.9 | 85.0 |
| 10 | | | | | | | | |
| SAMPLE | Al | 376 | Au/AlN | 33 | 51.1 | 25.8 | 76.9 | 66.4 |
| 11 | | | (SAMPLE 10) | | | | | |
| SAMPLE | Ag | 18 | GaN | 0.072 | 92.1 | 2.4 | 94.5 | 97.5 |
| 12 | | | | | | | | |
| SAMPLE | Al | 848 | Al | 848 | 48.9 | 25.0 | 73.9 | 66.2 |
| 13 | | | | | | | | |
| SAMPLE | WHITE | 545 | WHITE | 545 | 1.6 | 94.2 | 95.8 | 1.7 |
| 14 | SILICONE | | SILICONE | | | | | |
| | (CONTAINING | | (CONTAINING | | | | | |
| | TiO₂) | | TiO₂) | | | | | |
| SAMPLE | Al | — | GLASS | — | 87.9 | 0.7 | 88.6 | 99.2 |
| 15 | | | | | | | | |

Sample 1 is 1-mm-thick alumina ceramic fired at high temperature (hereinafter referred to high-temperature fired alumina ceramic). The high-temperature fired alumina ceramic exhibits insulating properties.
Sample 2 is obtained by forming about 4-μm-thick silver (Ag) on the high-temperature fired alumina ceramic of Sample 1.
Sample 3 is obtained by forming about 4-μm-thick gold (Au) on the high-temperature fired alumina ceramic of Sample 1.
Sample 4 is obtained by forming an about 10-μm-thick diamond-like carbon (DLC) film on the high-temperature fired alumina ceramic of Sample 1.
Sample 5 is obtained by forming about 4-μm-thick Ag on the DLC film formed on the high-temperature fired alumina ceramic in Sample 4.
Sample 6 is about 0.6-mm-thick alumina ceramic fired at low temperature (hereinafter referred to as low-temperature fired alumina ceramic). The low-temperature fired alumina ceramic exhibits insulating properties.
Sample 7 is obtained by forming about 10-μm-thick Ag on the low-temperature fired alumina ceramic of Sample 6.
Sample 8 is about 0.7-mm-thick ceramic made of aluminum nitride (AlN). The AlN ceramic exhibits insulating properties.
Sample 9 is obtained by forming about 4-μm-thick Ag on AlN ceramic.
Sample 10 is obtained by forming about 4-μm-thick Au on AlN ceramic.
Sample 11 is obtained by forming about 3-μm-thick aluminum (Al) on the Au formed on the AlN ceramic in Sample 10.
Sample 12 is obtained by forming about 400-nm-thick Ag on a monocrystalline substrate made of m-plane GaN and thermally treating the substrate region at a temperature of 500° C. for one minute.
Sample 13 is an about 1-mm-thick aluminum (Al) sheet.
Sample 14 is white silicone obtained by adding fine particles made of titanium dioxide (TiO₂) to a silicone resin. White silicone exhibits insulating properties.
Sample 15 is obtained by depositing about 1-μm-thick aluminum (Al) on glass. [symbol]
indicates data missing or illegible when filed

As seen from Table 1, the DLC film of Sample 4 is a material utilized also as an anti-reflection film, and the total reflectivity of the DLC film is as low as about 5%. The uppermost surface of each of Samples 3 and 10 is made of Au, and the total reflectivity thereof is as low as about 30%. The uppermost surface of Sample 8 is made of AlN, and the total reflectivity thereof is as low as about 33%. The total reflectivity of each of the other samples is a relatively high reflectivity higher than or equal to 58%.

The proportion of mirror reflection from each of Samples 1, 6, and 14 is less than 2%, and each of Samples 1, 6, and 14 is a material from which light is very predominantly diffusely reflected. Light is incident upon the base material of the sample, and the incident light is reflected while being scattered. Thus, the light is predominantly diffusely reflected.

The proportion of mirror reflection from each of the other samples is higher than 12%, and components of light reflected from the sample include a mirror reflection component. The materials of the samples are materials off the surface of each of which light is reflected, and conductive materials, such as metal, correspond to the materials. The proportion of mirror reflection from each of the materials strongly depends on the roughness of the uppermost surface of a corresponding one of the samples and the surface roughness of the base material of the corresponding sample.

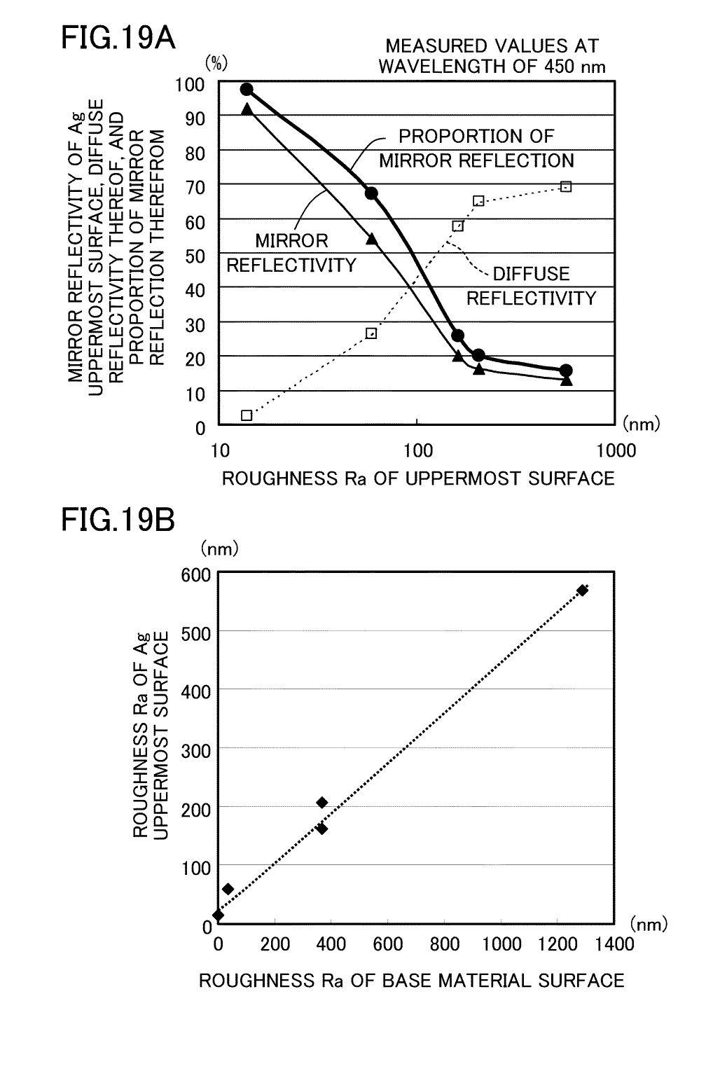

FIG. 19A relates to reflection from the Ag uppermost surface of each of Samples 2, 5, 7, 9, and 12, and illustrates the relationship between the Ag uppermost surface roughness and each of the mirror reflectivity of the Ag uppermost surface, the diffuse reflectivity thereof, and the proportion of mirror reflection from the Ag uppermost surface. With increasing Ag uppermost surface roughness, the diffuse reflectivity increases, and the mirror reflectivity, however, decreases. The Ag uppermost surface roughness at which the line showing the mirror reflectivity crosses the line showing the diffuse reflectivity in FIG. 19A, i.e., the Ag uppermost surface roughness at which the proportion of mirror reflection is 50%, is about 100 nm. In other words, when the surface roughness of the interconnect electrodes 102 is equal to or less than 100 nm, light is less likely to be affected by projections/recesses on the surface, and is more predominantly specularly reflected.

FIG. 19B illustrates the relationship between the surface roughness of the base material of each of Samples 2, 5, 7, 9, and 12 and the Ag uppermost surface roughness. The base material surface roughness is closely correlated with the Ag uppermost surface roughness, and in order to allow the Ag uppermost surface roughness to be equal to or less than 100 nm, the base material surface roughness is preferably equal to or less than 200 nm.

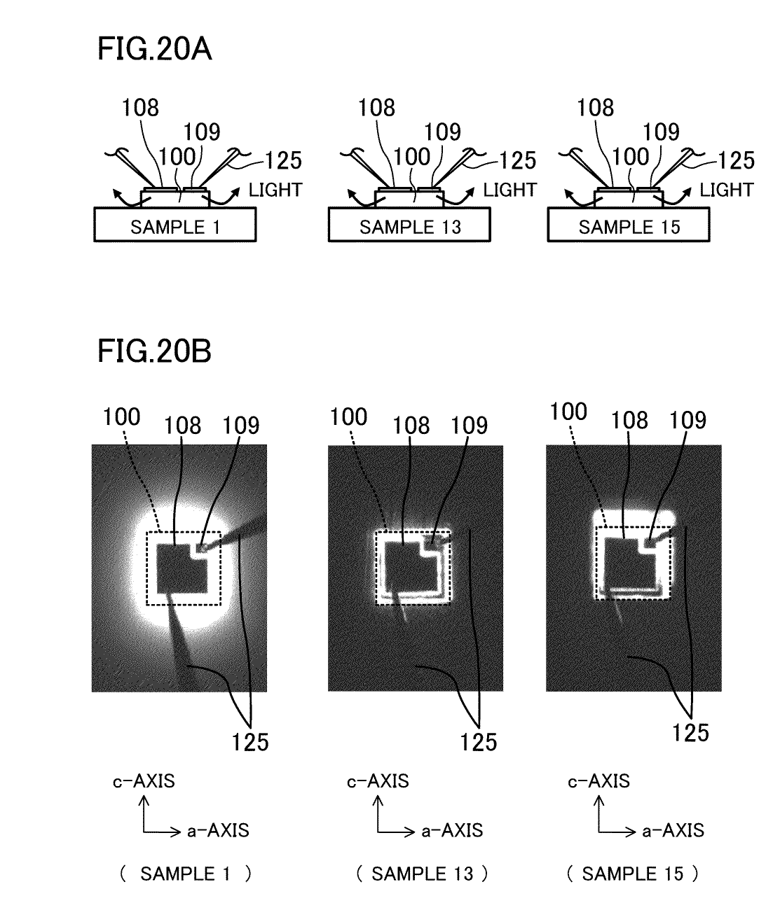

Next, a semiconductor light emitting chip 100 was placed on the surface of each of Samples 1, 13, and 15, and the degree of polarization of light from the semiconductor light emitting chip 100 was measured to examine the influence of the reflection properties of a reflection surface of the sample on the degree of polarization. FIGS. 20A and 20B illustrate examination systems for examining the influence of the reflection properties on the degree of polarization. FIG. 20A schematically illustrates a cross-sectional structure of each of the examination systems. FIG. 20B illustrates photographs obtained by taking the condition of light emitted from each of the semiconductor light emitting chips 100 and the reflected light from above, where the current injected into the semiconductor light emitting chip 100 is 10 mA. The semiconductor light emitting chip 100 was fabricated by a chip fabrication method described below in a first example. The length of each of sides of the chip is 950 μm, and the thickness of a substrate 104 is 150 μm. The wavelength of light emitted by a light emitting layer is 450 nm. A p-side electrode 108 and an n-side electrode 109 formed on the semiconductor light emitting chip 100 on each of the samples face upward.

The p-side and n-side electrodes 108 and 109 of each of the semiconductor light emitting chips 100 are both made of materials through which light is not transmitted, and thus, light emitted from the side surfaces of the semiconductor light emitting chip 100 is reflected off the surface of a corresponding one of the samples. A prober 125 is brought into contact with the p-side and n-side electrodes 108 and 109 to inject a predetermined current into the semiconductor light emitting chip 100. The plan view photograph of Sample 1 in FIG. 20B shows that light reflected off the surface of Sample 1 forms a substantially elliptical shape having a major axis along the c-axis, and a minor axis along the a-axis. Since the surface of Sample 1 is made of alumina having an extremely high diffuse reflectivity, it is clearly seen that light is scattered off the mounting surface, and a mounting surface effective portion forms a shape close to an elliptical shape. By contrast, since the surfaces of Samples 13 and 15 are made of a material having an extremely high mirror reflectivity, the shape of light reflected off the mounting surface of each of Samples 13 and 15 is unclear. The reason for this is that light does not enter the optical system of the camera used to take the photographs. The mounting surface effective portion of the sample forms an elliptical shape.

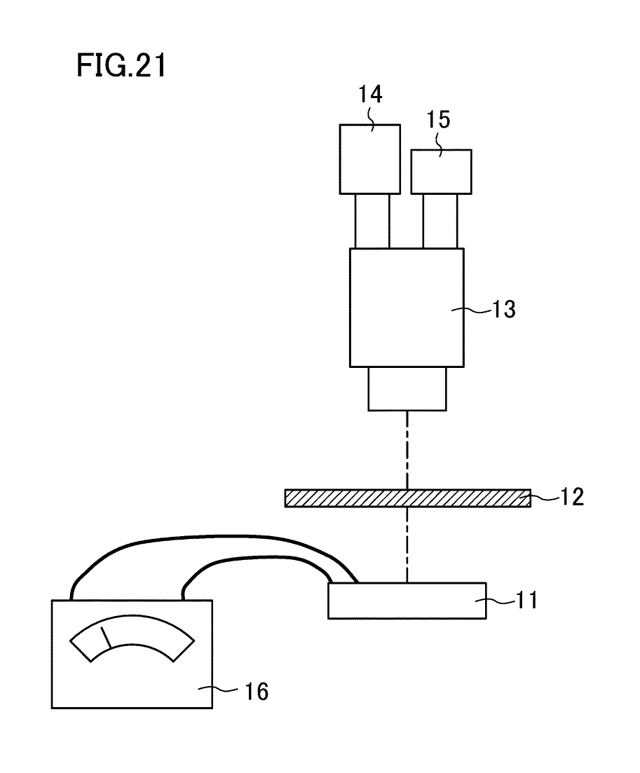

FIG. 21 schematically illustrates a measurement system for the degree of polarization. A power supply 16 allows a measurement target, i.e., a semiconductor light emitting device 11 made of a nitride semiconductor, to emit light. Light emitted from the semiconductor light emitting device 11 is viewed through a stereoscopic microscope 13. The stereoscopic microscope 13 has two ports, and while a silicon photodetector 14 is attached to one of the ports, a CCD camera 15 is attached to the other port. A polarizing plate 12 is interposed between the semiconductor light emitting device 11 and the stereoscopic microscope 13. While the polarizing plate 12 is rotated, the highest and lowest intensities of the emitted light are measured using the silicon photodetector 14.

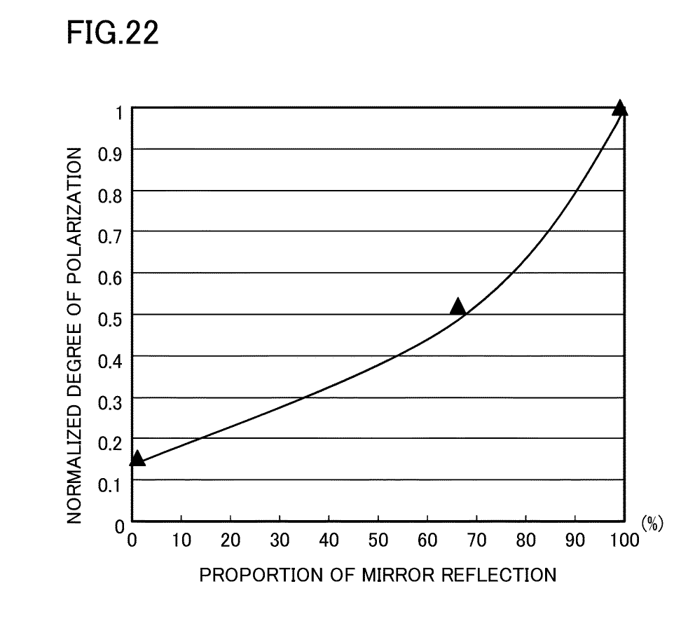

FIG. 22 illustrates the degree of polarization of light emitted from the semiconductor light emitting chip 100 placed on each of Samples 1, 13, and 15. The degree of polarization is normalized using the degree of polarization of light emitted from the semiconductor light emitting chip 100 on Sample 15. With increasing mirror reflectivity of the reflection surface, the degree of polarization of reflected light is maintained, and a decrease in the degree of polarization of reflected light is reduced. By contrast, it is seen that with decreasing mirror reflectivity of the reflection surface, the degree of polarization of reflected light decreases. In order to obtain a normalized degree of polarization greater than or equal to 0.5, the proportion of mirror reflection may be higher than or equal to 66%. FIG. 19A shows that the materials of the uppermost surfaces of some of the samples from which the proportion of mirror reflection is higher than or equal to 66% are metals formed on the corresponding base material having a surface roughness equal to or less than 50 nm.

(3) Examination of Influence of Projection/Recess Portions Formed on Light Extraction Surface Upon Polarization

In order to enhance the light extraction efficiency at which light is extracted from a nitride semiconductor light emitting chip, raised/recessed portions may be formed on the light extraction surface of the chip as illustrated in FIG. 8A. Here, in each of semiconductor light emitting devices each including stripe-shaped raised/recessed portions formed on a light extraction surface of a chip, the influence of an angle formed between the direction of extension of the stripes and the a-axis of a light emitting layer upon the degree of polarization was examined. Semiconductor light emitting chips including a light emitting layer that has an m-plane as a growth surface and is made of a nitride semiconductor were fabricated in a manner similar to that in a first example described below.

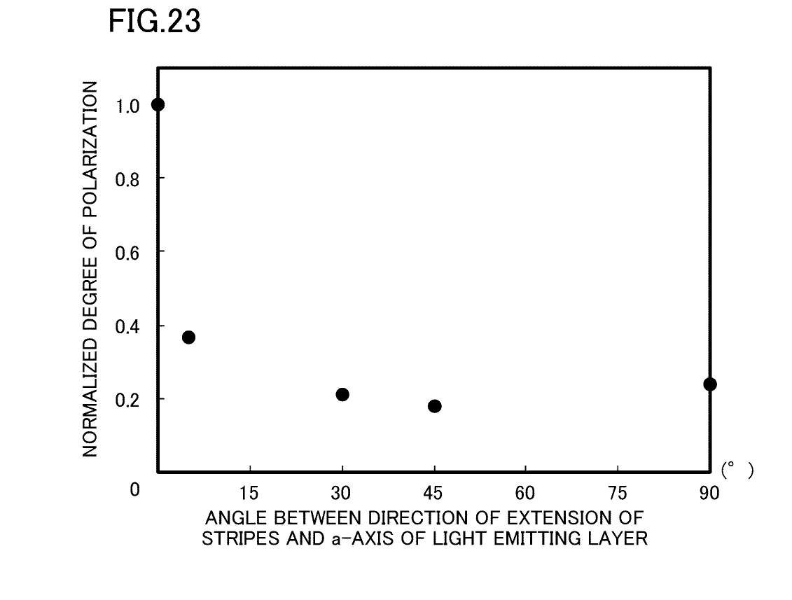

The semiconductor light emitting chips each form the shape of a square with sides having a length of 350 μm, and each have a 100-μm-thick substrate. Stripe-shaped raised/recessed portions were formed on the surface of each of the semiconductor light emitting chips (the back surface of the substrate). The cross-sectional shape of each of the stripe-shaped raised/recessed portions is close to an isosceles triangle as illustrated in FIG. 8D, the distance between each adjacent pair of the raised portions is 8 μm, and the height of each of the raised portions is 2.5 μm. The angle 0 formed between the direction of extension of the stripes and the electric field direction of polarized light (the a-axis of the light-emitting layer) was varied among 0°, 5°. 30°, 45°, and 90°. FIG. 23 illustrates the normalized degrees of polarization of light emitted from the semiconductor light emitting devices. The normalized degrees of polarization each denote a value normalized using the degree of polarization at an angle θ of 0° as 1.0. Measurement results illustrated in FIG. 23 show that when the angle θ is greater than or equal to 5°, the degree of polarization is reduced. Therefore, the angle θ may be greater than or equal to 0° and less than 5°. This can reduce a decrease in the degree of polarization. Furthermore, the angle θ may be substantially 0°. This can further reduce a decrease in the degree of polarization.

### First Example

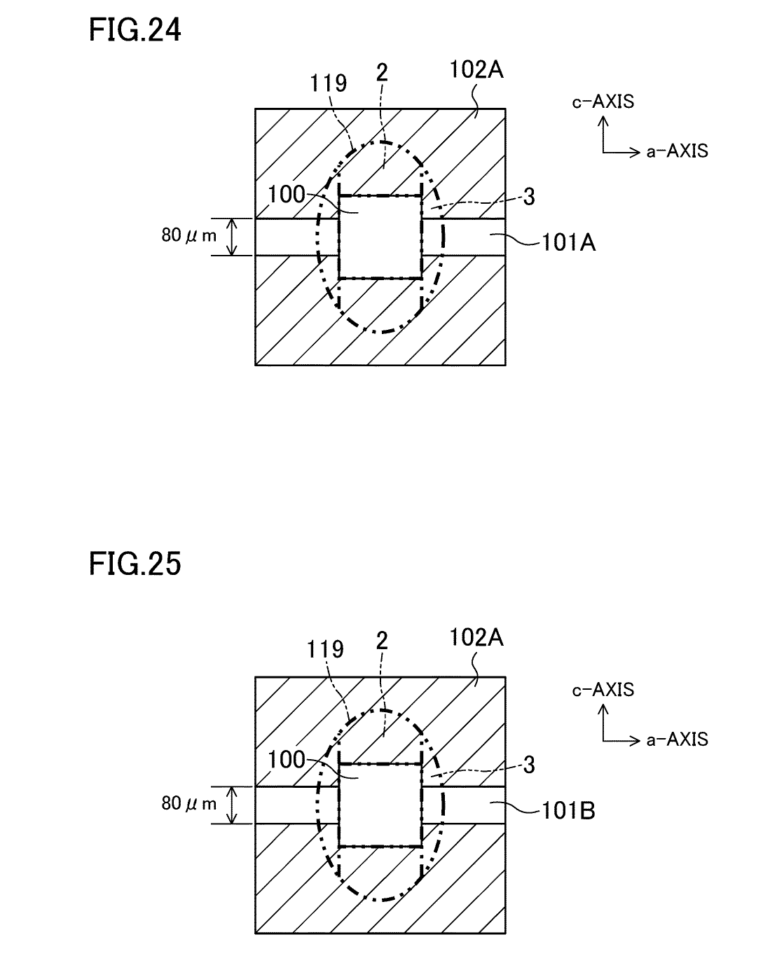

A semiconductor light emitting device according to a first example will be described with reference to FIG. 24. First, a method for fabricating a semiconductor light emitting chip 100 forming the semiconductor light emitting device according to the first example will be briefly described.

First, an active layer having a three-period quantum well structure including a 2-μm thick n-type nitride semiconductor layer made of n-type GaN, a quantum well layer made of InGaN, and a barrier layer made of GaN, and a 0.5-μm-thick p-type nitride semiconductor layer made of p-type GaN were formed on a wafer-level n-type GaN substrate having an m-plane as its principal surface, for example, by MOCVD.

A Ti/Pt layer was formed as an n-side electrode, and a Pd/Pt layer was formed as a p-side electrode. Thereafter, the thickness of the n-type GaN substrate was reduced to a thickness of 150 μm by grinding the back surface of the n-type GaN substrate.

Subsequently, grooves having a depth of about several μm from the surface of the wafer on which light-emitting structures were formed were formed in the wafer along the a c-axis, i.e., the [0001] direction, and the a-axis, i.e., the [11-20] direction, using a diamond pen. Thereafter, the wafer was broken into semiconductor light emitting chips 100 which each have sides each having a length of 350 μm and are made of an m-plane GaN-based semiconductor.

Subsequently, one of the fabricated semiconductor light emitting chips 100 was mounted on a mounting substrate 101A made of high-temperature fired alumina ceramic by flip-chip mounting, thereby fabricating a semiconductor light emitting device. The thickness of the mounting substrate 101A made of high-temperature fired alumina ceramic is about 1 mm. About 4-μm-thick interconnect electrodes 102A made of silver (Ag) were selectively formed on the surface of the mounting substrate 101A. The interconnect electrodes 102A were formed to cover at least a second region 2 of an elliptical shape 119.

As illustrated in Sample 2 in Table 1, the mirror reflectivity of the interconnect electrodes 102A made of Ag is 12.9%, the diffuse reflectivity thereof is 69.1%, the total reflectivity thereof is 82.0%, and the proportion of mirror reflection from the interconnect electrodes 102A is 15.7%.

High-temperature fired alumina ceramic is exposed on at least a portion of a third region 3 of the elliptical shape 119 between the interconnect electrodes 102A. As illustrated in Sample 1 in Table 1, the mirror reflectivity of the high-temperature fired alumina ceramic is 1.1%, the diffuse reflectivity thereof is 94.4%, the total reflectivity thereof is 95.5%, and the proportion of mirror reflection from the high-temperature fired alumina ceramic is 1.2%. The c-axis width of a region where the high-temperature fired alumina ceramic is exposed is about 80 μm. The proportion of the area of the region where the high-temperature fired alumina ceramic is exposed to the area of a mounting surface effective portion in the elliptical shape 119 is 4.5%.

The wavelength of light emitted from the semiconductor light emitting device of the first example that is operating at a current of 5 mA was 410 nm. When the degree of polarization of the light emitted from the semiconductor light emitting device that is operating at a current of 5 mA was measured, the degree of polarization was 0.29. The measurement result shows that since the degree of polarization of light emitted from a semiconductor light emitting device according to a comparative example described below is 0.24, the degree of polarization of the light emitted from the semiconductor light emitting device of the first example is higher than that of the light emitted from the semiconductor light emitting device of the comparative example.

### Second Example

A semiconductor light emitting device according to a second example will be described with reference to FIG. 25. A semiconductor light emitting chip 100 illustrated in FIG. 25 was fabricated in a manner similar to that in the first example.

Subsequently, the semiconductor light emitting chip 100 was mounted on a mounting substrate 101B including high-temperature fired alumina ceramic and a diamond-like carbon (DLC) film formed on the high-temperature fired alumina ceramic by flip-chip mounting, thereby fabricating a semiconductor light emitting device. The thickness of the mounting substrate 101B is about 1 mm, and the thickness of the DLC film is about 10 μm. About 4-μm-thick interconnect electrodes 102A made of Ag were selectively formed on the DLC film. The interconnect electrodes 102A were formed to cover at least a second region 2 of an elliptical shape 119.

As illustrated in Sample 5 in Table 1, the mirror reflectivity of the interconnect electrodes 102A made of Ag is 17.3%, the diffuse reflectivity thereof is 63.9%, the total reflectivity thereof is 81.2%, and the proportion of mirror reflection from the interconnect electrodes 102A is 21.3%.

The DLC film is exposed on at least a portion of a third region 3 between the interconnect electrodes 102A. As illustrated in Sample 4 in Table 1, the mirror reflectivity of the DLC film is 0.6%, the diffuse reflectivity thereof is 4.2%, the total reflectivity thereof is 4.8%, and the proportion of mirror reflection from the DLC film is 12.5%. The c-axis width of a region where the DLC film is exposed is about 80 μm. The proportion of the area of the region where the DLC film is exposed to the area of a mounting surface effective portion in the elliptical shape 119 is 4.5%.

The wavelength of light emitted from the semiconductor light emitting device of the second example that is operating at a current of 5 mA was 410 nm. When the degree of polarization of the light emitted from the semiconductor light emitting device that is operating at a current of 5 mA was measured, the degree of polarization was 0.29. The measurement result shows that since the degree of polarization of light emitted from the semiconductor light emitting device according to the comparative example described below is 0.24, the degree of polarization of the light emitted from the semiconductor light emitting device of the second example is higher than that of the light emitted from the semiconductor light emitting device of the comparative example.

### Third Example

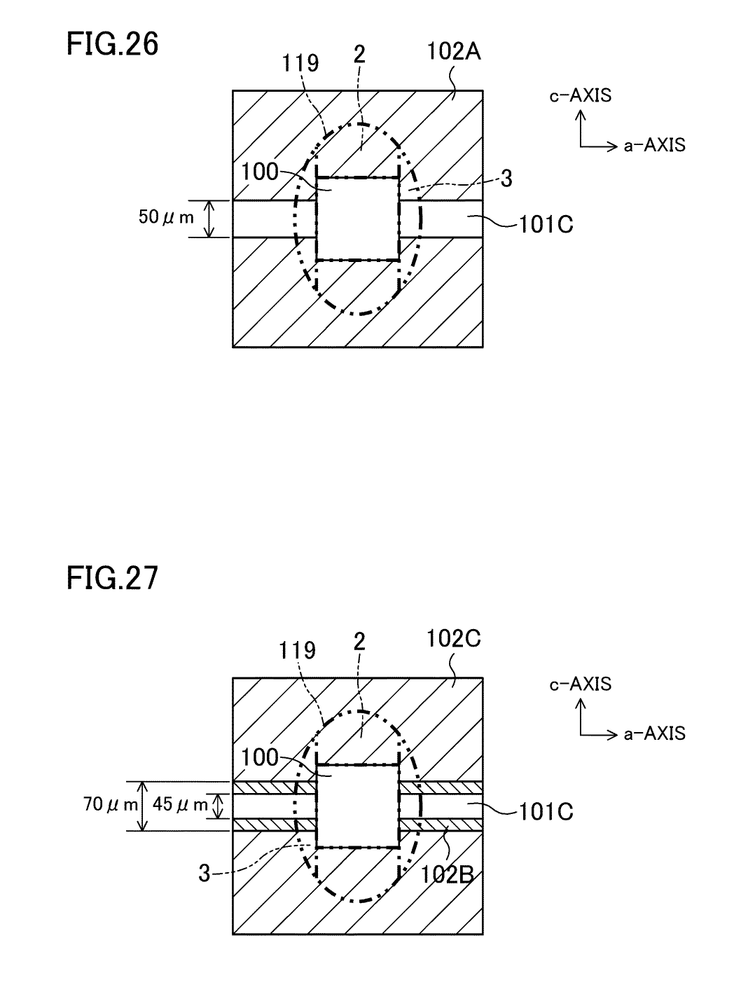

A semiconductor light emitting device according to a third example will be described with reference to FIG. 26. A semiconductor light emitting chip 100 illustrated in FIG. 26 was fabricated in a manner similar to that in the first example.

Subsequently, the semiconductor light emitting chip 100 was mounted on a mounting substrate 101C made of aluminum nitride (AlN) by flip-chip mounting, thereby fabricating a semiconductor light emitting device. The thickness of the mounting substrate 101C made of AlN is about 0.7 mm. About 4-μm-thick interconnect electrodes 102A made of Ag were selectively formed on the surface of the mounting substrate 101C. The interconnect electrodes 102A were formed to cover at least a second region 2 of an elliptical shape 119.

As illustrated in Sample 9 in Table 1, the mirror reflectivity of the interconnect electrodes 102A made of Ag is 54.0%, the diffuse reflectivity thereof is 26.5%, the total reflectivity thereof is 80.5%, and the proportion of mirror reflection from the interconnect electrodes 102A is 67.1%.

AlN is exposed on at least a portion of a third region 3 between the interconnect electrodes 102A. As illustrated in Sample 8 in Table 1, the mirror reflectivity of AlN is 8.7%, the diffuse reflectivity thereof is 24.7%, the total reflectivity thereof is 33.4%, and the proportion of mirror reflection from AlN is 25.9%. The c-axis width of a region where the AlN is exposed is about 50 μm. The proportion of the area of the region where the AlN is exposed to the area of a mounting surface effective portion in the elliptical shape 119 is 2.8%.

The wavelength of light emitted from the semiconductor light emitting device of the third example that is operating at a current of 5 mA was 410 nm. When the degree of polarization of the light emitted from the semiconductor light emitting device that is operating at a current of 5 mA was measured, the degree of polarization was 0.42. The measurement result shows that since the degree of polarization of light emitted from the semiconductor light emitting device according to the comparative example described below is 0.24, the degree of polarization of the light emitted from the semiconductor light emitting device of the third example is higher than that of the light emitted from the semiconductor light emitting device of the comparative example.

### Fourth Example

A semiconductor light emitting device according to a fourth example will be described with reference to FIG. 27. A semiconductor light emitting chip 100 illustrated in FIG. 27 was fabricated in a manner similar to that in the first example. Subsequently, the semiconductor light emitting chip 100 was mounted on a mounting substrate 101C made of AlN by flip-chip mounting, thereby fabricating a semiconductor light emitting device. The thickness of the mounting substrate 101C made of AlN is about 0.7 mm. About 4-μm-thick first interconnect electrodes 102B made of gold (Au) were selectively formed on the surface of the mounting substrate 101C. Furthermore, in this example, about 3-μm-thick second interconnect electrodes 102C made of aluminum (Al) were selectively formed on the first interconnect electrodes 102B. At least the second interconnect electrodes 102C are formed to cover at least a second region 2 of an elliptical shape 119.

As illustrated in Sample 11 in Table 1, the mirror reflectivity of the second interconnect electrodes 102C made of Al is 51.1%, the diffuse reflectivity thereof is 25.8%, the total reflectivity thereof is 76.9%, and the proportion of mirror reflection from the interconnect electrodes 102C is 66.4%.

The first interconnect electrodes 102B being upper electrodes, and AlN forming the mounting substrate 101C are exposed on at least a portion of a third region 3 between the interconnect electrodes 102C being upper electrodes. As illustrated in Sample 10 in Table 1, the mirror reflectivity of the first interconnect electrodes 102B made of Au is 25.4%, the diffuse reflectivity thereof is 4.5%, the total reflectivity thereof is 29.9%, and the proportion of mirror reflection from the first interconnect electrodes 102B is 85.0%. Furthermore, as illustrated in Sample 8, the mirror reflectivity of AlN is 8.7%, the diffuse reflectivity thereof is 24.7%, the total reflectivity thereof is 33.4%, and the proportion of mirror reflection from AlN is 25.9%. The c-axis width of a region where the AlN is exposed is about 45 μm. Exposed portions of the first interconnect electrodes 102B are in the form of stripes with a linearly exposed region of the AlN interposed therebetween along the c-axis, and the exposed portions each have a width of about 12.5 μm. The proportion of the area of the region where the AlN is exposed to the area of a mounting surface effective portion in the elliptical shape 119 is 2.6%, and the proportion of the area of a region where Au forming the first interconnect electrodes 102B is exposed to the area of the mounting surface effective portion is 1.4%.

The wavelength of light emitted from the semiconductor light emitting device of the fourth example that is operating at a current of 5 mA was 410 nm. When the degree of polarization of the light emitted from the semiconductor light emitting device that is operating at a current of 5 mA was measured, the degree of polarization was 0.40. The measurement result shows that since the degree of polarization of light emitted from the semiconductor light emitting device according to the comparative example described below is 0.24, the degree of polarization of the light emitted from the semiconductor light emitting device of the fourth example is higher than that of the light emitted from the semiconductor light emitting device of the comparative example.

### Comparative Example

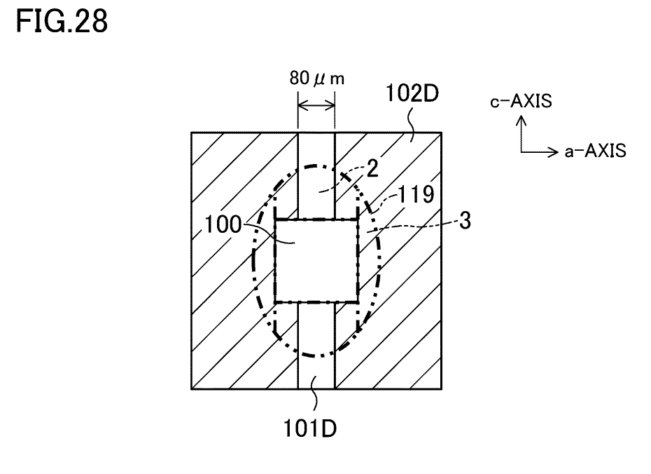

The semiconductor light emitting device according to the comparative example will be described hereinafter with reference to FIG. 28. A semiconductor light emitting chip 100 illustrated in FIG. 28 was fabricated in a manner similar to that in the first example.

Subsequently, the semiconductor light emitting chip 100 was mounted on a mounting substrate 101D made of high-temperature alumina ceramic by flip-chip mounting, thereby fabricating a semiconductor light emitting device. The thickness of the mounting substrate 101D made of high-temperature alumina ceramic is about 1 mm. About 4-μm-thick interconnect electrodes 102D made of Ag were selectively formed on the surface of the mounting substrate 101D.

In the comparative example, the interconnect electrodes 102D covered an entire third region 3 of an elliptical shape 119 and only part of a second region 2 thereof.

As illustrated in Sample 2 in Table 1, the mirror reflectivity of the interconnect electrodes 102D made of Ag is 12.9%, the diffuse reflectivity thereof is 69.1%, the total reflectivity thereof is 82.0%, and the proportion of mirror reflection from the interconnect electrodes 102D is 15.7%.

High-temperature fired alumina ceramic is exposed on at least a portion of the second region 2 between the interconnect electrodes 102D. As illustrated in Sample 1 in Table 1, the mirror reflectivity of high-temperature fired alumina ceramic is 1.1%, the diffuse reflectivity thereof is 94.4%, the total reflectivity thereof is 95.5%, and the proportion of mirror reflection from high-temperature fired alumina ceramic is 1.2%. The a-axis width of a region where the high-temperature fired alumina ceramic is exposed is about 80 μm. The proportion of the area of the region where the high-temperature fired alumina ceramic is exposed to the area of a mounting surface effective portion in the elliptical shape 119 is 8.7%.

The wavelength of light emitted from the semiconductor light emitting device of the comparative example that is operating at a current of 5 mA was 410 nm. When the degree of polarization of the light emitted from the semiconductor light emitting device that is operating at a current of 5 mA was measured, the degree of polarization was 0.24.

As such, according to the first through fourth examples, a decrease in the degree of polarization of light emitted from a nitride semiconductor light emitting device having a nonpolar plane, such as an a- or m-plane, or a semipolar plane, such as a (20-21), (20-2-1), (10-1-3), -r-, or (11-22) plane as a growth surface can be reduced.

While, in the first through seventh embodiments described above, the configuration that allows the degree of polarization of light exiting from a nitride semiconductor light emitting device to be maintained was described, the configuration that can reduce the degree of polarization of the exiting light will be described below in eighth through fourteenth embodiments.

### Eighth Embodiment

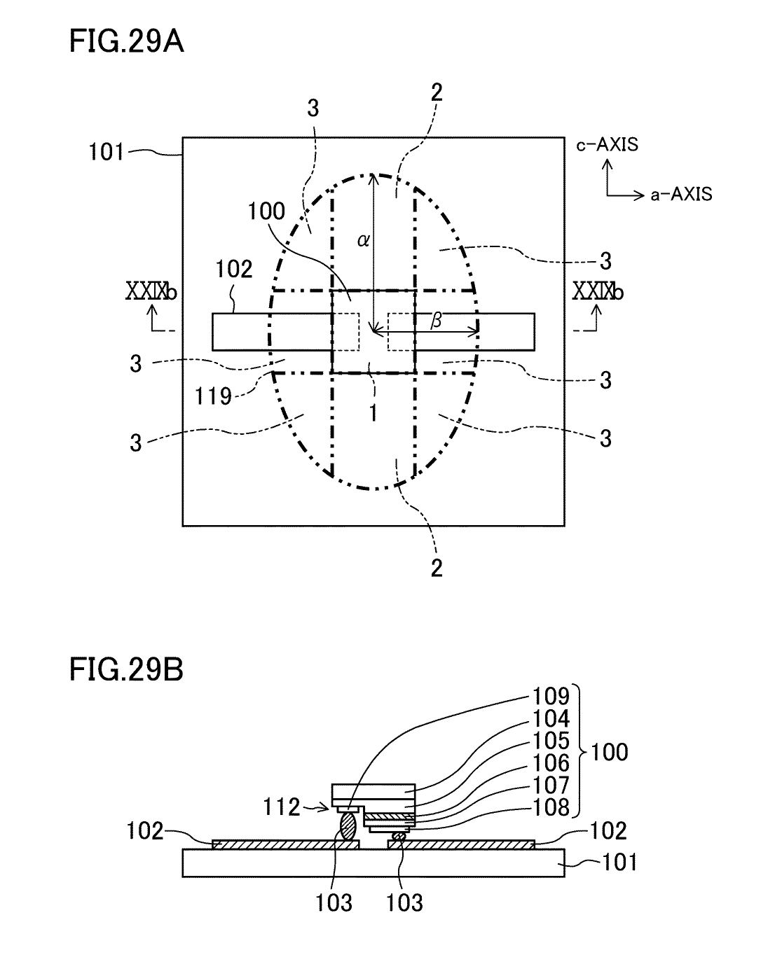

A semiconductor light emitting device according to an eighth embodiment of the present disclosure will be described hereinafter with reference to FIGS. 29A and 29B.

First, as illustrated in FIG. 29B, a semiconductor light emitting chip 100 made of a nitride semiconductor includes a substrate 104 including a GaN layer (hereinafter referred to as an m-plane GaN layer) that has an m-plane as its principal surface (and a growth surface) and is formed, for example, on at least a surface of the substrate 104, an n-type nitride semiconductor layer 105 formed on the principal surface of the substrate 104, an active layer 106 formed on the n-type nitride semiconductor layer 105 and made of a nitride semiconductor, a p-type nitride semiconductor layer 107 formed on the active layer 106, a p-side electrode 108 formed on and in contact with the p-type nitride semiconductor layer 107, and an n-side electrode 109 formed on and in contact with an exposed portion of the n-type nitride semiconductor layer 105. The growth surface of each of the n-type nitride semiconductor layer 105, the active layer 106, and the p-type nitride semiconductor layer 107 is substantially parallel to m-planes. In other words, the layers 105, 106, and 107 are stacked along the m-axis. Another layer may be formed between the n-type nitride semiconductor layer 105 and the active layer 106. Furthermore, another layer may be formed between the active layer 106 and the p-type nitride semiconductor layer 107. Here, a semiconductor (GaN-based semiconductor) made of a gallium nitride-based compound will be described as an example nitride semiconductor. The GaN-based semiconductor includes a semiconductor represented by the general expression AlₓIn_{y}Ga_{z}N (where 0≦x, y<1, 0<z≦1, and x+y+z=1).

As illustrated in FIGS. 29A and 29B, the semiconductor light emitting chip 100 is mounted on a mounting substrate 101 with the p-side and n-side electrodes 108 and 109 opposed to interconnect electrodes 102 that are placed on the surface of the mounting substrate 101. In other words, the semiconductor light emitting chip 100 is electrically connected to and held on the two interconnect electrodes 102 on the mounting substrate 101 with a bump 103 interposed between the semiconductor light emitting chip 100 and each of the interconnect electrodes 102. Such a structure is referred to as a flip-chip structure. One of the interconnect electrodes 102 is connected to the p-side electrode 108, and the other interconnect electrode 102 is connected to the n-side electrode 109.

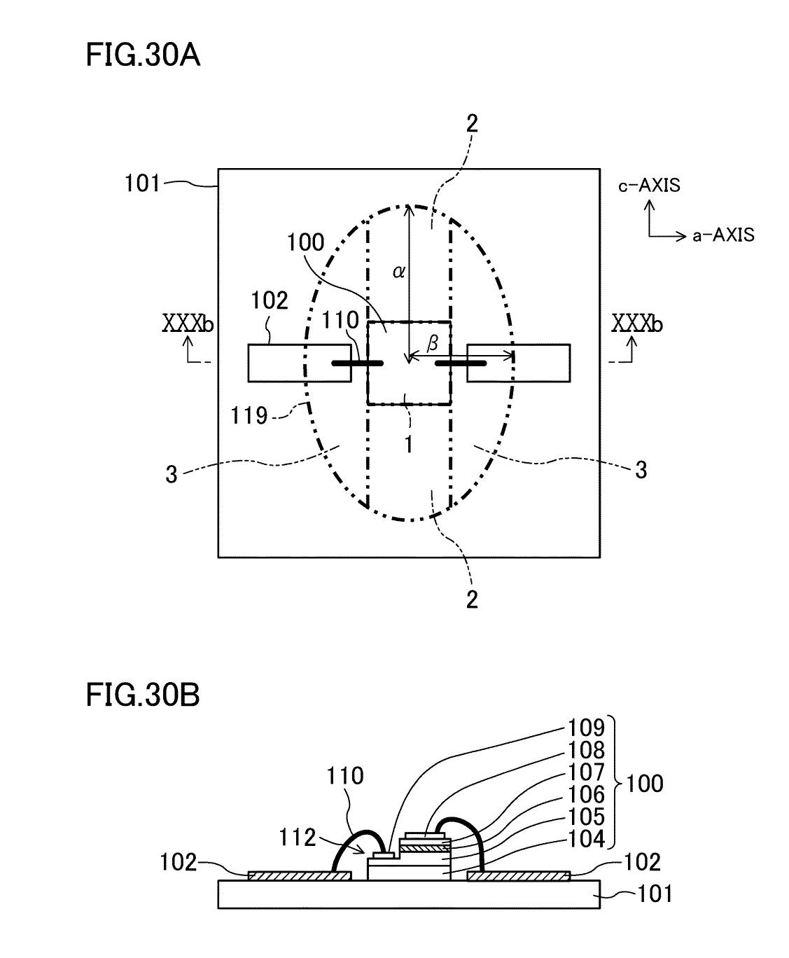

As illustrated in FIGS. 30A and 30B, instead of the flip-chip structure, a wire bonding structure can be employed in a first variation of this embodiment. In this case, the semiconductor light emitting chip 100 is held with the substrate 104 opposed to the surface of the mounting substrate 101. The p-side and n-side electrodes 108 and 109 are electrically connected through wires 110 made of gold (Au) to the interconnect electrodes 102 on the mounting substrate 101.

As such, the flip-chip structure and the wire bonding structure are different in terms of their processes used to connect the p-side and n-side electrodes 108 and 109 to the interconnect electrodes 102 on the mounting substrate 101. However, the other configuration in the first variation of the eighth embodiment are substantially similar to that in the eighth embodiment, and when the embodiment of the present disclosure is used, operational advantages in the first variation of the eighth embodiment are also similar to those in the eighth embodiment. Therefore, the flip-chip structure will be described hereinafter.

The substrate 104 may be a hexagonal m-plane GaN substrate, a hexagonal m-plane SiC substrate having a surface on which an m-plane GaN layer is formed, or an r-plane sapphire substrate, an m-plane sapphire substrate, or an a-plane sapphire substrate having a surface on which an m-plane GaN layer is formed. Furthermore, the substrate 104 may be removed.

The n-type nitride semiconductor layer 105 is made of, e.g., n-type AlᵤGaᵥIn_{w}N (where 0≦u, v, w≦1 and u+v+w=1). For example, silicon (Si) can be used as an n-type dopant.

The active layer 106 includes a plurality of barrier layers made of In_{Y}Ga_{1-Y}N (where 0≦Y<1), and at least one well layer vertically interposed between an adjacent pair of the barrier layers and made of InₓGa₁₋ₓN (where 0<X≦1). The well layer included in the active layer 106 may be a single layer. Alternatively, the active layer 106 may have a multiple quantum well (MQW) structure in which well layers and barrier layers are alternately stacked. The wavelength of light emitted from the semiconductor light emitting chip 100 depends on the In content ratio x of an InₓGa₁₋ₓN semiconductor that is a semiconductor composition of the well layer.

The p-type nitride semiconductor layer 107 is made of, e.g., a p-type AlₛGaₜN (where 0≦s, t≦1 and s+t=1) semiconductor. For example, magnesium (Mg) can be used as a p-type dopant. As the p-type dopant, instead of Mg, zinc (Zn) or beryllium (Be), for example, may be used. The Al content ratio s of the p-type nitride semiconductor layer 107 may be uniform along the thickness thereof, or may vary along the thickness thereof in a continuous or stepwise manner. Specifically, the thickness of the p-type nitride semiconductor layer 107 is, e.g., about 0.05-2 μm. The Al content ratio s of a portion of the p-type nitride semiconductor layer 107 near an upper surface thereof, i.e., a portion thereof near the interface between the p-type nitride semiconductor layer 107 and the p-side electrode 108, may be zero. In other words, the portion of the p-type nitride semiconductor layer 107 near the upper surface thereof may be made of GaN. In this case, GaN may contain a high concentration of p-type impurities, and may function as a contact layer with the p-side electrode 108.

The p-side electrode 108 may cover substantially the entire surface of the p-type nitride semiconductor layer 107. The p-side electrode 108 is made of, e.g., a layered structure (Pd/Pt) in which a palladium (Pd) layer and a platinum (Pt) layer are stacked. In order to increase the reflectivity of emitted light, a layered structure (Ag/Pt) in which a silver (Ag) layer and a platinum (Pt) layer are stacked, or a layered structure (Pd/Ag/Pt) in which a Pd layer, an Ag layer, and a Pt layer are sequentially stacked may be used as the p-side electrode 108.

The n-side electrode 109 is made of, e.g., a layered structure (Ti/Pt) in which a titanium (Ti) layer and a platinum (Pt) layer are stacked. In order to increase the reflectivity of emitted light, a layered structure (Ti/Al/Pt) in which a Ti layer, an Al layer, and a Pt layer are sequentially stacked may be used.

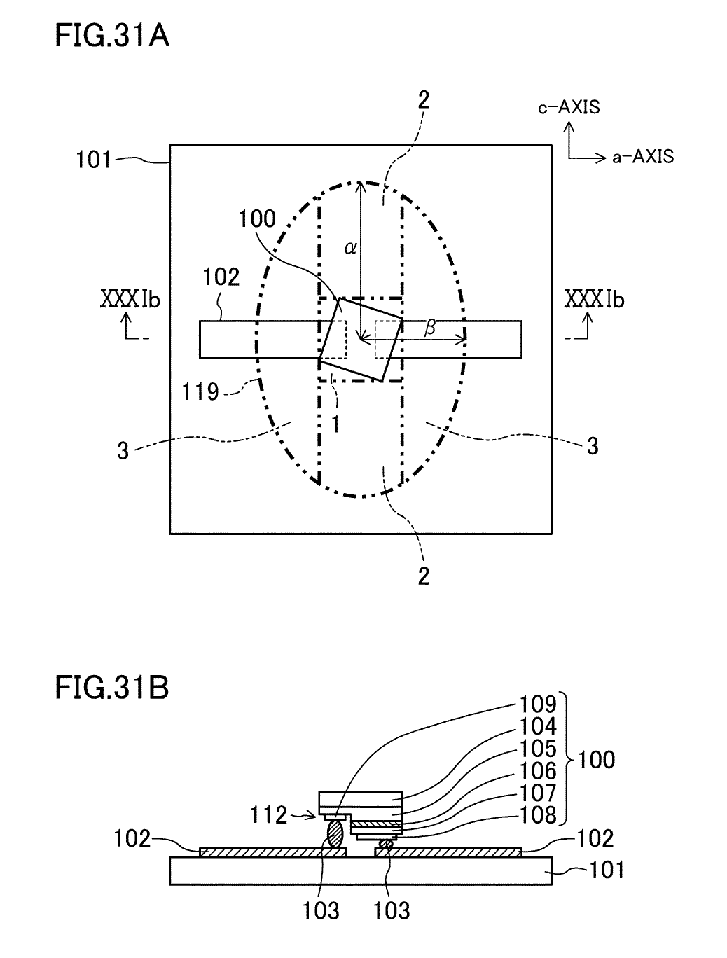

The semiconductor light emitting chip 100 illustrated in FIGS. 29A and 29B is one of square or rectangular pieces into which a wafer including stacked semiconductor layers is singulated along the a- and c-axes. In this case, a c-plane of a nitride semiconductor is easily cleaved, and thus, a singulation process step can be simplified. Alternatively, as illustrated in a second variation in FIGS. 31A and 31B, the semiconductor light emitting chip 100 may be one of pieces into which the wafer is singulated along directions inclined from the a- and c-axes. In this case, planes that are difficult to be cleaved are exposed at the side surfaces of the semiconductor light emitting chip 100. This exposure tends to cause the side surfaces of the semiconductor light emitting chip 100 to be uneven. The uneven surfaces enhance the light extraction efficiency at which emitted light is extracted from the side surfaces.

Features of the eighth embodiment are the reflection properties of the surface of the mounting substrate 101 (hereinafter referred to as the mounting surface), and the layout of components placed on the mounting surface. The reflection properties of the mounting surface of the mounting substrate 101, and the layout of components placed on the mounting surface will be described hereinafter in detail.

As described above, the semiconductor light emitting chip 100 including the active layer 106 having the m-plane as its principal surface (and the growth surface) and made of a nitride semiconductor has polarization characteristics. As a result, when emitted light is viewed from the m-axis, a contour line along which the light intensities are equal forms a shape close to an elliptical shape having a radius along the c-axis perpendicular to the polarization direction of the light as a major axis radius α, and a radius along the a-axis corresponding to the polarization direction of the light as a minor axis radius β. Since, as described below, the radiation angle of light emitted along the c-axis perpendicular to the polarization direction of the light is about 160°, and the radiation angle of light emitted along the a-axis corresponding to the polarization direction of the light is about 140°, the emitted light forms a shape close to an elliptical shape, and the ratio of the major axis of the elliptical shape to the minor axis thereof is 2:1. In other words, the major axis radius α is substantially twice as large as the minor axis radius β (α=2β). Furthermore, reflected light off the mounting surface also forms a shape close to an elliptical shape. In this case, the center of the elliptical shape substantially coincides with the center of gravity of the planar shape of the semiconductor light emitting chip 100. In FIG. 29A, the outline of an elliptical shape 119 shows the perimeter of a region illuminated principally with light emitted from the semiconductor light emitting chip 100 to the outside. The mounting surface strongly affects light reflected off a region in the elliptical shape 119. The mounting surface does not actually include such an elliptical shape. Here, suppose that the semiconductor light emitting chip 100 forms the shape of a square with sides having a length L when viewed in plan, and has a thickness T. A portion of the mounting surface having substantially the same area as the surface area of the semiconductor light emitting chip 100 significantly contributes to reflection, and thus, the following expression (11) holds.

παβ−L²=L²+4TL (11)

Here, the left-hand side of expression (11) corresponds to a value obtained by subtracting the area L² of the semiconductor light emitting chip 100 when viewed in plan from the area παβ of the elliptical shape 119, and can be considered as the area of a portion of the mounting surface that is located inside the elliptical shape 119 and can effectively contribute to reflection. The portion of the mounting surface is referred to as the mounting surface effective portion. The right-hand side of expression (11) corresponds to the area of a surface of the semiconductor light emitting chip 100 contributing to light extraction. Since the major axis radius α is twice as large as the minor axis radius β, the major axis radius α and the minor axis radius β of the elliptical shape 119 are represented by expressions (12) and (13), respectively, based on expression (11).

α=2√{(L²+2TL)/π} (12)

β=√{(L²+2TL)/π} (13)

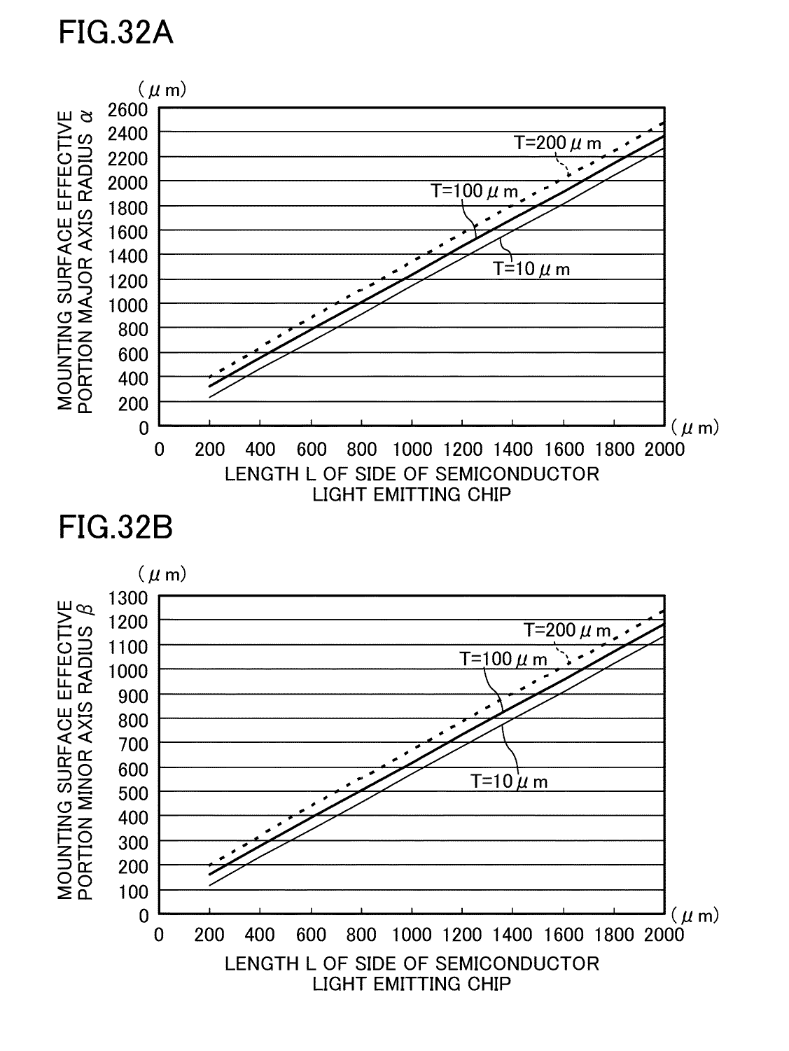

FIG. 32A illustrates the major axis radius α of the mounting surface effective portion as a function of the length L of each of the sides of the semiconductor light emitting chip 100, and FIG. 32B illustrates the minor axis radius β of the mounting surface effective portion thereas. In FIGS. 32A and 32B, the thickness T of the semiconductor light emitting chip 100 is varied among 10 μm, 100 μm, and 200 μm. As seen from FIGS. 32A and 32B, the major axis radius α and the minor axis radius β are substantially linear with respect to the length L of the side of the chip, and with increasing length L of the side, the major axis radius α and the minor axis radius β increase. Furthermore, with increasing chip thickness T, the major axis radius α and the minor axis radius β increase. Similar statements apply to nonpolar planes other than the m-planes, and semipolar planes. As described above, an active layer made of a nitride semiconductor having a nonpolar plane, such as an m- or a-plane, or a semipolar plane, such as a (20-21), (20-2-1), (10-1-3), (11-22), -r-, or (11-22) plane, as a growth surface and made of a nitride semiconductor also has polarization characteristics. As a result, when emitted light is viewed from the active layer, a contour line along which the light intensities are equal forms a shape close to an elliptical shape having a radius in a direction perpendicular to the polarization direction of the light as a major axis radius α, and a radius in the polarization direction of the light as a minor axis radius β. Furthermore, reflected light off the mounting surface also forms a shape close to an elliptical shape.

Next, the mounting surface of the mounting substrate 101 is sectioned into three regions.

As illustrated in FIG. 29A, when viewed in plan, a region of the mounting surface inside the elliptical shape 119 is sectioned into nine sub-regions using two straight lines parallel to the c-axis of the active layer 106 and two straight lines parallel to the a-axis thereof such that the semiconductor light emitting chip 100 is surrounded by the straight lines. One of the nine sub-regions containing the semiconductor light emitting chip 100 is a first region 1. Furthermore, a group of two of the nine sub-regions located outside the first region 1 and being adjacent to the first region 1 along the c-axis is a second region 2, and a group of six of the nine sub-regions except the first and second regions 1 and 2 is a third region 3.

The first region 1 is defined by the two straight lines parallel to the c-axis and the two straight lines parallel to the a-axis such that its area is minimum. A portion of the inner region of the elliptical shape 119 except the first region 1 corresponds to the mounting surface effective portion. In each of the semiconductor light emitting devices illustrated in FIGS. 29A-30B, the outline of the semiconductor light emitting chip 100 when viewed in plan coincides with the outline of the first region 1. On the other hand, in the semiconductor light emitting device illustrated in FIGS. 31A and 31B, the area of the first region 1 is larger than that of the semiconductor light emitting chip 100 when viewed in plan.

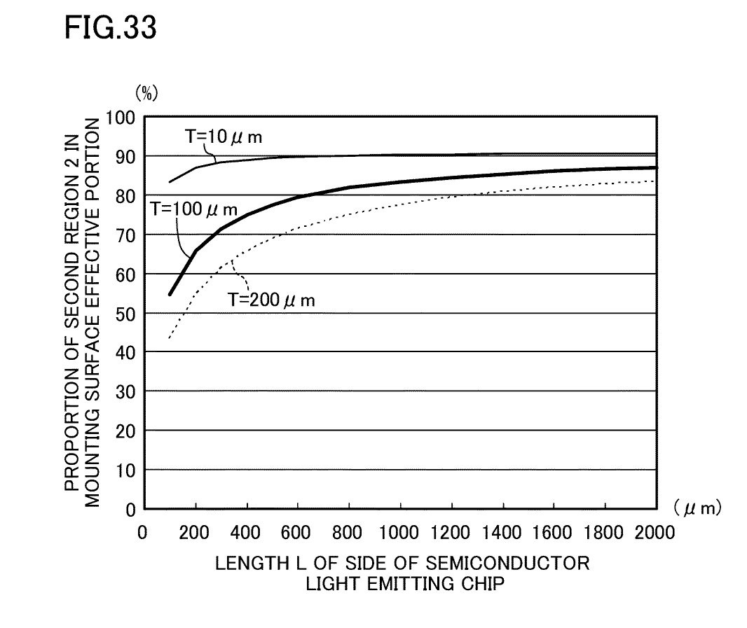

FIG. 33 illustrates the relationship between the proportion of the second region 2 in the mounting surface effective portion and the length L of a side of the semiconductor light emitting chip 100. The thickness T of the semiconductor light emitting chip 100 is varied among 10 μm, 100 μm, and 200 μm. With increasing length L of the side of the chip, the proportion of the second region 2 increases. Furthermore, with decreasing chip thickness T, the proportion of the second region 2 increases.

When the thickness T and the length L of the side are equal to each other (T=L), the proportion of the second region 2 is substantially 50%, and when the thickness T is less than the length L (T<L), the proportion of the second region 2 is higher than 50%. Therefore, when the thickness T is less than the length L (T<L), the second region 2 predominantly occupies the mounting surface effective portion.

When the thickness T is equal to the length L divided by six (T=L/6), the proportion of the second region 2 is substantially 80%, and when the thickness T is less than the length L divided by six (T<L/6), the proportion of the second region 2 is higher than 80%. Therefore, when the thickness T is less than the length L divided by six (T<L/6), the second region 2 very predominantly occupies the mounting surface effective portion.

The general size L of the semiconductor light emitting chip 100 is 200-1000 μm, and the chip thickness T is equal to or less than 150 μm. Thus, in these ranges, the proportion of the second region 2 is higher than 50%. In particular, when the chip size is increased to provide higher output power, the second region 2 grows in influence. In other words, in the semiconductor light emitting device including the semiconductor light emitting chip 100 including the active layer 106 having the m-plane as the growth surface, regions of the mounting surface of the mounting substrate 101 significantly contributing to reflection as a reflection surface correspond to the second region 2 illustrated in FIG. 29A. The present inventors found such findings.

Regions of the mounting substrate 101 illuminated with light from the active layer 106 and located laterally outward from the semiconductor light emitting chip 100 along the c-axis perpendicular to the polarization direction of the light are referred to as high polarization regions. Light reflected off the high polarization regions includes a large amount of light with electric field intensity varying along the a-axis corresponding to the polarization direction of the light from the semiconductor light emitting chip 100. The high polarization regions include, for example, the second region 2.

Furthermore, regions of the mounting substrate 101 illuminated with light from the active layer 106 except the high polarization regions are referred to as low polarization regions. Light reflected off the low polarization regions includes a large amount of light with electric field intensity varying in directions other than the direction along the a-axis. The low polarization regions include, for example, the third region 3.

The reflectivity of the object surface is classified into mirror reflectivity and diffuse reflectivity. Herein, the total reflectivity denotes the sum of the mirror reflectivity and diffuse reflectivity. The proportion of mirror reflection denotes the proportion of the mirror reflectivity to the total reflectivity. Although described below in detail, with increasing proportion of the diffuse reflectivity, the degree of polarization of reflected light decreases.

In the eighth embodiment, the surface of the second region 2 is covered with a material having a higher diffuse reflectivity than its mirror reflectivity. Here, at least the surface of the second region 2 merely needs to be made of a material having a higher diffuse reflectivity than its mirror reflectivity, and the constituent material (principal material) of the mounting substrate 101 may be different from that of the surface of the second region 2. In other words, a material having a high diffuse reflectivity is placed on the second region 2 predominantly occupying the mounting surface effective portion, thereby efficiency reducing the degree of polarization.

Furthermore, the material having a higher diffuse reflectivity than its mirror reflectivity may have insulating properties. Moreover, the proportion of mirror reflection from the surface of the second region 2 may be less than 10%, and the diffuse reflectivity of the surface of the second region 2 may be higher than or equal to 90%. The proportion of mirror reflection may be less than 2%, and the diffuse reflectivity may be higher than or equal to 94%. This can reduce the degree of polarization while maintaining high light output.

In the eighth embodiment, the interconnect electrodes 102 having a higher mirror reflectivity than the second region 2 are formed on at least portions of the surface of the third region 3. As long as the interconnect electrodes 102 are located to function as electrodes, they may form any shape, and only portions of the interconnect electrodes 102 on the third region 3 may have a higher mirror reflectivity than the second region 2. The principal material of the mounting substrate 101 may be different from the material of the uppermost surface of the mounting substrate 101, i.e., the material of the interconnect electrodes 102.

The proportion of mirror reflection from the surfaces of the interconnect electrodes 102 may be higher than or equal to 12%, and the diffuse reflectivity of the surfaces of the interconnect electrodes 102 may be less than 69%.

When, as such, a material having high mirror reflectivity is placed on the third region 3 which does not predominantly contribute to reflection as the reflection surface off which emitted light is reflected, this can also reduce the degree of polarization while maintaining high light output.

Here, the interconnect electrodes 102 may have a surface roughness greater than or equal to 200 nm. This allows the diffuse reflectivity of the surfaces of the interconnect electrodes 102 to be higher than or equal to 50%, and thus, the degree of polarization of light reflected off the third region 3 can be also reduced.

Furthermore, the total area of portions of the interconnect electrodes 102 located on the third region 3 may be 10% or less of the area of the mounting surface effective portion. This can reduce a problem where the degree of polarization is less likely to be reduced to a sufficient level due to the interconnect electrodes 102. Specifically, the total area of the portions of the interconnect electrodes 102 located on the third region 3 may be set to the value satisfying the following expression (14):

Set Area<(L²+4TL)/10 (14)

where L is the length of a side of the semiconductor light emitting chip 100, and T is the thickness of the chip 100.

When the material placed on the second region 2 and having a higher diffuse reflectivity than its mirror reflectivity has insulating properties, the interconnect electrodes 102 located on the third region 3 may be formed on portions of the surface of the material having a higher diffuse reflectivity. With this configuration, the mounting substrate 101 is easily fabricated.

An insulative material, such as alumina (aluminum oxide) or aluminum nitride (AlN), a metal material, such as aluminum (Al), copper (Cu), or tungsten (W), a semiconductor material, such as silicon (Si) or germanium (Ge), or a composite of the materials can be used as the principal material forming the mounting substrate 101.

When the principal material of the mounting substrate 101 is alumina or AlN, the principal material itself may be exposed on the second region 2. When the principal material of the mounting substrate 101 is metal, such as Al, Cu, or W, or a semiconductor, such as Si or Ge, the surface of the mounting substrate 101 may be covered with an insulating film. In this case, for example, a silicone resin containing fine particles made of, e.g., titanium dioxide (TiO₂), zinc oxide (ZnO), or silicon dioxide (SiO₂) can be used for the insulating film. Alternatively, a composite obtained by placing ceramic, such as alumina, on the metal surface can be used. Such a material can have a higher diffuse reflectivity than its mirror reflectivity while offering high reflectivity.

By contrast, a material having, e.g., aluminum (Al), silver (Ag), gold (Au) or copper (Cu) as the main ingredient can be used as a constituent material of the interconnect electrodes 102. The proportion of mirror reflection from the interconnect electrodes 102 is higher than or equal to 12%.

In this embodiment, a region of the mounting surface of the mounting substrate 101 outside the elliptical shape 119 does not significantly affect operating characteristics of the semiconductor light emitting device. Therefore, an optional material or component (electronic component) may be placed on the region outside the elliptical shape 119.

As described above, according to the eighth embodiment, while the degree of polarization of light reflected off the mounting surface of the mounting substrate 101 on which the semiconductor light emitting chip 100 is held is decreased to a sufficient level, a metal material or other materials which are less likely to reduce the degree of polarization of the reflected light can be appropriately placed on the mounting surface.

(Fabrication Method)

A method for fabricating a semiconductor light emitting device according to the eighth embodiment will be described hereinafter with reference to FIGS. 29A and 29B.

First, an n-type nitride semiconductor layer 105 is epitaxially grown on the principal surface of a substrate 104 having an m-plane as its principal surface and made of n-type GaN by metal organic chemical vapor deposition (MOCVD) or any other method. Specifically, for example, silicon (Si) is used as an n-type dopant, trimethylgallium (TMG (Ga(CH₃)₃)) being a gallium source, and ammonia (NH₃) being a nitrogen source are supplied to the substrate 104, and the about 1-3-μm-thick n-type nitride semiconductor layer 105 made of GaN is formed at growth temperatures approximately higher than or equal to 900° C. and equal to or less than 1100° C. In this stage, the substrate 104 is a substrate at the wafer level, and a plurality of light emitting structures forming semiconductor light emitting devices can be fabricated at once.

Next, an active layer 106 made of a nitride semiconductor is grown on the n-type nitride semiconductor layer 105. The active layer 106 has an InGaN/GaN multiple quantum well (MQW) structure in which, for example, 15-nm-thick well layers made of In₁₋ₓGaₓN and 10-nm-thick barrier layers made of GaN are alternately stacked. When the well layers made of In₁₋ₓGaₓN are formed, the growth temperatures may be decreased to about 700-800° C. to ensure incorporation of In into the well layers being grown. The wavelength of emitted light is selected based on uses of the semiconductor light emitting device, and the In content ratio x is determined based on the wavelength. For example, when the wavelength is 450 nm (blue light wavelength), the In content ratio x is determined to be 0.25-0.27. When the wavelength is 520 nm (green light wavelength), the In content ratio x is determined to be 0.40-0.42. When the wavelength is 630 nm (red light wavelength), the In content ratio x is determined to be 0.56-0.58.

Next, a p-type nitride semiconductor layer 107 is epitaxially grown on the active layer 106. Specifically, for example, Cp2Mg (bis(cyclopentadienyl) magnesium) is used as p-type impurities, TMG and NH₃ are supplied, as materials, to the substrate 104, and the about 50-500-nm-thick p-type nitride semiconductor layer 107 made of p-type GaN is formed on the active layer 106 at growth temperatures approximately higher than or equal to 900° C. and equal to or less than 1100° C. The p-type nitride semiconductor layer 107 may contain an about 15-30-nm-thick p-type AlGaN layer. The formation of the p-type AlGaN layer can reduce the overflow of electrons that are carriers. An undoped GaN layer may be formed between the active layer 106 and the p-type nitride semiconductor layer 107.

Next, in order to activate Mg with which the p-type nitride semiconductor layer 107 is doped, the p-type nitride semiconductor layer 107 is thermally treated at temperatures of about 800-900° C. for about 20 minutes.

Next, a semiconductor layered structure including the substrate 104, the n-type nitride semiconductor layer 105, the active layer 106, and the p-type nitride semiconductor layer 107 is selectively etched by lithography and dry etching using a chlorine (Cl₂) gas. Thus, a recess 112 is formed by removing a portion of the p-type nitride semiconductor layer 107, a portion of the active layer 106, and a portion of the n-type nitride semiconductor layer 105 to expose a region of the n-type nitride semiconductor layer 105.

Next, an n-side electrode 109 is selectively formed on and in contact with the exposed region of the n-type nitride semiconductor layer 105. Here, for example, a multilayer film (Ti/Pt layer) of titanium (Ti) and platinum (Pt) is formed as the n-side electrode 109.

Next, a p-side electrode 108 is selectively formed on and in contact with the p-type nitride semiconductor layer 107. For example, a multilayer film (Pd/Pt layer) of palladium (Pd) and platinum (Pt) is formed as the p-side electrode 108. Thereafter, heat treatment is performed to alloy a region between the Ti/Pt layer and the n-type nitride semiconductor layer 105 and a region between the Pd/Pt layer and the p-type nitride semiconductor layer 107. The order in which the n-side electrode 109 and the p-side electrode 108 are formed is not particularly limited.

Next, a (back) surface of the substrate 104 opposite to the n-type nitride semiconductor layer 105 is polished to reduce the thickness of the substrate 104 by a predetermined amount.

The wafer-level substrate 104 is singulated into individual semiconductor light emitting chips 100 corresponding to a plurality of semiconductor light emitting devices fabricated as above. Examples of this singulation process include some processes, such as laser dicing and cleavage. The individual semiconductor light emitting chips 100 into which the substrate 104 has been singulated are mounted on a mounting surface of a mounting substrate 101. Here, a flip-chip structure will be described.

First, the mounting substrate 101 is prepared. As described above, an insulative material, such as alumina or AlN, a metal material, such as Al or Cu, a semiconductor material, such as Si or Ge, or a composite of the materials can be used as the principal material of the mounting substrate 101. The location of each of interconnect electrodes 102 may correspond to that of a corresponding one of electrodes of the semiconductor light emitting chip 100. A metal material having, e.g., Cu, Au, Ag, or Al as the main ingredient can be used as the interconnect electrodes 102.

A metal film for forming interconnect electrodes is formed on the surface of the mounting substrate 101 through a film formation process, such as sputtering or plating. Thereafter, a desired resist pattern is formed on the formed metal film by, e.g., lithography. In this case, the resist pattern is designed such that interconnect electrodes 102 obtained by patterning the metal film are formed astride at least a portion of the third region 3 and a region of the mounting substrate 101 located outward from the third region 3. Thereafter, the resist pattern is transferred to the metal film by dry etching or wet etching to form interconnect electrodes 102 each having a desired electrode pattern.

Next, a plurality of bumps 103 are formed on predetermined portions of the interconnect electrodes 102. Gold (Au) is preferably used as a constituent material of the bumps 103. The bumps 103 each having a diameter of about 40-80 μm can be formed with a bump bonder. The bumps 103 can be formed by Au plating instead of with a bump bonder. The surfaces of the electrodes of the semiconductor light emitting chip 100 are connected onto the interconnect electrodes 102 on which the plurality of bumps 103 are formed as above by, e.g., ultrasonic welding.

As such, the semiconductor light emitting device according to the eighth embodiment can be obtained.

### Ninth Embodiment

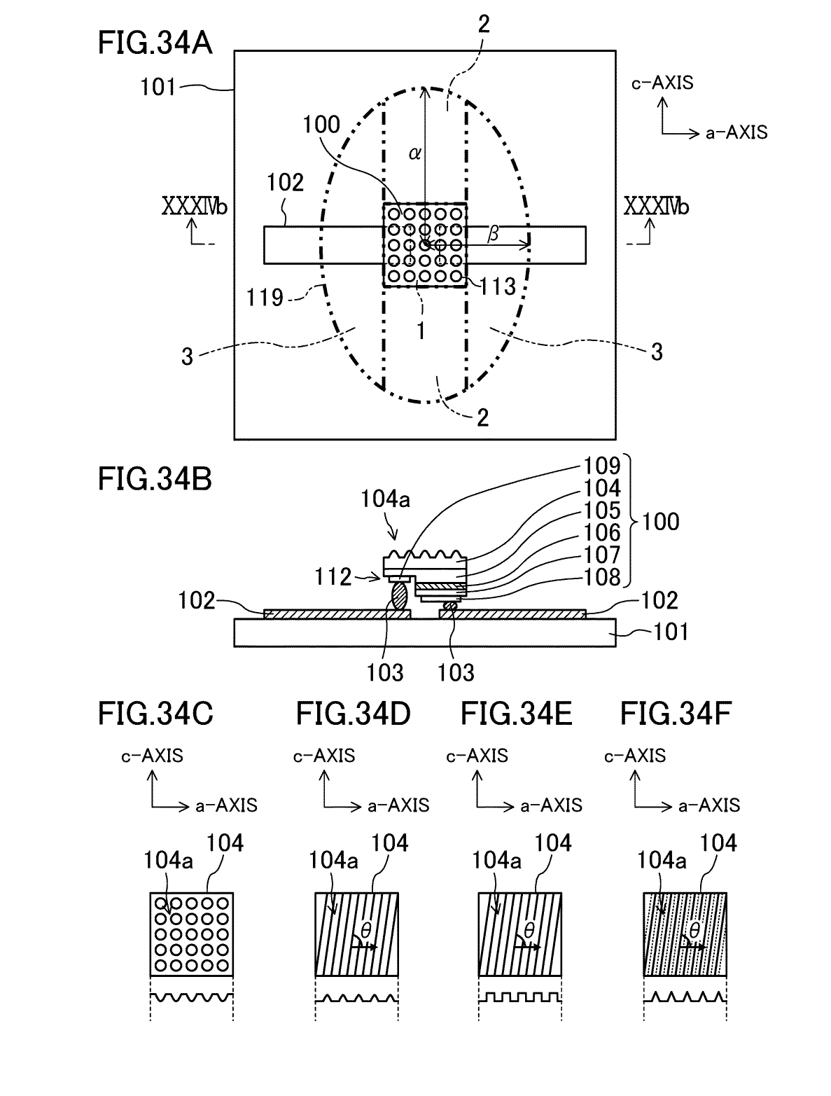

A semiconductor light emitting device according to a ninth embodiment of the present disclosure will be described hereinafter with reference to FIGS. 34A-34F. In FIG. 34A-34F, the same characters as those in FIGS. 3A and 3B are used to represent equivalent components, and thus, description thereof is omitted. The same applies to the following embodiments. The difference between the eighth and ninth embodiments will be described.

As illustrated in FIGS. 34A and 34B, the ninth embodiment is different from the eighth embodiment in that a surface of a semiconductor light emitting chip 100, specifically, a light extraction surface of a substrate 104 opposite to a mounting substrate 101, has a plurality of raised/recessed portions 104a. Here, raised portions of the raised/recessed portions 104a have a generally semicircular shape when viewed in cross section taken along a direction perpendicular to the substrate surface. When light passes through the raised/recessed portions 104a, emitted light is scattered, and thus, the degree of polarization of the light can be reduced.

The raised/recessed portions 104a can be formed on the back surface of the substrate 104 by reducing the thickness of the substrate 104, then forming a resist pattern by lithography, and processing the back surface of the substrate 104 by dry etching using a gas containing chlorine to allow the back surface to be uneven.

FIGS. 34C-34F illustrate variations of the raised/recessed portions 104a.

As illustrated in FIG. 34C, instead of the cross-sectional shape of each of the raised portions, the cross-sectional shape of each of the recessed portions may be generally semicircular. As illustrated in FIGS. 34D, 34E, and 34F, the raised/recessed portions 104a may be stripe-shaped when viewed in plan. FIG. 34D illustrates an example in which the cross-sectional shape of each of the raised portions is generally semicircular, FIG. 34E illustrates an example in which the cross-sectional shape of each of the raised portions is rectangular, and FIG. 34F illustrates an example in which the cross-sectional shape of each of the raised portions is triangular. The direction of extension of the stripes is inclined at an angle θ with respect to the a-axis of an active layer 106 made of a nitride semiconductor. When the angle θ is 0°, the degree of polarization is maintained, and thus, the angle θ may be greater than 0° and equal to or less than 90°. Alternatively, the angle θ may be greater than or equal to 30° and equal to or less than 90°.

A mounting surface effective portion of the ninth embodiment also has a configuration similar to that of the eighth embodiment. Specifically, at least the surface of a second region 2 defined inside an elliptical shape 119 is covered with a material having a higher diffuse reflectivity than its mirror reflectivity. Furthermore, interconnect electrodes 102 having a higher mirror reflectivity than the second region 2 are formed on at least portions of the surface of a third region 3.

According to the ninth embodiment, while the degree of polarization of emitted light reflected off a mounting surface of the mounting substrate 101 is reduced to a sufficient level, the degree of polarization of light emitted to the outside without being reflected off the mounting surface can be reduced. This can more significantly reduce the degree of polarization than the configuration of the eighth embodiment.

Although, in this embodiment, only a flip-chip structure was described, a wire bonding structure can also provide similar advantages.

### Tenth Embodiment

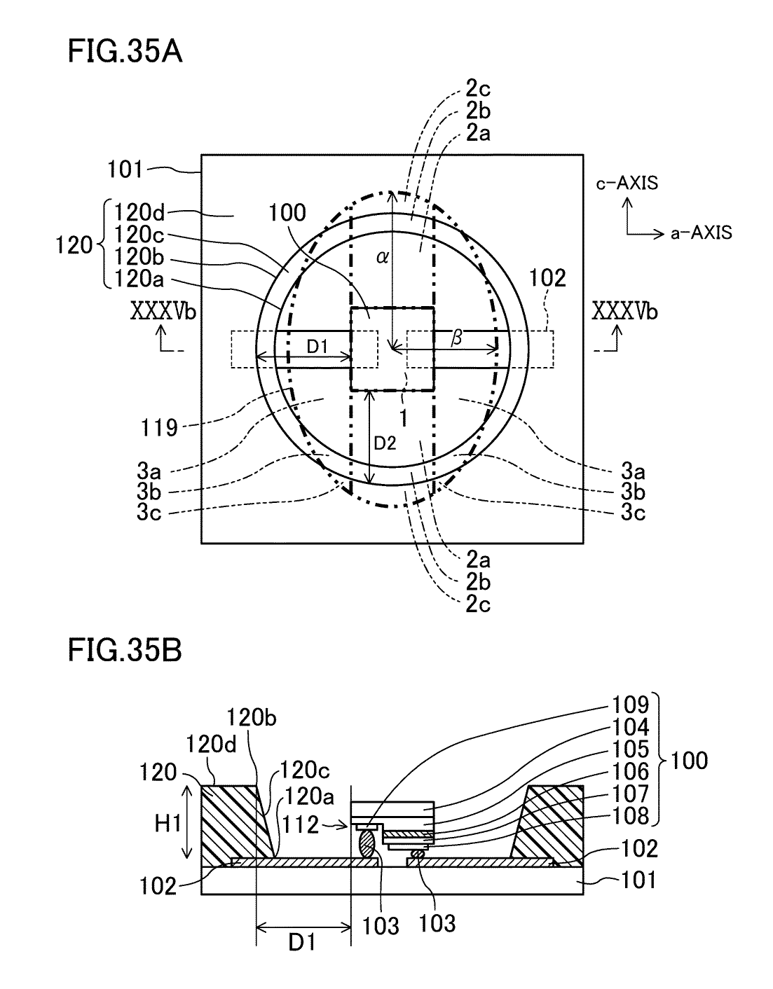

A semiconductor light emitting device according to a tenth embodiment of the present disclosure will be described hereinafter with reference to FIGS. 35A and 35B. Here, the difference between the eighth and tenth embodiments will be described.

As illustrated in FIGS. 35A and 35B, the tenth embodiment is different from the eighth embodiment in that a reflection member 120 is placed on a mounting surface of a mounting substrate 101. The reflection member 120 has a cavity. The reflection member 120 may control the directivity and radiation pattern of emitted light from a semiconductor light emitting chip 100. When the top surface of the semiconductor light emitting chip 100 is encapsulated with a transparent member, such as a silicone resin, the reflection member 120 functions as a cup (container) for the transparent member injected onto the top surface thereof. If the reflection member 120 serves to control the directivity and radiation pattern of emitted light from a semiconductor light emitting chip 100, the reflection member 120 is referred to also as a reflector.

The reflection member 120 has an opening 120a in its lower end surface being in contact with the mounting surface, an opening 120b in its upper end surface, a reflection surface 120c opposed to the side surfaces of the semiconductor light emitting chip 100, and an upper surface 120d. A material having a high light reflectivity is preferably used for the reflection surface 120c of the reflection member 120. For example, alumina can be used. Alternatively, a silicone resin containing fine particles of, e.g., titanium dioxide (TiO₂) may be used.

Although, in the tenth embodiment, each of the openings of the reflection member 120 is circular when viewed in plan, this shape is merely an example. For example, the opening of the reflection member 120 may be in the shape of an ellipse, an oval, or a polygon with three or more sides when viewed in plan.

Assume that H1 is the height of the reflection member 120, D1 is the distance from a side surface of the semiconductor light emitting chip 100 to the perimeter of the opening 120b in the upper end surface of the reflection member 120 along the a-axis, and D2 is the distance from a side surface of the semiconductor light emitting chip 100 to the perimeter of the opening 120b in the upper end surface of the reflection member 120 along the c-axis. Conditions where emitted light from the semiconductor light emitting chip 100 is effectively reflected off the reflection surface 120c of the reflection member 120 are that the radiation angle of light emitted along the c-axis is 160° and the radiation angle of light emitted along the a-axis is 140°, and thus, the distance D1 along the a-axis and the distance D2 along the c-axis are respectively given by the following expressions (15) and (16).

D1=H1·tan(140°/2)=2.75×H1 (15)

D2=H1·tan(160°/2)=5.67×H1 (16)

When the distances D1 and D2 are less than the values obtained from the expressions (15) and (16), respectively, the reflection surface 120c of the reflection member 120 strongly affects emitted light from the semiconductor light emitting chip 100. Therefore, when the reflection member 120 is provided in order to control the directivity and radiation pattern of light, the distances D1 and D2 are set less than the values obtained from the expressions (15) and (16), respectively.

The second region 2 is further sectioned into three portions: a portion 2a corresponding to an exposed portion of the surface of the mounting substrate 101; a portion 2b corresponding to the reflection surface 120c of the reflection member 120; and a portion 2c corresponding to the upper surface 120d of the reflection member 120. The portion 2b is a portion of the second region 2 on which the reflection surface 120c is located when viewed in plan from above the mounting substrate 101. In other words, the portion 2b corresponds to a region of the reflection surface 120c corresponding to the second region 2. The portion 2c is a portion of the second region 2 on which the upper surface 120d is located when viewed in plan from above the mounting substrate 101. In other words, the portion 2c corresponds to a portion of the upper surface 120d corresponding to the second region 2.

Similarly, the third region 3 is sectioned into three portions: a portion 3a corresponding to an exposed portion of the surface of the mounting substrate 101; a portion 3b corresponding to the reflection surface 120c of the reflection member 120; and a portion 3c corresponding to the upper surface 120d of the reflection member 120. The portion 3b is a portion of the third region 3 on which the reflection surface 120c is located when viewed in plan from above the mounting substrate 101. In other words, the portion 3b corresponds to a portion of the reflection surface 120c corresponding to the third region 3. The portion 3c is a portion of the third region 3 on which the upper surface 120d is located when viewed in plan from above the mounting substrate 101. In other words, the portion 3c corresponds to a portion of the upper surface 120d corresponding to the second region 2. Here, while the portions 2c and 3c are regions inside the elliptical shape 119, emitted light is not incident upon the portions 2c and 3c, and thus, the portions 2c and 3c do not function as a reflection surface off which light is reflected.

Specifically, in the tenth embodiment, the distance D1 in the third region 3 is less than 2.75×H1 represented by expression (15). Furthermore, the surfaces of the portions 2a and 2b of the second region 2 are covered with a material having a higher diffuse reflectivity than its mirror reflectivity. Furthermore, interconnect electrodes 102 having a higher mirror reflectivity than the surface of the second region 2 are formed on at least portions of the surface of the third region 3 that is less likely to affect the polarization characteristics of light.

According to the tenth embodiment, while the degree of polarization of light reflected off a mounting surface of the mounting substrate 101 is reduced to a sufficient level, the reflection member 120 placed on the mounting surface of the mounting substrate 101 can control the directivity and radiation pattern of emitted light.

While, in this embodiment, only the flip-chip structure was described, a wire bonding structure can also provide similar advantages.

### Eleventh Embodiment

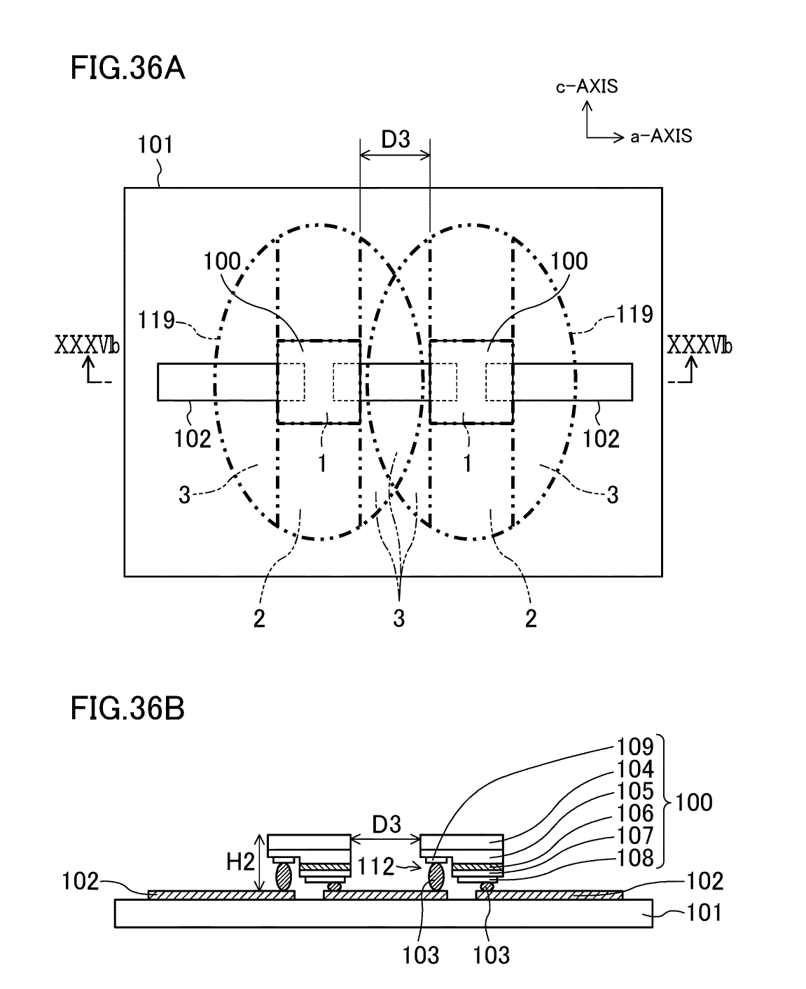

A semiconductor light emitting device according to an eleventh embodiment of the present disclosure will be described hereinafter with reference to FIGS. 36A and 36B. Here, the difference between the eighth and eleventh embodiments will be described.

As illustrated in FIGS. 36A and 36B, the eleventh embodiment is different from the eighth embodiment in that a plurality of semiconductor light emitting chips 100 are mounted on a mounting substrate 101. Here, two semiconductor light emitting chips 100 are substantially aligned along the a-axis. The number of the semiconductor light emitting chips 100 is not limited to two, and three or more semiconductor light emitting chips 100 may be substantially aligned along the a-axis.

As described above, the radiation angle of light emitted along the a-axis is less than that of light emitted along the c-axis, and thus, when the semiconductor light emitting chips 100 are aligned along the a-axis, emitted light waves from the adjacent semiconductor light emitting chips 100 are less likely to interfere with each other. When emitted light from one of the semiconductor light emitting chips 100 enters the other semiconductor light emitting chip 100, this causes problems, such as a decrease in light output due to light absorption, and variations in directivity and radiation pattern due to light reflection. However, when the semiconductor light emitting chips 100 are aligned along the a-axis, the distance between the semiconductor light emitting chips 100 emitting light waves that interfere with each other is equal to or less than half of that when the semiconductor light emitting chips 100 are aligned along the c-axis. This enables a dense arrangement of a plurality of semiconductor light emitting chips 100.

When D3 is the distance between the semiconductor light emitting chips 100 adjacent to each other along the a-axis, the distance D3′ between the semiconductor light emitting chips 100 emitting light waves that interfere with each other is given by the following expression (17), based on the fact that the radiation angle of light emitted along the a-axis is 140°.

D3′=H2·tan(140°/2)=2.75×H2 (17)

where H2 is the height from the mounting surface of the mounting substrate 101 to an upper surface of each of the semiconductor light emitting chips 100.

Therefore, when the distance D3′ is equal to or less than 2.75×H2, light emitted from a side surface of one of the adjacent semiconductor light emitting chips 100 and directed upward from the semiconductor light emitting device interferes with light emitted from the other semiconductor light emitting chip 100.

Also when a mounting surface effective portion inside an elliptical shape 119 formed by one of the semiconductor light emitting chips 100 overlaps an elliptical shape 119 formed by the other semiconductor light emitting chip 100, light waves interfere with each other.

The largest a-axis width of a group of three of sub-regions of a third region 3 that are adjacent along the c-axis, i.e., the distance D3″, is given by (minor axis radius β)−L/2, where L is the length of a side of each of the semiconductor light emitting chips 100, and thus, is given by the following expression (18) based on expression (13).

D3″=√{(L²+2TL)/π}−L/2 (18)

where T is the thickness of the semiconductor light emitting chip 100.

Specifically, a greater one of the distances D3′ and D3″ corresponds to a boundary value up to which light waves emitted from the semiconductor light emitting chips 100 interfere with each other.

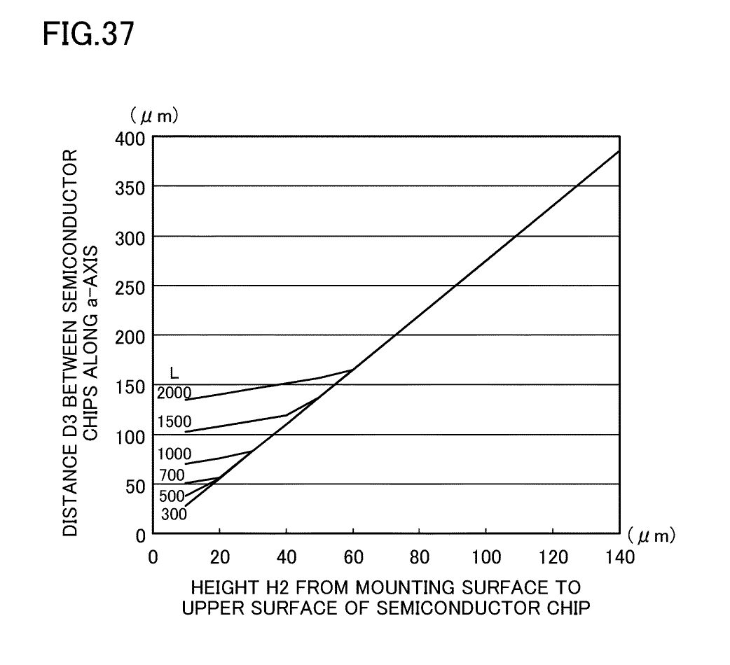

FIG. 37 illustrates the relationship between the height H2 from the mounting surface of the mounting substrate 101 to the upper surface of each of the semiconductor light emitting chips 100 and the distance D3 between the semiconductor light emitting chips 100 emitting light waves that interfere with each other along the a-axis. When the distance D3 is less than the corresponding value on a corresponding one of line graphs illustrated in FIG. 37, light waves emitted from the semiconductor light emitting chips 100 interfere with each other. The length L of a side of each of the semiconductor light emitting chips 100 is varied among 300 μm, 500 μm, 700 μm, 1000 μm, 1500 μm, and 2000 μm.

As seen from FIG. 37, with increasing height H2 of each of the semiconductor light emitting chips 100, light emitted from one of the adjacent semiconductor light emitting chips 100 and directed upward from the semiconductor light emitting device tends to interfere with light emitted from the other semiconductor light emitting chip 100. With increasing length L of a side of each of the semiconductor light emitting chips 100, light waves emitted from the semiconductor light emitting chips 100 tends to interfere with each other, because mounting surface effective portions overlap each other.

Therefore, when the distance D3 is greater than a smaller one of the distances D3′ and D3″ based on expressions (17) and (18), this can reduce the light interference occurring either with increasing height H2 or with increasing length L.

Furthermore, when the distance D3 is greater than a greater one of the distances D3′ and D3″, this can reduce the light interference occurring both with increasing height H2 and with increasing length L.

In the eleventh embodiment, the plurality of semiconductor light emitting chips 100 are preferably connected in series. When the semiconductor light emitting chips 100 are connected in parallel, the operating voltages of the plurality of semiconductor light emitting chips 100 need to be set substantially equal to one another; however, when the semiconductor light emitting chips 100 are connected in series, and the chips 100 have different operating voltages, this also allows the chips 100 to emit light.

According to the eleventh embodiment, the semiconductor light emitting device including the plurality of semiconductor light emitting chips 100 reduces the interference between light waves emitted from the adjacent semiconductor light emitting chips 100 while reducing the degree of polarization of emitted light reflected off the mounting surface of the mounting substrate 101 to a sufficient level, thereby enabling dense integration.

While, in this embodiment, only the flip-chip structure was described, a wire bonding structure can also provide similar advantages.

### Twelfth Embodiment

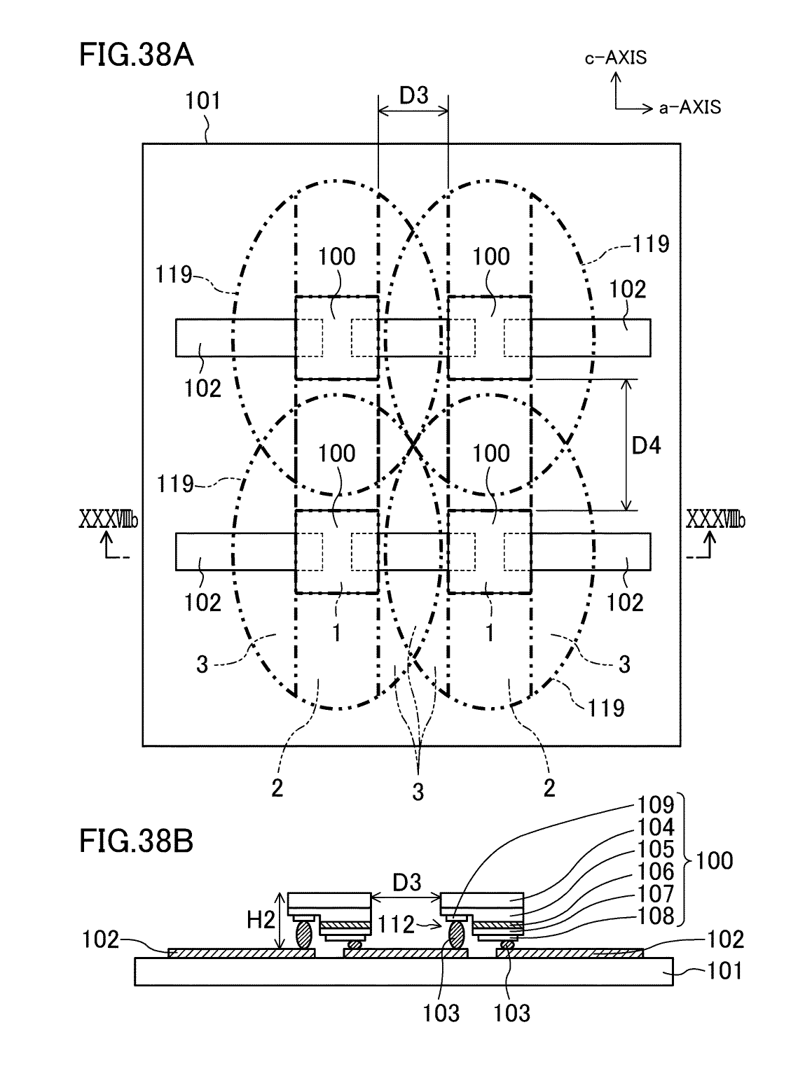

A semiconductor light emitting device according to a twelfth embodiment of the present disclosure will be described hereinafter with reference to FIGS. 38A and 38B. Here, the difference between the eleventh and twelfth embodiments will be described.

As illustrated in FIGS. 38A and 38B, the twelfth embodiment is different from the eleventh embodiment in that a plurality of semiconductor light emitting chips 100 are arranged on a mounting substrate 101 in an array. Here, four semiconductor light emitting chips 100 are arranged in two rows and two columns along the a- and c-axes. The number of the semiconductor light emitting chips 100 is not limited to four, and five or more semiconductor light emitting chips 100 may be arranged in an array with two or more rows and two or more columns.

When D4 is the distance between two of the semiconductor light emitting chips 100 that are adjacent to each other along the c-axis, the distance D4′ between the adjacent semiconductor light emitting chips 100 emitting light waves that interfere with each other is given by the following expression (19), based on the fact that the radiation angle of light emitted along the c-axis is 160°.

D4′=H2·tan(160°/2)=5.67×H2 (19)

where H2 is the height from the mounting surface of the mounting substrate 101 to an upper surface of each of the semiconductor light emitting chips 100.

Therefore, when the distance D4′ is equal to or less than 5.67×H2, light emitted from a side surface of one of the semiconductor light emitting chips 100 and directed upward from the semiconductor light emitting device interferes with light emitted from another one of the semiconductor light emitting chips 100 adjacent to the one of the semiconductor light emitting chips 100 along the c-axis.

Also when a mounting surface effective portion inside an elliptical shape 119 formed by one of the semiconductor light emitting chips 100 overlaps an elliptical shape 119 formed by another one of the semiconductor light emitting chips 100 aligned with the one of the semiconductor light emitting chips 100 along the c-axis, light waves emitted from the semiconductor light emitting chips 100 interfere with each other.

The largest c-axis width of each of sub-regions of the second region 2, i.e., the distance D4″, is given by (major axis radius α)−L/2, where L is the length of a side of each of the semiconductor light emitting chips 100, and thus, is given by the following expression (20) based on expression (12).

D4″=√{(L²+2TL)/π}−L/2 (20)

where T is the thickness of the semiconductor light emitting chip 100.

Specifically, a greater one of the distances D4′ and D4″ corresponds to a boundary value up to which light waves emitted from the semiconductor light emitting chips 100 interfere with each other.

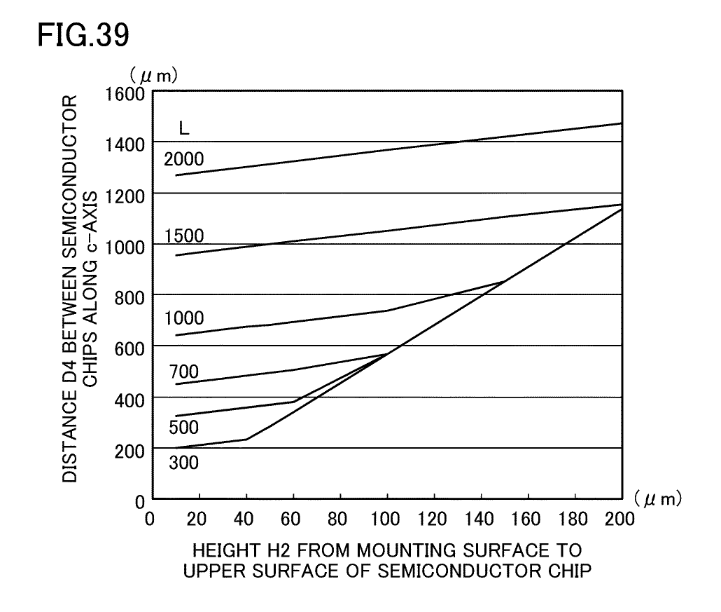

FIG. 39 illustrates the relationship between the height H2 from the mounting surface of the mounting substrate 101 to the upper surface of each of the semiconductor light emitting chips 100 and the distance D4 between two of the semiconductor light emitting chips 100 emitting light waves that interfere with each other along the c-axis. When the distance D4 is less than the corresponding value on a corresponding one of line graphs illustrated in FIG. 39, light waves emitted from the semiconductor light emitting chips 100 interfere with each other. The length L of a side of each of the semiconductor light emitting chips 100 is varied among 300 μm, 500 μm, 700 μm, 1000 μm, 1500 μm, and 2000 μm.

As seen from FIG. 39, with increasing height H2 of each of the semiconductor light emitting chips 100, light emitted from one of the semiconductor light emitting chips 100 and directed upward from the semiconductor light emitting device tends to interfere with light emitted from another one of the semiconductor light emitting chips 100 adjacent to the one of the semiconductor light emitting chips 100 along the c-axis. With increasing length L of a side of each of the semiconductor light emitting chips 100, light waves emitted from the semiconductor light emitting chips 100 tends to interfere with each other, because mounting surface effective portions overlap each other.

Comparison between FIG. 37 according to the eleventh embodiment and FIG. 39 according to the twelfth embodiment shows that light waves emitted from semiconductor light emitting chips 100 adjacent to each other along the c-axis more easily interfere with each other than those emitted from semiconductor light emitting chips 100 adjacent to each other along the a-axis.

In view of the above, when D3 is the distance between two of the semiconductor light emitting chips 100 that are adjacent to each other along the a-axis, and D4 is the distance between two of the semiconductor light emitting chips 100 that are adjacent to each other along the c-axis, the distance D3 along the a-axis may be smaller than the distance D4 along the c-axis (D3<D4). This can reduce the interference between light waves emitted from adjacent ones of the semiconductor light emitting chips 100.

Therefore, when the distance D3 along the a-axis is greater than a smaller one of the distances D3′ and D3″, this can reduce the light interference occurring either with increasing height H2 or with increasing length L.

Furthermore, when the distance D3 along the a-axis is greater than a greater one of the distances D3′ and D3″, this can reduce the light interference occurring both with increasing height H2 and with increasing length L.

When the distance D4 along the c-axis is greater than a smaller one of the distances D4′ and D4″, this can reduce the light interference occurring either with increasing height H2 or with increasing length L.

Furthermore, when the distance D4 along the c-axis is greater than a greater one of the distances D4′ and D4″, this can reduce the light interference occurring both with increasing height H2 and with increasing length L.

When the number of semiconductor light emitting chips 100 arranged along the a-axis is Na, and the number of semiconductor light emitting chips 100 arranged along the c-axis is Nc, the number Na of semiconductor light emitting chips 100 arranged along the a-axis may be greater than the number Nc of semiconductor light emitting chips 100 arranged along the c-axis (Na>Nc). Thus, even when semiconductor light emitting devices include the same total number of chips, some of the semiconductor light emitting devices in which the number Na is greater than the number Nc can provide denser integration of semiconductor light emitting chips 100 than other semiconductor light emitting devices in which the number Na is less than the number Nc.

According to the twelfth embodiment, the semiconductor light emitting device including the plurality of semiconductor light emitting chips 100 reduces the degree of polarization of emitted light reflected off the mounting surface of the mounting substrate 101 to a sufficient level, and furthermore, the semiconductor light emitting chips 100 are sparsely arranged along the c-axis along which the radiation angle of emitted light is large while being densely arranged along the a-axis along which the radiation angle of emitted light is smaller than that of emitted light along the c-axis. This reduces the interference between light waves emitted from adjacent ones of the semiconductor light emitting chips 100, thereby enabling dense integration.

While, in this embodiment, only the flip-chip structure was described, a wire bonding structure can also provide similar advantages.

### Thirteenth Embodiment

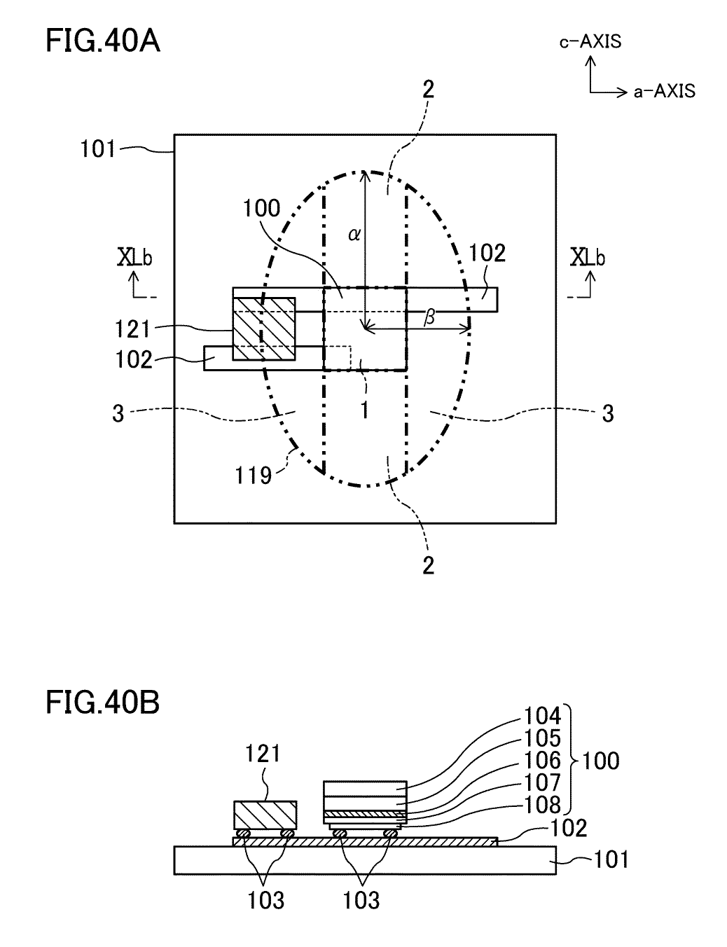

A semiconductor light emitting device according to a thirteenth embodiment of the present disclosure will be described hereinafter with reference to FIGS. 40A and 40B. Here, the difference between the eighth and thirteenth embodiments will be described.

As illustrated in FIGS. 40A and 40B, the thirteenth embodiment is different from the eighth embodiment in that a protection element 121 is placed on a mounting surface of a mounting substrate 101. The protection element 121 is connected in parallel to a semiconductor light emitting chip 100, for example, to protect the semiconductor light emitting chip 100 from high voltage, such as a surge. For example, a varistor or a Zener diode is used as the protection element 121. For example, ceramic to which zinc oxide (ZnO) is added as an additive can be used as the varistor. A Zener diode made of silicon (Si) can be used as the Zener diode.

A feature of the thirteenth embodiment is that the protection element 121 is placed on a region of the mounting surface except a second region 2. Here, the protection element 121 is exemplarily placed astride a third region 3 and a region of the mounting surface located outward from the third region 3. A material absorbing light emitted from the semiconductor light emitting chip 100 is used for the protection element 121. Therefore, the light output can be enhanced by placing the protection element 121 on a region of a mounting surface effective portion defined by an elliptical shape 119 except the second region 2 or a region of the mounting surface outside the mounting surface effective portion.

The protection element 121 needs to be connected in parallel to the semiconductor light emitting chip 100, and thus, as illustrated in FIGS. 40A and 40B, the semiconductor light emitting chip 100 and the protection element 121 are arranged along the a-axis, thereby reducing the length of each of interconnect electrodes 102 on the mounting surface.

Furthermore, the protection element 121 may be placed on a region of the mounting surface outside the mounting surface effective portion. This can reduce the influence of light absorption of the protection element 121 to a sufficient level.

According to the thirteenth embodiment, a semiconductor light emitting device configured to reduce the influence of light absorption of the protection element 121 while reducing the degree of polarization of emitted light reflected off the mounting surface to a sufficient level can be achieved.

The protection element 121 is an example electronic component, and an electronic component placed on the mounting surface of the mounting substrate 101 is not limited to a protection element. The number of placed electronic components is not limited to one, and may be two or more.

While, in this embodiment, only the flip-chip structure was described, a wire bonding structure can also provide similar advantages.

### Fourteenth Embodiment

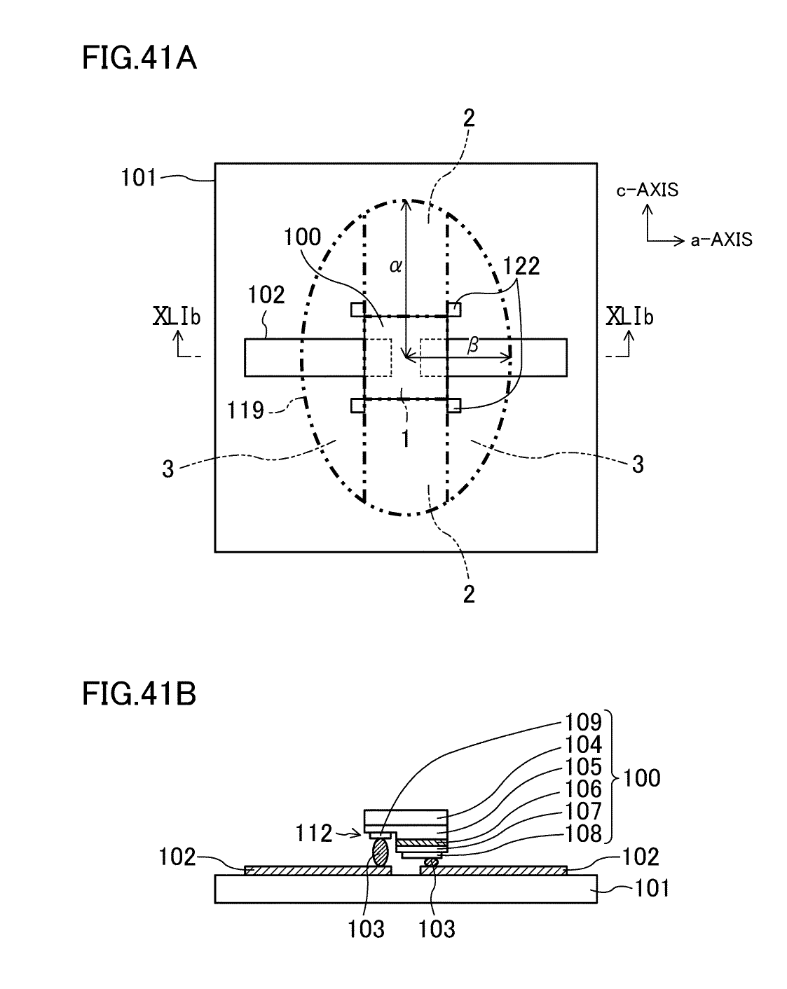

A semiconductor light emitting device according to a fourteenth embodiment of the present disclosure will be described hereinafter with reference to FIGS. 41A and 41B. Here, the difference between the eighth and fourteenth embodiments will be described.

As illustrated in FIGS. 41A and 41B, the fourteenth embodiment is different from the eighth embodiment in that alignment markers 122 are placed on a third region 3 of a mounting surface of a mounting substrate 101.

The alignment markers 122 according to this embodiment are marks used to place a semiconductor light emitting chip 100 on the mounting surface of the mounting substrate 101, specifically, on predetermined portions of interconnect electrodes 102. As illustrated in FIG. 41A, for example, the square alignment markers 122 are placed outward from four corners of the semiconductor light emitting chip 100. However, the planar shape of each of the alignment markers 122 is not limited to a square. As long as the planar shape of the alignment marker 122 can be visually checked or can be identified by a mounting facility, it may be any shape. As long as the number of the alignment markers 122 can be visually checked or can be identified by a mounting facility, it is also not limited to four. What is significant is that the alignment markers 122 are placed on the third region 3 of the mounting surface.

The alignment markers 122 are placed on the third region 3 of the mounting surface of the mounting substrate 101, thereby reducing the influence of the alignment markers 122 on the polarization characteristics of emitted light. The alignment markers 122 may be placed at locations different from on the interconnect electrodes 102. The same material as that of the interconnect electrodes 102 can be used as a material of the alignment markers 122. For example, after the formation of the interconnect electrodes 102, portions of the interconnect electrodes 102 corresponding to the alignment markers 122 may be removed to expose corresponding portions of the surface of the mounting substrate 101. When the alignment markers 122 and the interconnect electrodes 102 are formed at the same time, this can reduce the fabrication cost.

According to the fourteenth embodiment, a semiconductor light emitting device configured to reduce the influence of the alignment markers 122 on polarization characteristics while reducing the degree of polarization of emitted light reflected off the mounting surface of the mounting substrate 101 to a sufficient level can be achieved.

While, in this embodiment, only the flip-chip structure was described, a wire bonding structure can also provide similar advantages.

As described above, according to the eighth through fourteenth embodiments, the degree of polarization of light emitted from a nitride semiconductor light emitting device including an active layer having a nonpolar plane, such as an m- or a-plane, or a semipolar plane, such as a (20-21), (20-2-1), (10-1-3), (11-22), -r-, or (11-22) plane, as a growth surface can be reduced. Furthermore, a plurality of semiconductor light emitting chips can be densely arranged on the mounting surface while the degree of polarization of light emitted from the nitride semiconductor light emitting chips is reduced.

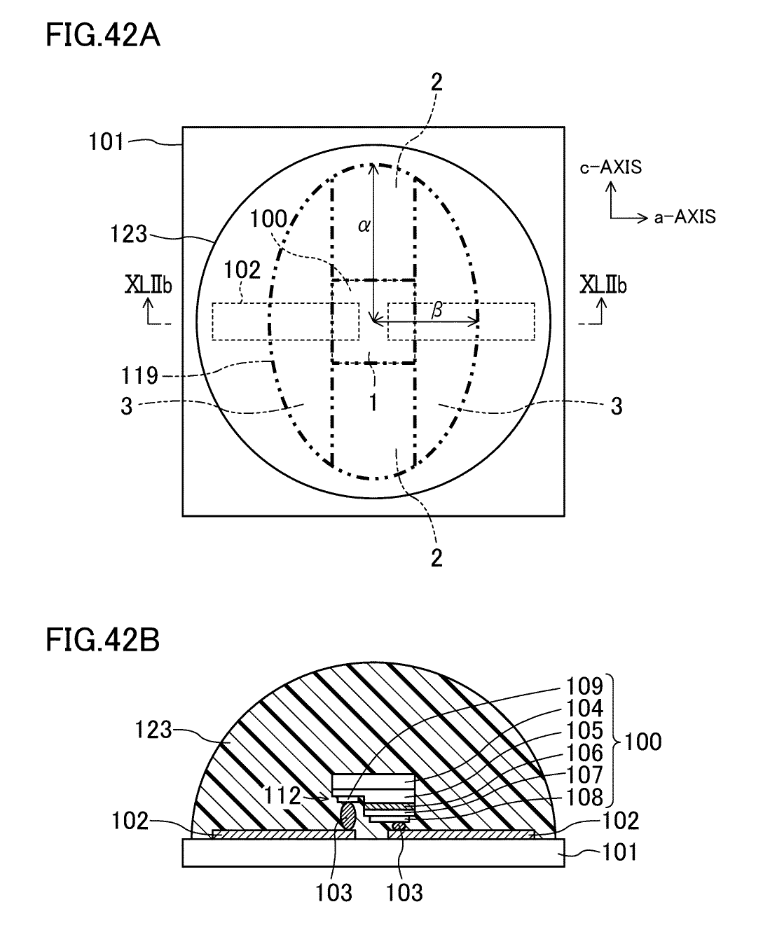

Also in each of all the embodiments and their variations, the semiconductor light emitting chip 100 may be covered with a transparent member. If the semiconductor light emitting chip 100 is covered with a transparent member, this increases the amount of light extracted from the semiconductor light emitting chip 100. Furthermore, the semiconductor light emitting chip 100 can be protected from water or contaminants in the outside air. FIG. 42 illustrates an example in which the semiconductor light emitting chip 100 of the eighth embodiment illustrated in FIGS. 29A and 29B is covered with a transparent member 123. For example, a resin material, such as a silicone resin or an acrylic resin, or a low-temperature glass material can be used as the transparent member 123. Although, in FIG. 42, the example transparent member 123 has a hemispherical shape, the hemispherical transparent member 123 may be distorted in shape, or the transparent member 123 may have an optional shape, such as a cubic shape or a rectangular parallelepiped shape.

The configuration of the semiconductor light emitting device including the reflection member 120 described in the tenth embodiment can be used also in the embodiments other than the tenth embodiment and their variations.

### Examples

The luminous intensity distribution characteristics of emitted light, the reflection properties of a reflecting material, and the influence of raised/recessed portions of a light extraction surface on polarization characteristics were described in each of the eighth through fourteenth embodiments, and prior to examples, (1) examination of luminous intensity distribution characteristics of emitted light, (2) examination of reflection properties of a reflecting material, and (3) examination of the influence of raised/recessed portions of a light extraction surface on polarization characteristics will be quantitatively described hereinafter.

(1) Examination of Luminous Intensity Distribution Characteristics of Emitted Light from m-Plane Nitride Semiconductor Light Emitting Chip

First, an active layer having a three-period quantum well structure including a 2-μm-thick n-type nitride semiconductor layer made of n-type GaN, a quantum well layer made of InGaN, and a barrier layer made of GaN, and a 0.5-μm-thick p-type nitride semiconductor layer made of p-type GaN were formed on a wafer-level n-type GaN substrate having an m-plane as its principal surface. In order to fabricate semiconductor light emitting chips emitting light having different wavelengths, a plurality of chips including quantum well layers made of InGaN and having different In contents were fabricated by appropriately changing the amount of In supplied and the crystal growth temperature.

A Ti/Pt layer was formed as an n-side electrode, and a Pd/Pt layer was formed as a p-side electrode. The thickness of the n-type GaN substrate having an m-plane as its principal surface was reduced to a thickness of 150 μm by back grinding. Grooves having a depth of about several μm from the surface of the wafer were formed in the wafer along the c-axis, i.e., the [0001] direction, and the a-axis, i.e., the [11-20] direction, using a diamond pen. Thereafter, the wafer was broken into semiconductor light emitting chips 100 with sides each having a length of 350 μm.

One of the fabricated semiconductor light emitting chips 100 was mounted on a mounting substrate 101 made of alumina and having an upper surface on which interconnects were formed by flip-chip mounting, thereby fabricating a semiconductor light emitting device illustrated in FIGS. 29A and 29B. In order to focus attention on the luminous intensity distribution characteristics of emitted light from the semiconductor light emitting device, a sealing member is not formed on the surface of the semiconductor light emitting device.

An OL700-30 LED Goniometer made by Optronic Laboratories, Inc. was used to measure the semiconductor light emitting device fabricated as above. The luminous intensity distribution characteristics of light emitted along the a-axis and light emitted along the c-axis were measured under the condition A (where the distance between the front end of an LED to a measuring device 118 is 316 mm) specified in CIE127 published by International Commission on Illumination (CIE).

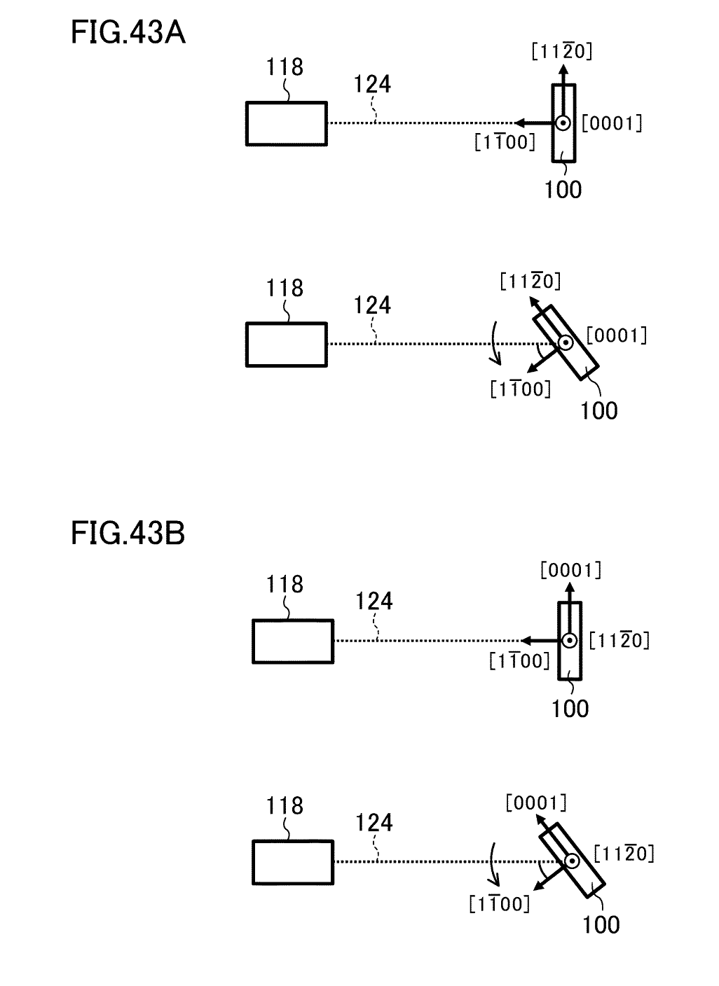

FIGS. 43A and 43B schematically illustrate a measurement system for the luminous intensity distribution characteristics.

The luminous intensity distribution characteristics of light emitted along the a-axis correspond to light intensities measured in the following manner: as illustrated in FIG. 43A, while the semiconductor light emitting chip 100 was rotated about its c-axis, the light intensities were measured using, as a measurement angle, an angle formed between the m-axis, i.e., the [1-100] direction, normal to an m-plane of an active layer of the semiconductor light emitting chip 100 and a measurement line 124 connecting the semiconductor light emitting chip 100 and the measuring device 118 together.

The luminous intensity distribution characteristics of light emitted along the c-axis correspond to light intensities measured in the following manner: as illustrated in FIG. 43B, while the semiconductor light emitting chip 100 was rotated about its a-axis, the light intensities were measured using, as a measurement angle, an angle formed between the m-axis, i.e., the [1-100] direction, normal to the m-plane of the active layer of the semiconductor light emitting chip 100 and the measurement line 124 connecting the semiconductor light emitting chip 100 and the measuring device 118 together. Here, the range of angles in which when the intensity of light emitted along the m-axis, i.e., the [1-100] direction, is one, the light intensity is 0.5 or greater is referred to as a radiation angle.

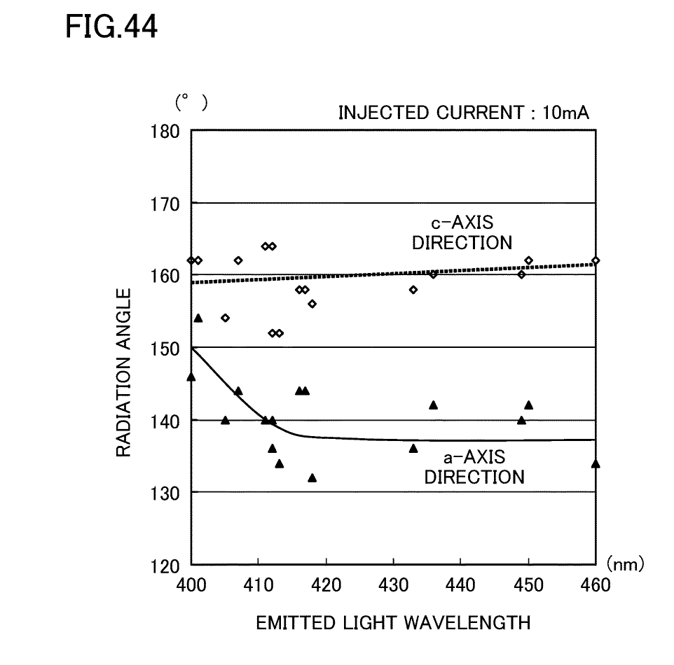

FIG. 44 illustrates the relationship between each of the radiation angles of light emitted from the semiconductor light emitting chip 100 along the a- and c-axes and the wavelength of the corresponding emitted light. The current injected into the semiconductor light emitting chip 100 is 10 mA. As seen from FIG. 44, the radiation angle of the light emitted along the c-axis is substantially fixed, and is about 160°. The radiation angle of the light emitted along the a-axis and having a wavelength greater than or equal to 420 nm is substantially fixed, and is about 140°. In other words, the semiconductor light emitting chip 100 using an m-plane as a growth surface of the active layer has luminous intensity distribution spread along the c-axis. A contour line along which the light intensity is 0.5 forms a shape close to an elliptical shape having a major axis along the c-axis, and a minor axis along the a-axis. When the radiation angle of light emitted along the c-axis is 160°, and the radiation angle of light emitted along the a-axis is 140°, the ratio of the length of the major axis (along the c-axis) to the length of the minor axis (along the a-axis) is 2 to 1.

(2) Examination of Reflection Properties of Reflecting Material

As a base material forming a mounting substrate 101 or a constituent material of the interconnect electrodes 102, 15 types of samples were prepared, and their reflectivities were measured. In the measurement of the reflectivities, the mirror reflectivity and diffuse reflectivity of each of the samples were measured using a spectrophotometer (UV-VIS) made by JASCO Corporation. Table 1 above shows the material and roughness Ra of the uppermost surface of each of the 15 types of samples, the material and surface roughness Ra of the base material of the sample, the mirror reflectivity, diffuse reflectivity, and total reflectivity of the uppermost surface of the sample, and the proportion of mirror reflection from the uppermost surface of the sample. The reflectivities are values at a wavelength of 450 nm.

As seen from Table 1, the DLC film of Sample 4 is a material utilized also as an anti-reflection film, and the total reflectivity of the DLC film is as low as about 5%. The uppermost surface of each of Samples 3 and 10 is made of Au, and the total reflectivity thereof is as low as about 30%. The uppermost surface of Sample 8 is made of AlN, and the total reflectivity thereof is as low as about 33%. The total reflectivity of each of the other samples is a relatively high value higher than or equal to 58%.

The proportion of mirror reflection from each of Samples 1, 6, and 14 is less than 2%, and each of Samples 1, 6, and 14 is a material from which light is very predominantly diffusely reflected. Light is incident upon the base material of the sample, and the incident light is reflected while being scattered. Thus, the light is predominantly diffusely reflected.

The proportion of mirror reflection from each of the other samples is higher than 12%, and components of light reflected from the sample include a mirror reflection component. The materials of the samples are materials off the surface of each of which light is reflected, and conductive materials, such as metal, correspond to the materials. The proportion of mirror reflection from each of the materials strongly depends on the roughness of the uppermost surface of a corresponding one of the samples and the surface roughness of the base material of the corresponding sample.

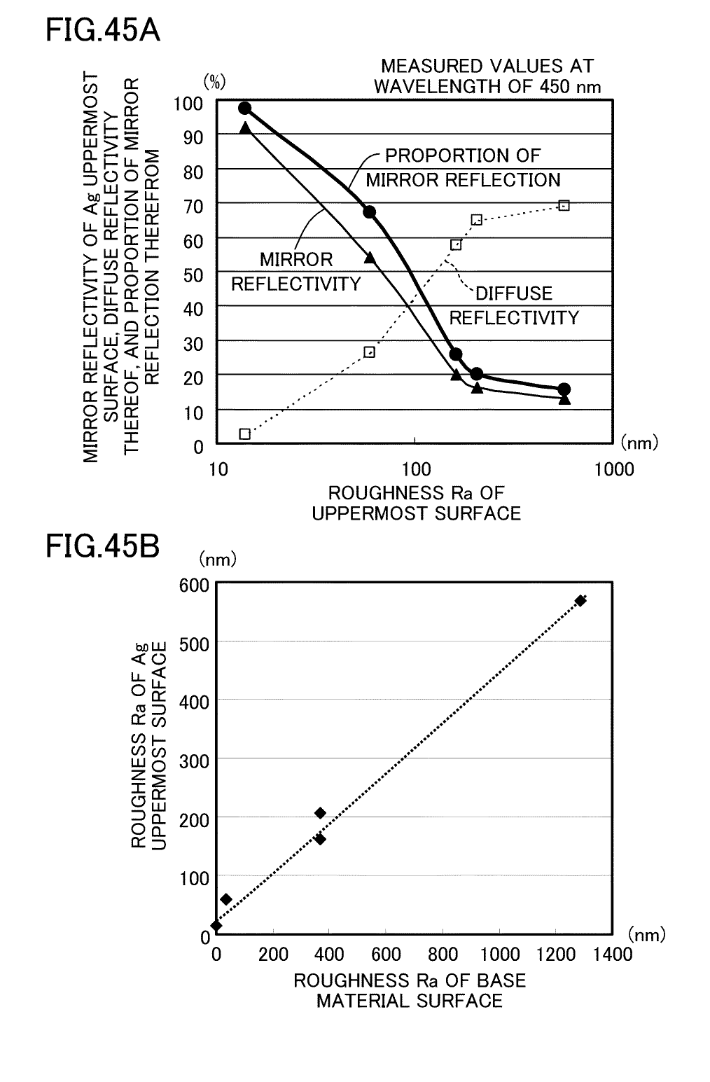

FIG. 45A relates to reflection from the Ag uppermost surface of each of Samples 2, 5, 7, 9, and 12, and illustrates the relationship between the Ag uppermost surface roughness and each of the mirror reflectivity of the Ag uppermost surface, the diffuse reflectivity thereof, and the proportion of mirror reflection from the Ag uppermost surface. With increasing Ag uppermost surface roughness, the diffuse reflectivity increases, and the mirror reflectivity, however, decreases. The Ag uppermost surface roughness at which the line showing the mirror reflectivity crosses the line showing the diffuse reflectivity in FIG. 45A, i.e., the Ag uppermost surface roughness at which the proportion of mirror reflection is 50% is about 100 nm. In other words, when the surface roughness of the interconnect electrodes 102 is greater than or equal to 100 nm, light is strongly affected by projections/recesses on the surface, and thus, is more predominantly diffusely reflected.

FIG. 45B illustrates the relationship between the surface roughness of the base material of each of Samples 2, 5, 7, 9, and 12 and the Ag uppermost surface roughness. The base material surface roughness is closely correlated with the Ag uppermost surface roughness, and in order to allow the Ag uppermost surface roughness to be greater than or equal to 100 nm, the base material surface roughness may be greater than or equal to 200 nm.

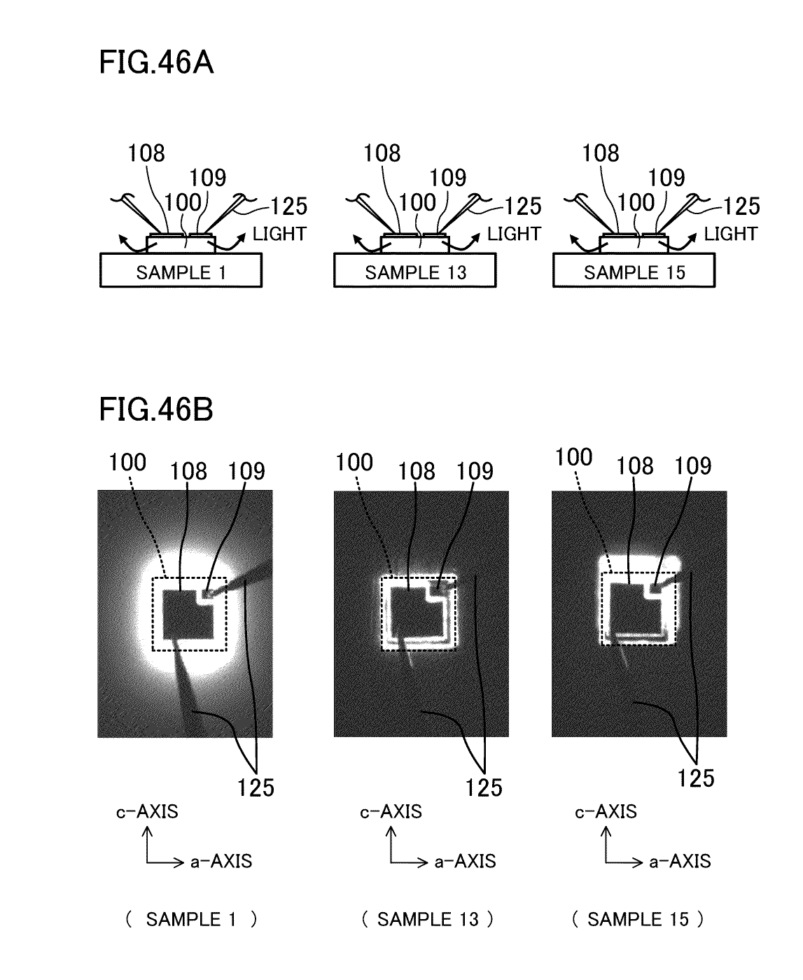

Next, a semiconductor light emitting chip 100 was placed on the surface of each of Samples 1, 13, and 15, and the degree of polarization of light from the semiconductor light emitting chip 100 was measured to examine the influence of the reflection properties of a reflection surface of the sample on the degree of polarization. FIGS. 46A and 46B illustrate examination systems for examining the influence of the reflection properties on the degree of polarization. FIG. 46A schematically illustrates a cross-sectional structure of each of the examination systems. FIG. 46B illustrates photographs obtained by taking the condition of light emitted from each of the semiconductor light emitting chips 100 and the reflected light from above, where the current injected into the semiconductor light emitting chip 100 is 10 mA. The semiconductor light emitting chip 100 was fabricated by a chip fabrication method described below in a fifth example. The length of each of sides of the chip is 950 μm, and the thickness of a substrate 104 is 150 μm. The wavelength of light emitted by a light emitting layer is 450 nm. A p-side electrode 108 and an n-side electrode 109 formed on the semiconductor light emitting chip 100 on each of the samples face upward.

The p-side electrode 108 and n-side electrode 109 of each of the semiconductor light emitting chips 100 are both made of materials through which light is not transmitted, and thus, light emitted from the side surfaces of the semiconductor light emitting chip 100 is reflected off the surface of a corresponding one of the samples. A prober 125 is brought into contact with the p-side electrode 108 and the n-side electrode 109 to inject a predetermined current into the semiconductor light emitting chip 100. The plan view photograph of Sample 1 in FIG. 46B shows that light reflected off the surface of Sample 1 forms a substantially elliptical shape having a major axis along the c-axis, and a minor axis along the a-axis. Since the surface of Sample 1 is made of alumina having an extremely high diffuse reflectivity, it is clearly seen that light is scattered off the mounting surface, and a mounting surface effective portion forms a shape close to an elliptical shape. By contrast, since the surfaces of Samples 13 and 15 are made of a material having an extremely high mirror reflectivity, the shape of light reflected off the mounting surface of each of Samples 13 and 15 is unclear. The reason for this is that light does not enter the optical system of the camera used to take the photographs. The mounting surface effective portion of the sample forms an elliptical shape.

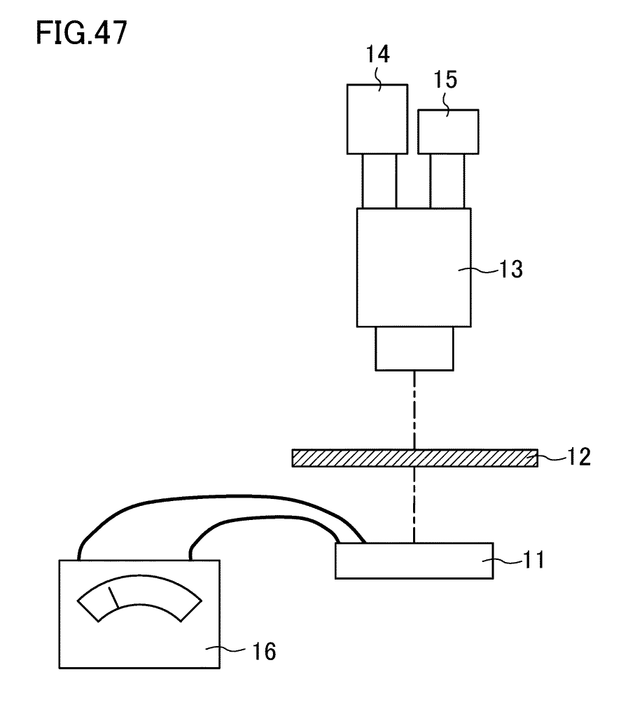

FIG. 47 schematically illustrates a measurement system for the degree of polarization. A power supply 16 allows a measurement target, i.e., a semiconductor light emitting device 11 made of a nitride semiconductor, to emit light. Light emitted from the semiconductor light emitting device 11 is viewed through a stereoscopic microscope 13. The stereoscopic microscope 13 has two ports, and while a silicon photodetector 14 is attached to one of the ports, a CCD camera 15 is attached to the other port. A polarizing plate 12 is interposed between the semiconductor light emitting device 11 and the stereoscopic microscope 13. While the polarizing plate 12 is rotated, the highest and lowest intensities of the emitted light are measured using the silicon photodetector 14.

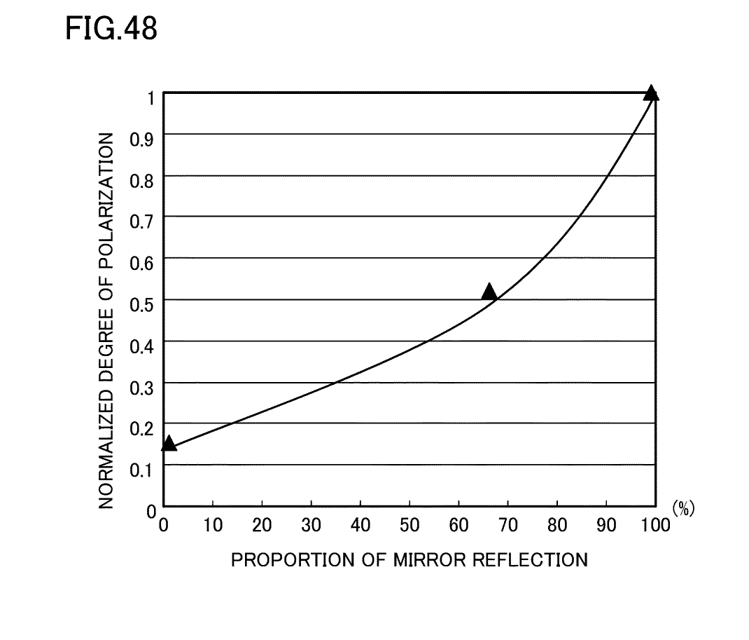

FIG. 48 illustrates the degree of polarization of light emitted from the semiconductor light emitting chip 100 placed on each of Samples 1, 13, and 15. The degree of polarization is normalized using the degree of polarization of light emitted from the semiconductor light emitting chip 100 on Sample 15. With increasing mirror reflectivity of the reflection surface, the degree of polarization of reflected light is maintained, and a decrease in the degree of polarization of reflected light is reduced. By contrast, it is seen that with decreasing mirror reflectivity of the reflection surface, the degree of polarization of reflected light decreases.

In view of the above, the degree of polarization of light emitted from the semiconductor light emitting chip 100 can be varied depending on the reflection properties of the reflection surface.

(3) Examination of Influence of Projection/Recess Portions Formed on Light Extraction Surface Upon Polarization

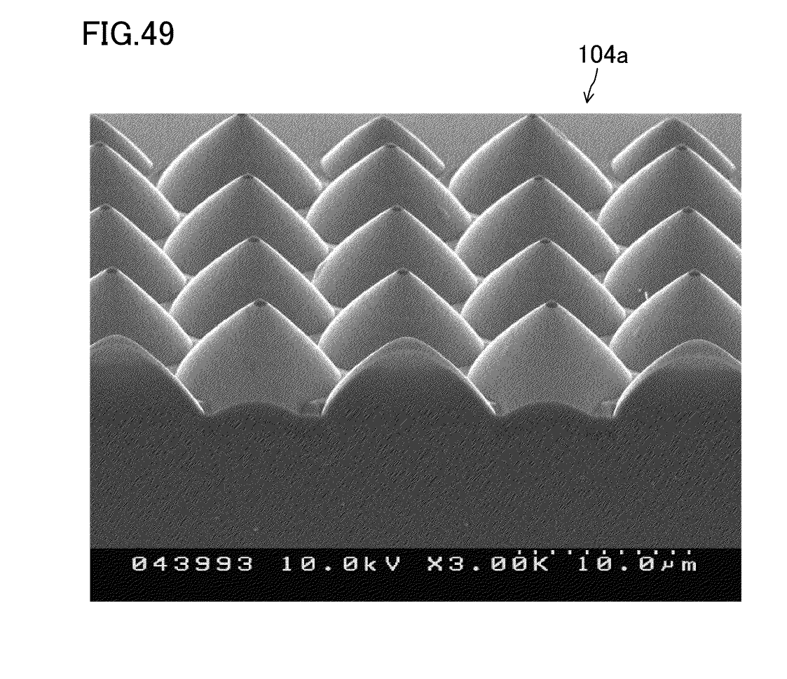

FIG. 49 is a scanning electron microscope (SEM) image where raised/recessed portions having a shape that has a diameter of 8 μm and a height of 5 μm and is close to a cone are formed on the surface of an m-plane GaN substrate. The shape of each of the raised/recessed portions corresponds to that of each of the raised/recessed portions 104a in FIG. 34A of the ninth embodiment.

For comparison, an m-plane GaN substrate that does not have raised/recessed portions and has an even surface was prepared. The substrates both have a thickness of 100 μm. The linear reflectivity (mirror reflectivity) and linear transmittance of each of the two types of samples were measured using a spectrophotometer (UV-VIS) made by JASCO Corporation. The reflectivity of the m-plane GaN substrate having the even surface was 18.4%, and the transmittance thereof was 69.5%. The reflectivity of the m-plane GaN substrate having the even surface, i.e., 18.4%, is substantially equal to the reflectivity determined based on the refractive index of GaN.

By contrast, the reflectivity of the m-plane GaN substrate having the surface on which the raised/recessed portions are formed was 14.0%, and the transmittance thereof was 54.0%. As such, both the values were less than those of the m-plane GaN substrate having the even surface. The reason for this is that light is scattered on the surface of the m-plane GaN substrate due to the raised portions, and the scattered light departs from the measured optical axis. As described above, it is seen that raised/recessed portions having the shape close to a cone, i.e., a dot shape, scatter light.

Next, in each of semiconductor light emitting devices including a chip having a light extraction surface on which stripe-shaped raised/recessed portions are formed, the influence of an angle formed between the direction of extension of the stripes and the a-axis of a light emitting layer upon the degree of polarization was examined. Semiconductor light emitting chips including a light emitting layer that has an m-plane as a growth surface and is made of a nitride semiconductor were fabricated in a manner similar to that in a fifth example described below.

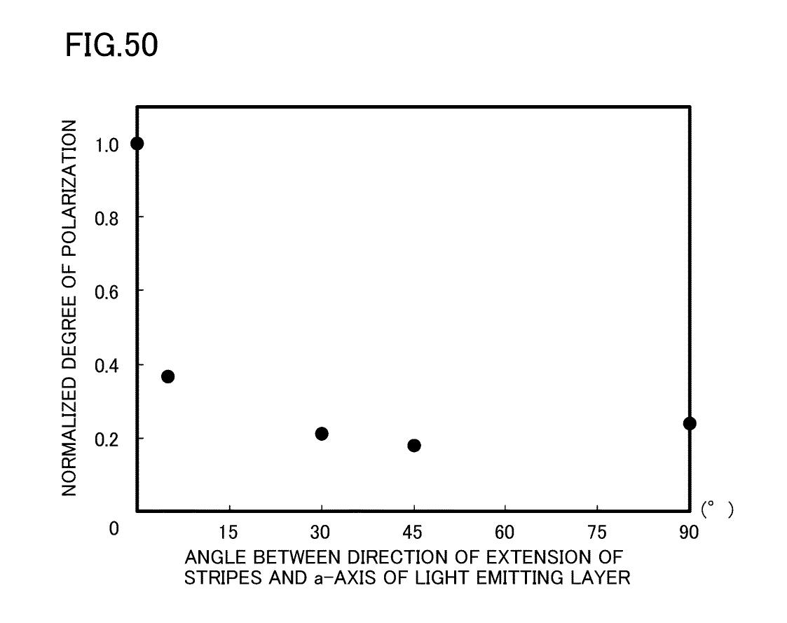

The semiconductor light emitting chips each form the shape of a square with sides having a length of 350 μm, and each have a 100-μm-thick substrate. Stripe-shaped raised/recessed portions were formed on the surface of each of the semiconductor light emitting chips (the back surface of the substrate). The cross-sectional shape of each of the stripe-shaped raised/recessed portions is close to an isosceles triangle as illustrated in FIG. 34F, the distance between each adjacent pair of the raised portions is 8 μm, and the height of each of the raised portions is 2.5 μm. The angle θ formed between the direction of extension of the stripes and the electric field direction of polarized light (the a-axis of the light emitting layer) was varied among 0°, 5°. 30°, 45°, and 90°. FIG. 50 illustrates the normalized degrees of polarization of light emitted from the semiconductor light emitting devices. The normalized degrees of polarization each denote a value normalized using the degree of polarization at an angle θ of 0° as 1.0. Measurement results illustrated in FIG. 50 show that when the angle θ is 45°, the normalized degree of polarization is lowest. Based on the measurement result, the range of the angles θ within which the degree of polarization can be reduced may be about 5-90°. Furthermore, the angle θ may be about 30-90°, or may be about 45°.

### Fifth Example

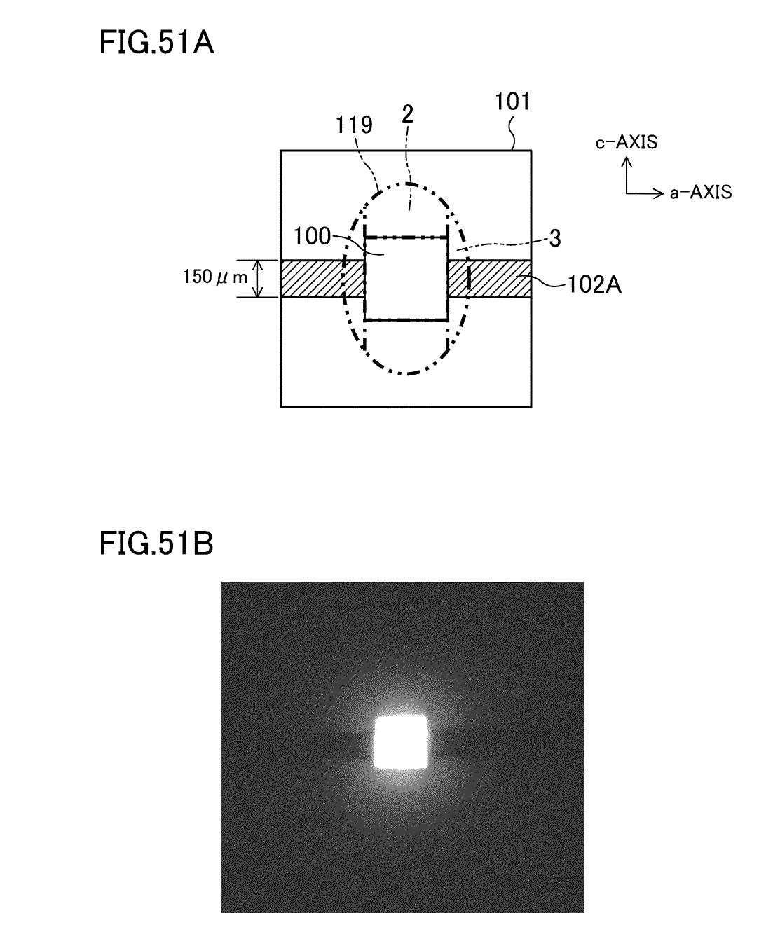

A semiconductor light emitting device according to a fifth example will be described with reference to FIGS. 51A and 51B. First, a method for fabricating a semiconductor light emitting chip 100 forming the semiconductor light emitting device according to the fifth example will be briefly described.

First, an active layer having a three-period quantum well structure including a 2-μm thick n-type nitride semiconductor layer made of n-type GaN, a quantum well layer made of InGaN, and a barrier layer made of GaN, and a 0.5-μm-thick p-type nitride semiconductor layer made of p-type GaN were formed on a wafer-level n-type GaN substrate having an m-plane as its principal surface, for example, by MOCVD.

A Ti/Pt layer was formed as an n-side electrode, and a Pd/Pt layer was formed as a p-side electrode. Thereafter, the thickness of the n-type GaN substrate was reduced to a thickness of 150 μm by grinding the back surface of the n-type GaN substrate.

Subsequently, grooves having a depth of about several μm from the surface of the wafer on which light-emitting structures were formed were formed in the wafer along the c-axis, i.e., the [0001] direction, and the a-axis, i.e., the [11-20] direction, using a diamond pen. Thereafter, the wafer was broken into semiconductor light emitting chips 100 which each have sides each having a length of 350 μm and are made of an m-plane GaN-based semiconductor.

Subsequently, one of the fabricated semiconductor light emitting chips 100 was mounted on a mounting substrate 101 made of high-temperature fired alumina ceramic by flip-chip mounting, thereby fabricating a semiconductor light emitting device. The thickness of the mounting substrate 101 made of high-temperature fired alumina ceramic is about 1 mm. About 4-μm-thick interconnect electrodes 102A made of silver (Ag) were selectively formed on the surface of the mounting substrate 101. In other words, the interconnect electrodes 102A were formed astride a portion of a third region 3 of an elliptical shape 119 and a region of the mounting substrate 101 located outward from the third region 3, were arranged in a direction parallel to the a-axis, and were not formed on the second region 2.

As illustrated in Sample 2 in Table 1, the mirror reflectivity of the interconnect electrodes 102A made of Ag is 12.9%, the diffuse reflectivity thereof is 69.1%, the total reflectivity thereof is 82.0%, and the proportion of mirror reflection from the interconnect electrodes 102A is 15.7%. The c-axis width of each of the interconnect electrodes 102A is about 150 μm. The proportion of the area of portions of the interconnect electrodes 102A on a mounting surface effective portion inside the elliptical shape 119 to the area of the mounting surface effective portion is 8.5%.

High-temperature fired alumina ceramic is exposed on the second region 2 of the elliptical shape 119. As illustrated in Sample 1 in Table 1, the mirror reflectivity of the high-temperature fired alumina ceramic is 1.1%, the diffuse reflectivity thereof is 94.4%, the total reflectivity thereof is 95.5%, and the proportion of mirror reflection from the high-temperature fired alumina ceramic is 1.2%.

The wavelength of light emitted from the semiconductor light emitting device of the fifth example that is operating at a current of 5 mA was 410 nm. FIG. 51B is a plan view photograph of the semiconductor light emitting device of this example that is operating at a current of 5 mA. When the degree of polarization of the light emitted from the semiconductor light emitting device that is operating at a current of 5 mA was measured, the degree of polarization was 0.22. The measurement result shows that since the degree of polarization of light emitted from a semiconductor light emitting device according to a comparative example described below is 0.26, the degree of polarization of the light emitted from the semiconductor light emitting device of the fifth example can be lower than that of the light emitted from the semiconductor light emitting device of the comparative example.

### Sixth Example

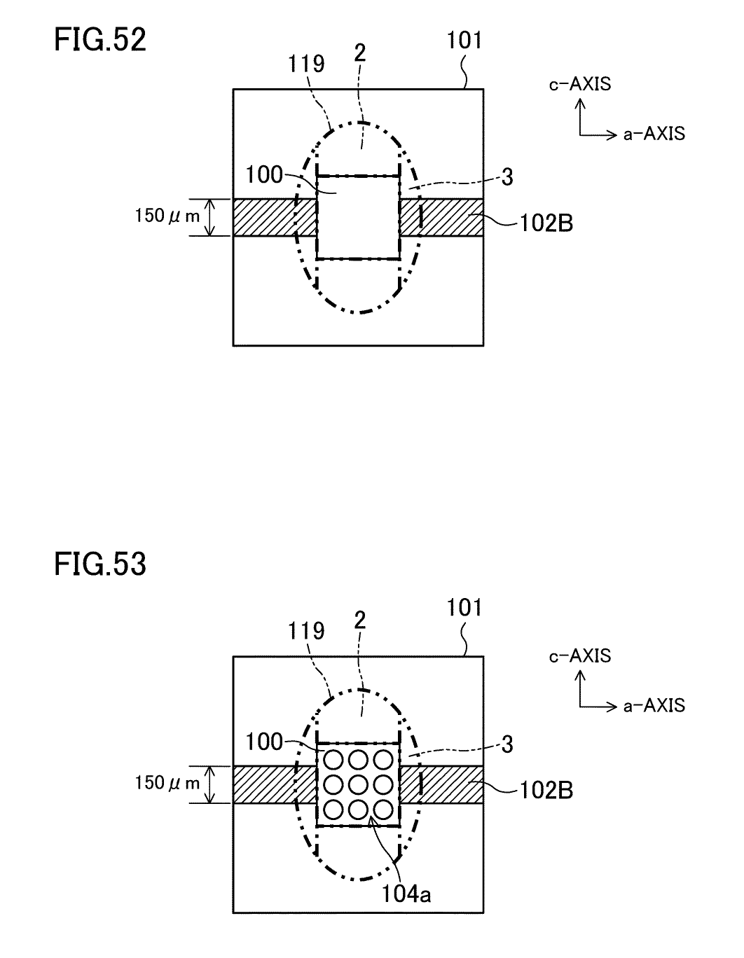

A semiconductor light emitting device according to a sixth example will be described with reference to FIG. 52. A semiconductor light emitting chip 100 illustrated in FIG. 52 was fabricated in a manner similar to that in the fifth example.

Subsequently, the semiconductor light emitting chip 100 was mounted on a mounting substrate 101 made of high-temperature fired alumina ceramic by flip-chip mounting, thereby fabricating a semiconductor light emitting device. The thickness of the mounting substrate 101 is about 1 mm. About 4-μm-thick interconnect electrodes 102B made of gold (Au) were selectively formed on the mounting substrate 101. In other words, the interconnect electrodes 102B were formed astride a portion of a third region 3 of an elliptical shape 119 and a region of the mounting substrate 101 located outward from the third region 3, were arranged in a direction parallel to the a-axis, and were not formed on the second region 2.

As illustrated in Sample 3 in Table 1, the mirror reflectivity of the interconnect electrodes 102B made of Au is 4.1%, the diffuse reflectivity thereof is 29.1%, the total reflectivity thereof is 33.2%, and the proportion of mirror reflection from the interconnect electrodes 102B is 12.3%. The c-axis width of each of the interconnect electrodes 102B is about 150 μm. The proportion of the area of portions of the interconnect electrodes 102B made of Au on a mounting surface effective portion inside the elliptical shape 119 to the area of the mounting surface effective portion is 8.5%.

The high-temperature fired alumina ceramic is exposed on the second region 2 of the elliptical shape 119. As illustrated in Sample 1 in Table 1, the mirror reflectivity of high-temperature fired alumina ceramic is 1.1%, the diffuse reflectivity thereof is 94.4%, the total reflectivity thereof is 95.5%, and the proportion of mirror reflection from high-temperature fired alumina ceramic is 1.2%.

The wavelength of light emitted from the semiconductor light emitting device of the sixth example that is operating at a current of 5 mA was 410 nm. When the degree of polarization of the light emitted from the semiconductor light emitting device that is operating at a current of 5 mA was measured, the degree of polarization was 0.22. The measurement result shows that since the degree of polarization of light emitted from a semiconductor light emitting device according to a comparative example described below is 0.26, the degree of polarization of the light emitted from the semiconductor light emitting device of the sixth example can be lower than that of the light emitted from the semiconductor light emitting device of the comparative example.

### Seventh Example

A semiconductor light emitting device according to a seventh example will be described with reference to FIG. 53. A semiconductor light emitting chip 100 illustrated in FIG. 53 was fabricated in a manner similar to that in the fifth example, and then, generally hemispherical raised/recessed portions 104a were formed on an upper surface of the semiconductor light emitting chip 100 from which emitted light is extracted (the back surface of a substrate) in a manner similar to that in the ninth embodiment.

Subsequently, the semiconductor light emitting chip 100 was mounted on a mounting substrate 101 made of high-temperature fired alumina ceramic by flip-chip mounting, thereby fabricating a semiconductor light emitting device. The thickness of the mounting substrate 101 is about 1 mm. About 4-μm-thick interconnect electrodes 102B made of gold (Au) were selectively formed on the surface of the mounting substrate 101. In other words, the interconnect electrodes 102B were formed astride a portion of a third region 3 of an elliptical shape 119 and a region of the mounting substrate 101 located outward from the third region 3, were arranged in a direction parallel to the a-axis, and were not formed on the second region 2.

As illustrated in Sample 3 in Table 1, the mirror reflectivity of the interconnect electrodes 102B made of Au is 4.1%, the diffuse reflectivity thereof is 29.1%, the total reflectivity thereof is 33.2%, and the proportion of mirror reflection from the interconnect electrodes 102B is 12.3%. The c-axis width of each of the interconnect electrodes 102B is about 150 μm. The proportion of the area of portions of the interconnect electrodes 102B made of Au on a mounting surface effective portion inside the elliptical shape 119 to the area of the mounting surface effective portion is 8.5%.

The high-temperature fired alumina ceramic is exposed on the second region 2 of the elliptical shape 119. As illustrated in Sample 1 in Table 1, the mirror reflectivity of high-temperature fired alumina ceramic is 1.1%, the diffuse reflectivity thereof is 94.4%, the total reflectivity thereof is 95.5%, and the proportion of mirror reflection from high-temperature fired alumina ceramic is 1.2%.

The wavelength of light emitted from the semiconductor light emitting device of the seventh example that is operating at a current of 5 mA was 410 nm. When the degree of polarization of the light emitted from the semiconductor light emitting device that is operating at a current of 5 mA was measured, the degree of polarization was 0.16. The measurement result shows that since the degree of polarization of light emitted from a semiconductor light emitting device according to a comparative example described below is 0.26, the degree of polarization of the light emitted from the semiconductor light emitting device of the seventh example can be much lower than that of the light emitted from the semiconductor light emitting device of the comparative example.

### Comparative Example

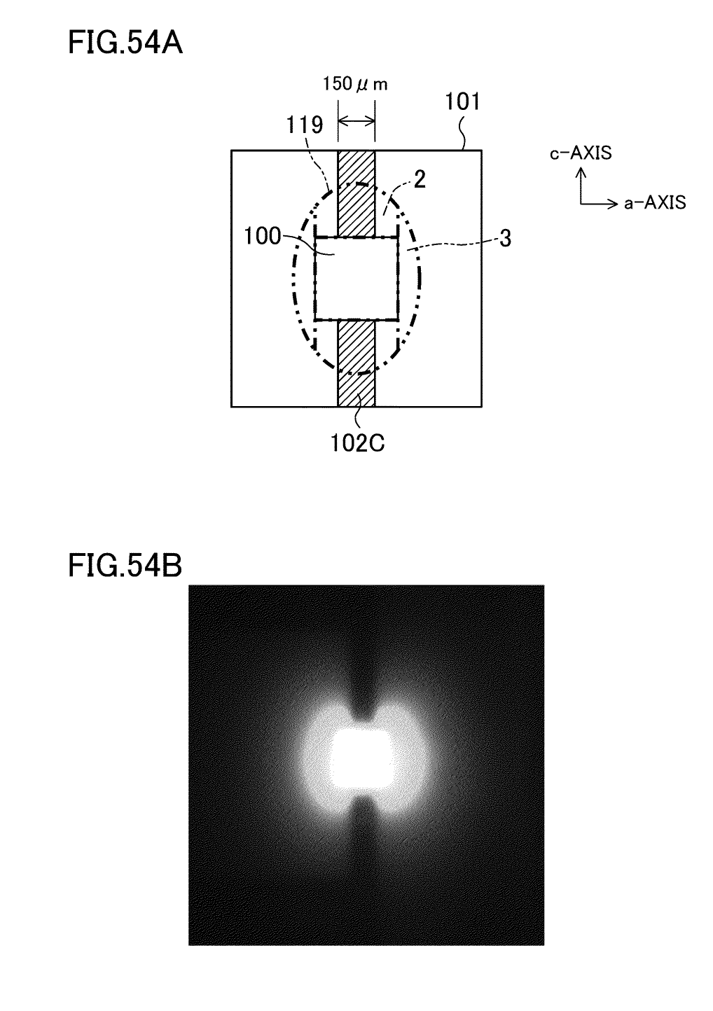

A semiconductor light emitting device according to a comparative example will be described hereinafter with reference to FIGS. 54A and 54B. A semiconductor light emitting chip 100 illustrated in FIGS. 54A and 54B was fabricated in a manner similar to that in the fifth example.

Subsequently, the semiconductor light emitting chip 100 was mounted on a mounting substrate 101 made of high-temperature alumina ceramic by flip-chip mounting, thereby fabricating a semiconductor light emitting device. The thickness of the mounting substrate 101 made of high-temperature alumina ceramic is about 1 mm. About 4-μm-thick interconnect electrodes 102C made of Ag were selectively formed on the surface of the mounting substrate 101. In other words, the interconnect electrodes 102C were formed astride a portion of a second region 2 of an elliptical shape 119 and a region of the mounting substrate 101 located outward from the second region 2, were arranged in a direction parallel to the c-axis, and were not formed on a third region 3.

Therefore, the high-temperature fired alumina ceramic is exposed on the third region 3 of the elliptical shape 119. As illustrated in Sample 1 in Table 1, the mirror reflectivity of high-temperature fired alumina ceramic is 1.1%, the diffuse reflectivity thereof is 94.4%, the total reflectivity thereof is 95.5%, and the proportion of mirror reflection from high-temperature fired alumina ceramic is 1.2%.

As illustrated in Sample 2 in Table 1, the mirror reflectivity of the interconnect electrodes 102C made of Ag is 12.9%, the diffuse reflectivity thereof is 69.1%, the total reflectivity thereof is 82.0%, and the proportion of mirror reflection from the interconnect electrodes 102C is 15.7%. The c-axis width of each of the interconnect electrodes 102C is about 150 μm. The proportion of the area of portions of the interconnect electrodes 102C made of Ag on an mounting surface effective portion inside the elliptical shape 119 to the area of the mounting surface effective portion is 8.5%. The a-axis width of each of the interconnect electrodes 102C is about 150 μm. The proportion of the area of the region where the high-temperature fired alumina ceramic is exposed to the area of the mounting surface effective portion inside the elliptical shape 119 is 17.0%.

The wavelength of light emitted from the semiconductor light emitting device of the comparative example that is operating at a current of 5 mA was 410 nm. FIG. 54B is a plan view photograph of the semiconductor light emitting device of this comparative example operating at a current of 5 mA. When the degree of polarization of the light emitted from the semiconductor light emitting device that is operating at a current of 5 mA was measured, the degree of polarization was 0.26.

A semiconductor light emitting device according to an aspect of the present disclosure can be utilized as, e.g., a liquid crystal projector light source device, or a backlight for a light emitting diode (LED). A semiconductor light emitting device according to another aspect of the present disclosure can be utilized as, e.g., a light source device for illumination, lighting, or other uses.

What is claimed is:

1. A semiconductor light emitting device comprising:
a mounting substrate;
metal formed on a surface of the mounting substrate; and
a semiconductor light emitting chip held on the surface of the mounting substrate, and including a nitride semiconductor active layer having a nonpolar plane or a semipolar plane as a growth surface, wherein
the metal is placed on at least one portion of one of high polarization regions,
a proportion of mirror reflection from at least one portion of one of low polarization regions is lower than a proportion of mirror reflection from the metal, and
a proportion of mirror reflection from the high polarization regions is higher than a proportion of mirror reflection from the low polarization regions
where the high polarization regions represent regions of the surface of the mounting substrate illuminated with light from the nitride semiconductor active layer and located laterally outward from the semiconductor light emitting chip along a crystal axis that is parallel to the nitride semiconductor active layer and perpendicular to a polarization direction of the light from the nitride semiconductor active layer, and the low polarization regions represent regions of the surface of the mounting substrate illuminated with the light from the nitride semiconductor active layer except the high polarization regions.

2. A semiconductor light emitting device comprising:
a mounting substrate;
an interconnect electrode formed on a surface of the mounting substrate; and
a semiconductor light emitting chip held on the surface of the mounting substrate so as to be electrically connected to the interconnect electrode, and including a nitride semiconductor active layer having a nonpolar plane or a semipolar plane as a growth surface, wherein
the interconnect electrode is placed on at least one portion of one of high polarization regions,
a proportion of mirror reflection from at least one portion of one of low polarization regions is lower than a proportion of mirror reflection from the interconnect electrode, and
a proportion of mirror reflection from the high polarization regions is higher than a proportion of mirror reflection from the low polarization regions,
where the high polarization regions represent regions of the surface of the mounting substrate illuminated with light from the nitride semiconductor active layer and located laterally outward from the semiconductor light emitting chip along a crystal axis that is parallel to the nitride semiconductor active layer and perpendicular to a polarization direction of the light from the nitride semiconductor active layer, and the low polarization regions represent regions of the surface of the mounting substrate illuminated with the light from the nitride semiconductor active layer except the high polarization regions.

3. A semiconductor light emitting device comprising:
a mounting substrate;
an interconnect electrode formed on a surface of the mounting substrate; and
a semiconductor light emitting chip held on the surface of the mounting substrate so as to be electrically connected to the interconnect electrode, and including a nitride semiconductor active layer having an m-plane as a growth surface, wherein
an elliptical shape is defined on the surface of the mounting substrate,
the elliptical shape has a center identical with a center of gravity of the semiconductor light emitting chip when viewed in plan, a major axis parallel to a c-axis of the nitride semiconductor active layer, and a minor axis parallel to an a-axis of the nitride semiconductor active layer,
the major axis and the minor axis respectively have a radius α and a radius β respectively represented by:
α=2√{(L²+2TL)/π} (1);
and
β=√{(L²+2TL)/π} (2)
where L is a length of a side of the semiconductor light emitting chip, and T is a thickness of the semiconductor light emitting chip,
when viewed in plan, a region of the surface of the mounting substrate inside the elliptical shape is sectioned into nine sub-regions using two straight lines parallel to the c-axis of the nitride semiconductor active layer and two straight lines parallel to the a-axis of the nitride semiconductor active layer such that the semiconductor light emitting chip is surrounded by the straight lines,
a first region represents one of the nine sub-regions that contains the semiconductor light emitting chip,
a second region represents a group of two of the nine sub-regions adjacent to the first region along the c-axis,
a third region represents a group of six of the nine sub-regions except the first and second regions,
the two straight lines parallel to the c-axis and the two straight lines parallel to the a-axis are defined such that an area of the first region is minimum,
the interconnect electrode is formed on at least one portion of the second region,
a proportion of mirror reflection from at least one portion of the third region is lower than a proportion of mirror reflection from the interconnect electrode, and
a proportion of mirror reflection from the second region is higher than a proportion of mirror reflection from the third region.

4. The semiconductor light emitting device of claim 3, wherein
a proportion of mirror reflection from a surface of the interconnect electrode is higher than or equal to 15%.

5. The semiconductor light emitting device of claim 3, wherein
a relationship represented by T<L is satisfied.

6. The semiconductor light emitting device of claim 3, wherein
a relationship represented by T<L/6 is satisfied.

7. The semiconductor light emitting device of claim 3, wherein
a proportion of mirror reflection from a surface of the interconnect electrode is higher than or equal to 50%.

8. The semiconductor light emitting device of claim 3, wherein
a surface roughness of the interconnect electrode is equal to or less than 50 nm.

9. The semiconductor light emitting device of claim 3, wherein
an area of a portion of the third region from which a proportion of mirror reflection is lower than the proportion of mirror reflection from the interconnect electrode when viewed in plan is equal to or less than (L²+4TL)/10.

10. The semiconductor light emitting device of claim 1, wherein
a plurality of stripe-shaped raised/recessed portions are formed on a light extraction surface of the semiconductor light emitting chip, and
a direction of extension of the raised/recessed portions is inclined at an angle greater than or equal to 0° and less than 5° with respect to a direction of polarization of light from the nitride semiconductor active layer or an a-axis of the nitride semiconductor active layer.

11. The semiconductor light emitting device of claim 3, further comprising:
a reflection member held on the surface of the mounting substrate, having a height H1 from the surface, and having its inner surface that is a reflection surface, wherein
the relationships represented by D1<2.75×H1 and D2<5.67×H1 are satisfied
where D1 is a distance from an end surface of the semiconductor light emitting chip corresponding to an a-plane of the chip to the reflection member along the a-axis, and D2 is a distance from an end surface of the chip corresponding to a c-plane of the chip to the reflection member along the c-axis, and
a proportion of mirror reflection from a region of the reflection surface of the reflection member corresponding to the second region is higher than or equal to 15%.

12. The semiconductor light emitting device of claim 3, wherein
the semiconductor light emitting chip includes a plurality of semiconductor light emitting chips held on the surface of the mounting substrate along the a-axis while being spaced, and
the elliptical shape inside which the region of the surface of the mounting substrate is sectioned into the first region, the second region, and the third region is defined on the surface of the mounting substrate to correspond to each of the semiconductor light emitting chips.

13. The semiconductor light emitting device of claim 12, wherein
a distance D3 between an adjacent pair of the semiconductor light emitting chips is greater than a smaller one of a value given by (2.75×H2), where H2 is a height from the surface of the mounting substrate to an upper surface of each of the semiconductor light emitting chips, and a value given by [√{(L²+2TL)/π}−L/2].

14. The semiconductor light emitting device of claim 12, wherein
a distance D3 between an adjacent pair of the semiconductor light emitting chips is greater than a greater one of a value given by (2.75×H2), where H2 is a height from the surface of the mounting substrate to an upper surface of each of the semiconductor light emitting chips, and a value given by [√{(L²+2TL)/π}−L/2].

15. The semiconductor light emitting device of claim 3, wherein
the semiconductor light emitting chip includes a plurality of semiconductor light emitting chips at least two of which are held on the surface of the mounting substrate along the a-axis while being spaced, and at least two of which are held on the surface of the mounting substrate along the c-axis while being spaced,
the elliptical shape inside which the region of the surface of the mounting substrate is sectioned into the first region, the second region, and the third region is defined on the surface of the mounting substrate to correspond to each of the semiconductor light emitting chips, and
D3<D4 is satisfied where D3 is a distance between an adjacent pair of the semiconductor light emitting chips along the a-axis, and D4 is a distance between an adjacent pair of the semiconductor light emitting chips along the c-axis.

16. The semiconductor light emitting device of claim 15, wherein
Nc<Na is satisfied where Na is the number of the semiconductor light emitting chips arranged along the a-axis, and Nc is the number of the semiconductor light emitting chips arranged along the c-axis.

17. The semiconductor light emitting device of claim 15, wherein
the distance D3 is greater than a smaller one of a value given by (2.75×H2), where H2 is a height from the surface of the mounting substrate to an upper surface of each of the semiconductor light emitting chips, and a value given by [√{(L²+2TL)/π}−L/2], and
the distance D4 is greater than a smaller one of a value given by (5.67×H2) and a value given by [2√{(L²+2TL)/π}−L/2].

18. The semiconductor light emitting device of claim 15, wherein
the distance D3 is greater than a greater one of a value given by (2.75×H2), where H2 is a height from the surface of the mounting substrate to an upper surface of each of the semiconductor light emitting chips, and a value given by [√{(L²+2TL)/π}−L/2], and
the distance D4 is greater than a greater one of a value given by (5.67×H2) and a value given by [2√{(L²+2TL)/π}−L/2].

19. The semiconductor light emitting device of claim 1, further comprising:
a protection element held on one of the low polarization regions of the mounting substrate.

20. The semiconductor light emitting device of claim 1, further comprising:
an alignment marker placed on one of the low polarization regions of the mounting substrate.
